(19) United States
(12) Patent Application Publication
(10) Pub. No.: US 2026/0255669 A1
(43) Pub. Date: Aug. 27, 2026

(54) BACKSIDE GATE CONTACT AND METHOD OF FORMING SAME

(71) Applicants: Taiwan Semiconductor Manufacturing Company, Ltd., Hsin-Chu (TW); TSMC Arizona Corporation, Phoenix, AZ (US)

(72) Inventors: Cheng-Yi Peng, Taipei City (TW); Tsung-Chieh Hsiao, Hsinchu (TW); Tso-Hsuan Chen, Phoenix, AZ (US); Chih-Lin Wang, Hsinchu County (TW)

(21) Appl. No.: 19/282,956

(22) Filed: Jul. 28, 2025

Related U.S. Application Data
(60) Provisional application No. 63/764,069, filed on Feb. 27, 2025.

(51) Int. Cl. H10D 84/85; H10D 30/00; H10D 30/62; H10D 62/10; H10D 64/27; H10D 84/01

(52) U.S. Cl. CPC H10D 84/853; H10D 64/518; H10D 84/0172; H10D 84/0188; H10D 84/0193; H10D 84/851; H10D 30/502; H10D 30/6211; H10D 62/121

(57) ABSTRACT

A semiconductor device includes a first active region including a first channel region and two first source/drain regions sandwiching the first channel region, a second active region including a second channel region and two second source/drain regions sandwiching the second channel region, an isolation structure extending from a first sidewall of the first active region to a second sidewall of the second active region, and a gate structure extending across the first and second channel regions. The gate structure includes a gate dielectric layer and a gate electrode layer. The gate electrode layer includes a first segment of a first conductivity type over the first channel region and a second segment of a second conductivity type over the second channel region. The semiconductor device also includes a backside gate contact extending through the gate dielectric layer and interfacing a bottom surface of the gate electrode layer.

### PRIORITY DATA

This application claims priority to U.S. Provisional Patent Application No. 63/764,069 filed on Feb. 27, 2025, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Conventional ICs are constructed in a vertically stacked manner, with transistors formed at the lowest level and interconnect structures (such as vias and metal lines) positioned above the transistors to provide electrical connectivity. Power rails (such as metal routings for supply voltages and ground planes) and signal lines (such as metal routings for gate control signals) are also located above the transistors and are part of the interconnect. As ICs continue to scale down, the critical dimensions (CDs) and pitches of the signal lines also shrink, which can result in increased voltage drop along the signal lines and increased parasitic capacitance among the signal lines. The increased voltage drop along the signal lines may compromise signal integrity, and the increased parasitic capacitance among the signal lines may degrade circuit speed. Lithographic overlay control also becomes challenging through the fabrication processes. Accordingly, although conventional semiconductor fabrication techniques have generally been adequate, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A and 1B illustrate a perspective view and a top view of a portion of a semiconductor device, respectively, in accordance with some embodiments of the present disclosure.

FIG. 2 illustrates a cross-sectional view of various layers of a semiconductor device, in accordance with some embodiments of the present disclosure.

FIG. 3 illustrates a top view of a standard cell array containing a plurality of standard cells, in accordance with some embodiments of the present disclosure.

FIGS. 4A-44D illustrate top and cross-sectional views of a circuit containing a pair of CMOS transistors having a common gate structure and one or more backside gate contacts, in accordance with some embodiments of the present disclosure.

FIG. 45 shows a flow chart of a method for forming a circuit containing a pair of CMOS transistors having a common gate structure and one or more backside gate contacts, in accordance with some embodiments of the present disclosure.

FIGS. 46-63 illustrate cross-sectional views of a circuit containing a pair of CMOS transistors having a common gate structure during fabrication processes according to the method of FIG. 45, in accordance with some embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

The present disclosure generally relates to integrated circuit (IC) chips having transistors with backside interconnect structures, which include backside metal lines and backside contacts. More particularly, the present disclosure relates to transistors that share gate structures, wherein one or more backside gate contacts (also referred to as backside gate vias) are coupled to the gate structures from the backside of the semiconductor device.

A gate contact (also referred to as a gate via) provides electrical connectivity between a transistor's gate structure and a signal line for gate voltage control, which is within a multilayer interconnect structure. In conventional semiconductor devices, this multilayer interconnect structure is formed on the frontside of the device, overlying the source/drain contacts and gate contacts of the transistors. It includes metal routing layers that interconnect power and signal lines within and between transistors. As device dimensions continue to scale down, the metal lines within the frontside interconnect layers also shrink, resulting in increased resistance and voltage drop due to narrower widths and tighter pitches. To alleviate routing congestion and improve electrical performance, metal lines may additionally be formed on the backside of the semiconductor device as illustrated in the present disclosure. This dual-side interconnect approach by incorporating interconnect structures on both the frontside and backside can be referred to as a dual-side multilayer interconnect structure. The present disclosure further illustrates that gate contacts can be positioned on the frontside, the backside, or both. When gate contacts are formed on the backside, they are referred to as backside gate contacts in the context.

For transistors that share gate structures, incorporating backside gate contacts offers several manufacturing and performance advantages. First, because backside processing can be performed independently of frontside patterning constraints, it allows for improved control of critical dimensions (CD) and enlarged process windows for lithographic overlay, enhancing patterning accuracy and yield. Second, by relocating certain gate contacts to the backside, the frontside layout becomes less congested, enabling more efficient use of layout area and improving layout density. Third, the backside gate contact may be positioned underneath the channel region, which may suppress leakage current into the substrate. Fourth, the backside gate contact may block a dopant diffusion path between the shared gate structures of serially tied transistors and thus mitigate metal boundary effects (MBE). Last but not least, the backside gate contact can provide a more direct and less resistive path to the gate structures, thereby lowering the contact resistivity between the gate structures and the signal line for gate voltage control.

The details of the device structures disclosed herein are described with reference to the accompanying figures. Some exemplary embodiments are related to, but not otherwise limited to, multi-gate transistors. Multi-gate transistors have been introduced in an effort to improve gate control by increasing gate-channel coupling, reduce OFF-state current, and reduce short-channel effects (SCEs). One such multi-gate transistor that has been introduced is the fin-like field-effect transistor (FinFET). The FinFET gets its name from the fin-like structure which extends from a substrate on which it is formed, and which is used to provide the channel region. Another multi-gate transistor, introduced in part to address performance challenges associated with the FinFET, is the gate-all-around (GAA) transistor. The GAA transistor gets its name from the gate structure which can extend around the channel region (e.g., a stack of channel layers) providing access to the channel on four sides. The GAA transistor is compatible with conventional complementary metal-oxide-semiconductor (CMOS) processes and its structure allows it to be aggressively scaled while maintaining gate control and mitigating SCEs. The following disclosure will continue with FinFET examples and GAA examples in an exemplary inverter circuit to illustrate various embodiments of the present disclosure. It is understood, however, that the application should not be limited to a particular type of device, except as specifically claimed. For example, aspects of the present disclosure may also apply to circuits other than inverters.

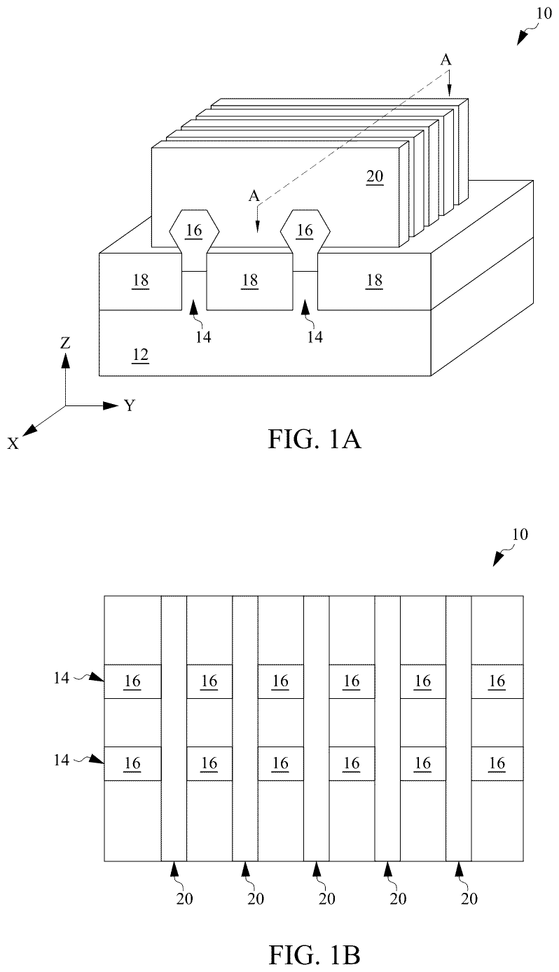

FIGS. 1A and 1B illustrate a perspective view and a top view, respectively, of a portion of an Integrated Circuit (IC) device 10, such as a standard (STD) cell array, implemented using multi-gate transistors, such as FinFET or GAA transistors. Referring to FIG. 1A, the IC device 10 includes a substrate 12. The substrate 12 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GalnAs, GaInP, GaInAsP, and/or other suitable materials. The substrate 12 may be a single-layer material having a uniform composition. Alternatively, the substrate 12 may include multiple material layers having similar or different compositions suitable for IC device manufacturing. In one example, the substrate 12 may be a silicon-on-insulator (SOI) substrate having a semiconductor silicon layer formed on a silicon oxide layer. In another example, the substrate 12 may include a conductive layer, a semiconductor layer, a dielectric layer, other layers, or combinations thereof. Various doped regions, such as source/drain regions, may be formed in or on the substrate 12. The doped regions may be doped with n-type dopants, such as phosphorus or arsenic, and/or p-type dopants, such as boron, depending on design requirements. The doped regions may be formed directly on the substrate 12, in a p-well structure, in an n-well structure, in a dual-well structure, or using a raised structure. Doped regions may be formed by implantation of dopant atoms, in-situ doped epitaxial growth, and/or other suitable techniques.

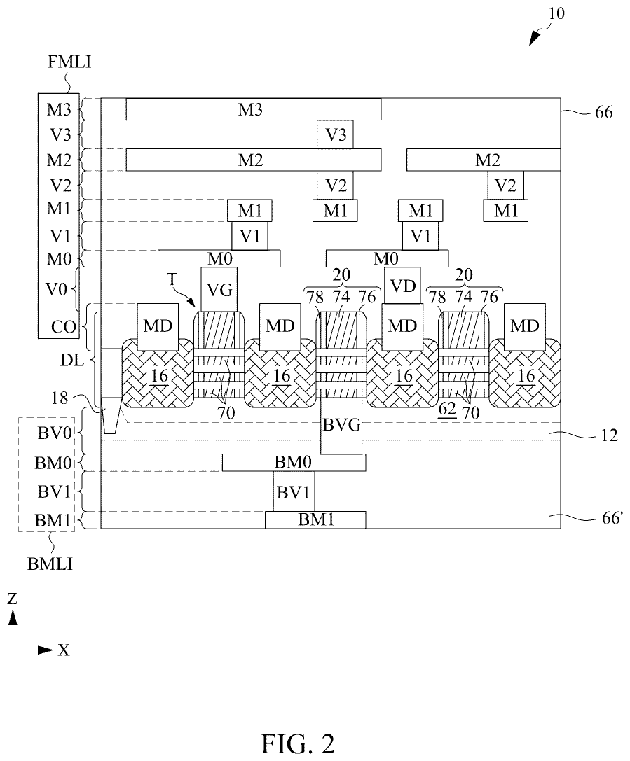

Three-dimensional active regions 14 are formed on the substrate 12. An active region for a transistor refers to the area where a source region, a drain region, and a channel region under a gate structure of the transistor are formed. An active region is also referred to as an “oxide-definition (OD) region” in the context. One active region may also provide source regions, drain regions, and channel regions for multiple transistors. In FinFETs, the active region 14 includes a fin-shaped structure protruding upwardly out of the substrate 12. In GAA transistors, the active region 14 includes elongated nanostructures 70 (as shown in FIG. 2) vertically stacked in channel regions defined in the active region and above a fin-shaped base. The fin-shaped base protrudes upwardly out of the substrate 12. Source/drain features 16 are formed in source/drain regions defined in the active region 14. The source/drain features 16 abut two opposing ends of the respective channel regions under the gate structures 20.

The IC device 10 further includes isolation structures (or isolation features) 18 formed over the substrate 12. The isolation structures 18 electrically separate various components of the IC device 10. The isolation structures 18 may include silicon oxide, silicon nitride, silicon oxynitride, fluoride-doped silicate glass (FSG), a low-k dielectric material, and/or other suitable materials. In some embodiments, the isolation structures 18 may include shallow trench isolation (STI) features. In one embodiment, the isolation structures 18 are formed by etching trenches in the substrate 12 during the formation of the active regions 14. The trenches may then be filled with an isolating material described above, followed by a chemical mechanical planarization (CMP) process. Other isolation structure such as field oxide, local oxidation of silicon (LOCOS), and/or other suitable structures may also be implemented as the isolation structures 18. Alternatively, the isolation structures 18 may include a multi-layer structure, for example, having one or more thermal oxide liner layers.

The IC device 10 also includes gate structures (or gate stacks) 20 formed over and engaging channel regions in the active regions 14. The gate structures 20 may be high-k metal gate (HKMG) structures that contain a high-k gate dielectric and a metal gate electrode, where the HKMG structures are formed by replacing dummy gate structures. Though not depicted herein, the gate structures 20 may include additional material layers, such as an interfacial layer, a capping layer, other suitable layers, or combinations thereof.

Referring to FIG. 1B, multiple active regions 14 are oriented lengthwise along the X-direction, and multiple gate structures 20 are oriented lengthwise along the Y-direction, i.e., generally perpendicular to the active regions 14. At intersections of the active regions 14 and the gate structures 20, transistors are formed. In many embodiments, the IC device 10 includes additional features such as gate spacers disposed along sidewalls of the gate structures 20, and numerous other features.

FIG. 2 is a fragmentary diagrammatic cross-sectional view (e.g., along the A-A line in FIG. 1A) of various layers (levels) that can be fabricated over and under a semiconductor substrate (or wafer) to form a portion of a memory device, such as IC chip 10 of FIGS. 1A and 1B, according to various aspects of the present disclosure. As represented in FIG. 2, the various layers include a device layer DL, a frontside multilayer interconnect structure FMLI disposed over the device layer, and a backside multilayer interconnect structure BMLI disposed under the device layer DL.

Device layer includes devices (e.g., transistors, resistors, capacitors, and/or inductors) and/or device components (e.g., doped wells, gate structures, and/or source/drain features). In embodiments represented by FIG. 2, the device layer includes substrate 12, doped regions 62 (e.g., n-wells and/or p-wells) disposed in substrate 12, isolation feature 18, and transistors T. In the depicted embodiment, transistors T are GAA transistors including suspended channel layers (also referred to as channel members) 70 in the form of nanostructures (e.g., nanowires or nanosheets) and gate structures 20 disposed between source/drain features 16, where gate structures 20 wrap and/or surround suspended channel layers 70. Alternatively, transistors T may be FinFETs including fin-shaped structures as channel regions. Each gate structure 20 has a metal gate stack formed from a gate electrode 74 disposed over a gate dielectric layer 76, together with gate spacers 78 disposed along sidewalls of the metal gate stack.

Multilayer interconnect structures FMLI and BMLI electrically couple various devices and/or components of device layer DL, such that the various devices and/or components can operate as specified by design requirements for the memory device. Each of the multilayer interconnect structures FMLI and BMLI may include one or more interconnect layers.

In the depicted embodiment, the frontside multilayer interconnect structure FMLI includes a contact interconnect layer (CO level), a via zero interconnect layer (V0 level), a metal zero interconnect layer (M0 level), a via one interconnect layer (V1 level), a metal one interconnect layer (M1 level), a via two interconnect layer (V2 level), a metal two interconnect layer (M2 level), a via three interconnect layer (V3 level), and a metal three interconnect layer (M3 level). Each of the CO level, V0 level, M0 level, V1 level, M1 level, V2 Level, M2 level, V3 level, and M3 level may be referred to as a metal level. Metal lines formed at the M0 level may be referred to as M0 metal lines. Similarly, via or metal lines formed at the V1 level, M1 level, V2 level, M2 level, V3 level, and M3 level may be referred to as V1 vias, M1 metal lines, V2 vias, M2 metal lines, V3 vias, and M3 metal lines, respectively. The present disclosure contemplates multilayer interconnect structure FMLI having more or less interconnect layers and/or levels, for example, a total number of N interconnect layers (levels) of the multilayer interconnect structure FMLI with N as an integer ranging from 1 to 10. Each level of multilayer interconnect structure FMLI includes conductive features (e.g., metal lines, metal vias, and/or metal contacts) disposed in one or more dielectric layers (e.g., an interlayer dielectric (ILD) layer and an etch stop layer (ESL)). The dielectric layers of the multilayer interconnect structure FMLI are collectively referred to as a dielectric structure 66. In some embodiments, conductive features at the same level of multilayer interconnect structure FMLI, such as M0 level, are formed simultaneously. In some embodiments, conductive features at the same level of multilayer interconnect structure FMLI have top surfaces that are substantially planar with one another and/or bottom surfaces that are substantially planar with one another.

In the depicted embodiment, the CO level includes source/drain contacts MD disposed in the dielectric structure 66. The source/drain contacts MD may be formed on and in direct contact with silicide layers disposed directly on the source/drain features 16. The V0 level may include gate contacts VG disposed on the gate structures and source/drain contact vias VD disposed on the source/drain contacts MD, where gate vias VG connect gate structures to M0 metal lines, source/drain vias VD connect source/drain contacts MD to M0 metal lines. In some embodiments, the V0 level may also include butted contacts disposed in the dielectric structure 66. The V1 level includes V1 vias disposed in the dielectric structure 66, where V1 vias connect M0 metal lines to M1 metal lines. M1 level includes M1 metal lines disposed in the dielectric structure 66. V2 level includes V2 vias disposed in the dielectric structure 66, where V2 vias connect M1 metal lines to M2 metal lines. M2 level includes M2 metal lines disposed in the dielectric structure 66. V3 level includes V3 vias disposed in the dielectric structure 66, where V3 vias connect M2 metal lines to M3 metal lines.

In the depicted embodiment, the backside multilayer interconnect structure BMLI includes a backside via zero interconnect layer (BV0 level), a backside metal zero level (BM0 level), a backside via one interconnect layer (BV1 level) and a backside metal one interconnect layer (BM1 level). Each of the BV0 level, BM0 level, BV1 level, and BM1 level may be referred to as a metal level. Metal lines formed at the BM0 level may be referred to as BM0 metal lines. Similarly, via or metal lines formed at the BV0 level, BV1 level, and BM1 level may be referred to as BV0 vias, BV1 vias, and BM1 metal lines, respectively. The present disclosure contemplates multilayer interconnect structure BMLI having more or less interconnect layers and/or levels, for example, a total number of M interconnect layers (levels) of the multilayer interconnect structure BMLI with M as an integer ranging from 1 to 10. Each level of multilayer interconnect structure BMLI includes conductive features (e.g., metal lines, metal vias, and/or metal contacts) disposed in one or more dielectric layers (e.g., an interlayer dielectric (ILD) layer and an etch stop layer (ESL)). The dielectric layers of the multilayer interconnect structure BMLI are collectively referred to as a backside dielectric structure 66′. In some embodiments, conductive features at a same level of the backside multilayer interconnect structure BMLI, such as BM0 level, are formed simultaneously. In some embodiments, conductive features at a same level of multilayer interconnect structure BMLI have top surfaces that are substantially planar with one another and/or bottom surfaces that are substantially planar with one another.

In the depicted embodiment, the BV0 level includes backside contacts formed under the device layer DL. For example, the backside contacts may include one or more backside gate contacts BVG formed directly under and in direct contact (or interfacing) with the gate structure(s) of the device layer DL. In some embodiments, the backside contacts may also include one or more backside source/drain contacts formed directly under the source/drain features of the device layer DL and coupled to those source/drain features by way of a silicide layer. The BM0 level includes BM0 metal lines formed under the BV0 level. The backside gate contacts connect gate structures to BM0 metal lines, and the backside source/drain contacts (if presented) connect source/drain features to BM0 metal lines. The BV1 level includes BV1 vias disposed in the backside dielectric structure 66′, where BV1 vias connect BM0 metal lines to BM1 metal lines. The BM1 level includes BM1 metal lines formed under the BV1 level.

FIG. 2 has been simplified for the sake of clarity to better understand the inventive concepts of the present disclosure. Additional features can be added in the various layers of the memory, and some of the features described can be replaced, modified, or eliminated in other embodiments of the memory. FIG. 2 is merely an example and may not reflect an actual cross-sectional view of the IC chip 10 and/or the standard cell array 100 that are described in further detail below.

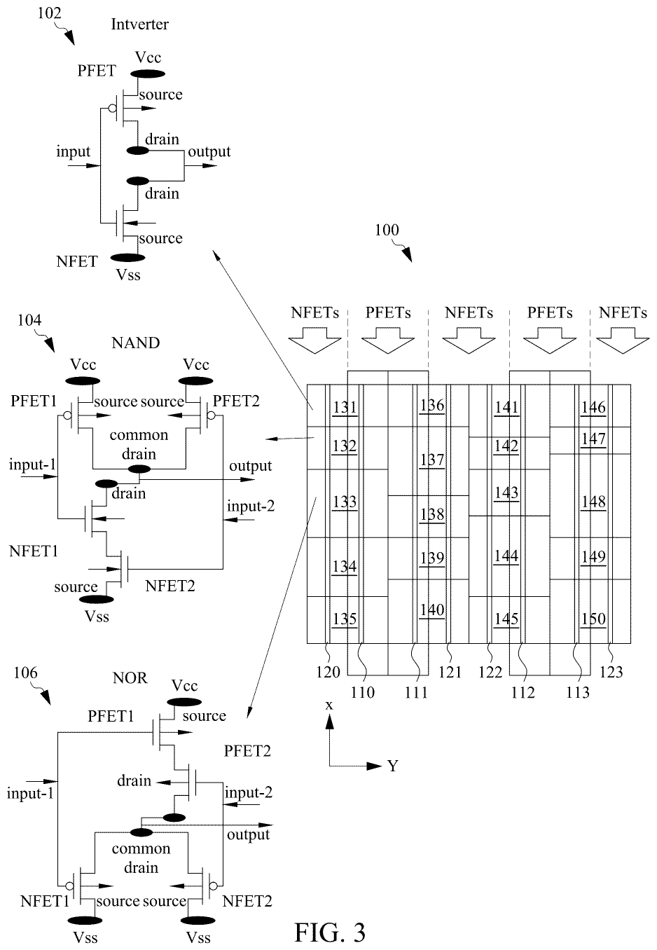

FIG. 3 illustrates a top view of a standard (STD) cells array according to embodiments of the present disclosure. The standard cells array 100 may include logic circuits or logic devices, and as such it is also referred to as a logic cells array or a logic circuit array. In various embodiments, the logic circuits or devices may include components such as inverters, NAND gates, NOR gates, flip-flops, or combinations thereof.

As illustrated in FIG. 3, the standard cells array 100 includes n-type field effect transistors (also known as NFETs) disposed on p-type wells and p-type field effect transistors (also known as PFETs) disposed on n-type wells. The standard cells array 100 also includes a plurality of elongated active regions, for example active regions 110, 111, 112, 113 as parts of the p-type transistors and active regions 120, 121, 122, 123 as parts of the n-type transistors. The active regions 110, 111, 112, 113 are located over n-type wells, and the active regions 120, 121, 122, 123 are located over p-type wells.

As an example, the standard cells array 100 shown herein includes 20 standard cells 131 through 150, where the cells 131 through 135 are arranged into a first column, the cells 136 through 140 are arranged into a second column adjacent to the first column, the cells 141 through 145 are arranged into a third column adjacent to the second column, and the cells 146 through 150 are arranged into a fourth column adjacent to the third column. The active regions 110 to 113 and 120 to 123 each extend through a respective column of the standard cells (e.g., active regions 110 and 120 extending through the standard cells 131 to 135, active regions 111 and 121 extending through the standard cells 136 to 140, active regions 122 and 112 extending through the standard cells 141 to 145, and active regions 113 and 123 extending through the standard cells 146 to 150) in the X-direction (X-direction of FIG. 1A). FIG. 3 merely illustrates an example of the standard cells array 100, and other embodiments may have different numbers of cells and/or may be arranged differently.

FIG. 3 also illustrates several circuit schematics of some common logic gates built using complementary metal-oxide semiconductor (CMOS) transistors, such as an inverter 102, a NAND 104, and a NOR 106. The logic gates, such as the inverter 102, the NAND 104, and the NOR 106, each include one or more n-type transistors and one or more p-type transistors. The particular type of logic gate is determined by coupling the gate, source, and drain of the n-type transistors and p-type transistors in a specific configuration, such as shown in FIG. 3. The input terminal and output terminal of each logic gate is also labeled in FIG. 3 as such. In some embodiments, the standard cell 131 can be an inverter, the standard cell 132 can be a NAND, and the standard cell 133 can be a NOR.

The illustrated standard cells each have at least a pair of CMOS transistors with their gates coupled together. For example, in the inverter 102, the gates of the NFET and PFET are coupled to each other; in the NAND 104, the gates of the NFET1 and PFET1 are coupled to each other, and the gates of the NFET2 and PFET2 are coupled to each other; and in the NOR 106, the gates of the NFET1 and PFET1 are coupled to each other, and the gates of the NFET2 and PFET2 are coupled to each other.

Taking the inverter 102 as an example, the operation of a pair of CMOS transistors is further discussed below. An inverter's primary function is to invert the input signal, such as converting a logical high signal (“1”) to a logical low (“0”), or vice versa. The inverter 102 includes one p-type transistor (PFET) functioning as a pull-up transistor and one n-type transistor (NFET) functioning as a pull-down transistor. The pull-up transistor and the pull-down transistor are configured in series between two power rails, namely the positive supply voltage (also denoted as Vcc) and the ground (also denoted as Vss).

The gates of the PFET and the NFET are coupled to each other and connected directly to the inverter's input node. The PFET, situated at the top in the schematic, acts as the pull-up transistor. Its source terminal is connected to Vcc, while its drain terminal is connected to the inverter's output node. Because the PFET is turned on by a logic low input, it acts to pull the output node up to Vcc when the input signal is low.

The NFET, located below the PFET in the schematic, acts as the pull-down transistor. Its source terminal connects directly to the ground Vss, and its drain connects to the same output node as the PFET. The gate of the NFET also receives the inverter's input signal. Unlike the PFET, the NFET switches on with a logical high input, pulling the output node down to Vss when the input signal is high.

When a logical high voltage is applied to the input node, the NFET activates, creating a conducting path between the output node and ground. The PFET simultaneously turns off because its gate is at a high potential relative to its source, disconnecting the output from Vcc. Consequently, the output node is driven low. Conversely, when input node is low, the NFET switches off, disconnecting the output node from the ground. Meanwhile, the PFET activates, pulling the output node up to Vcc, thus generating a logical high at the output node.

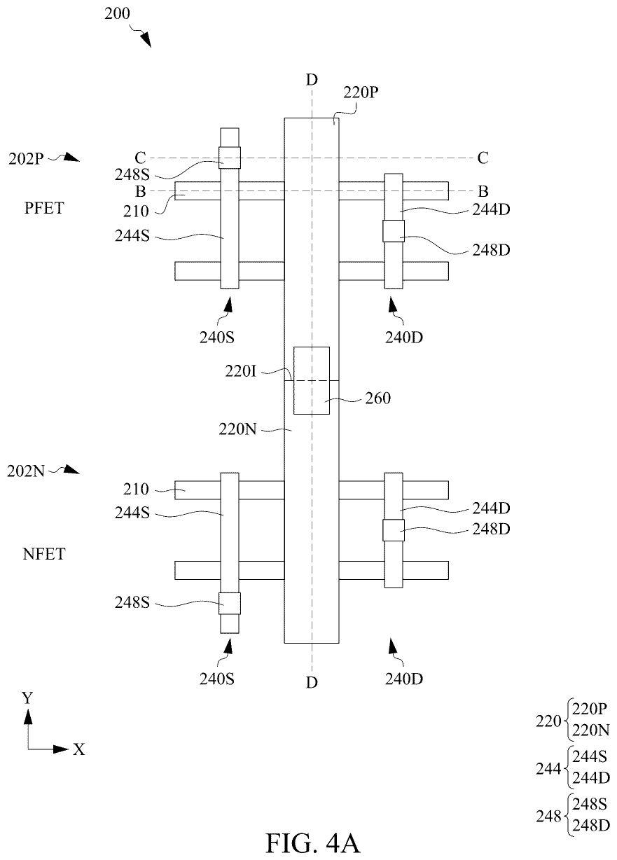

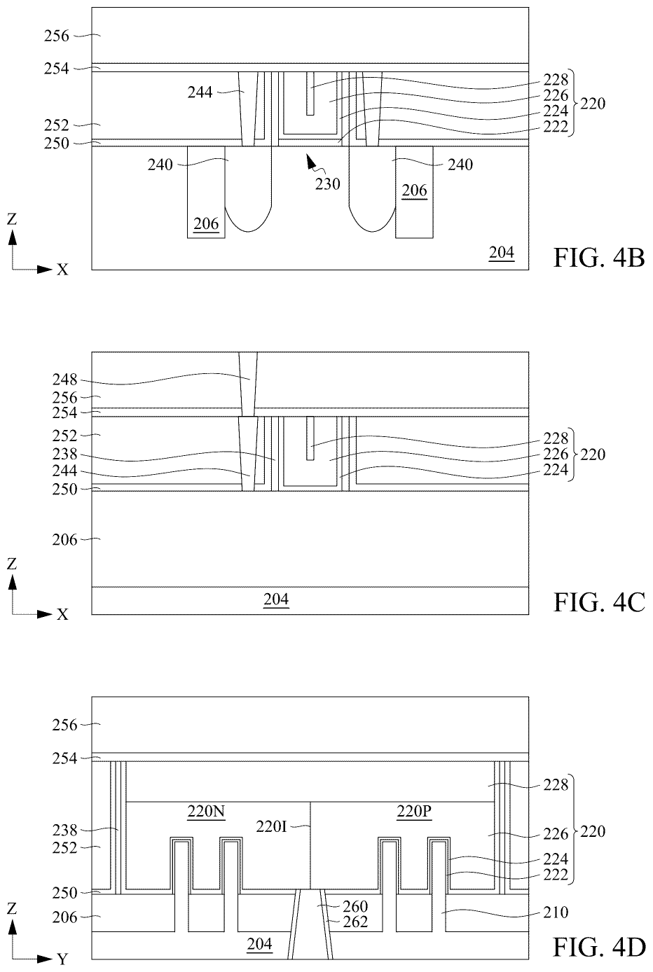

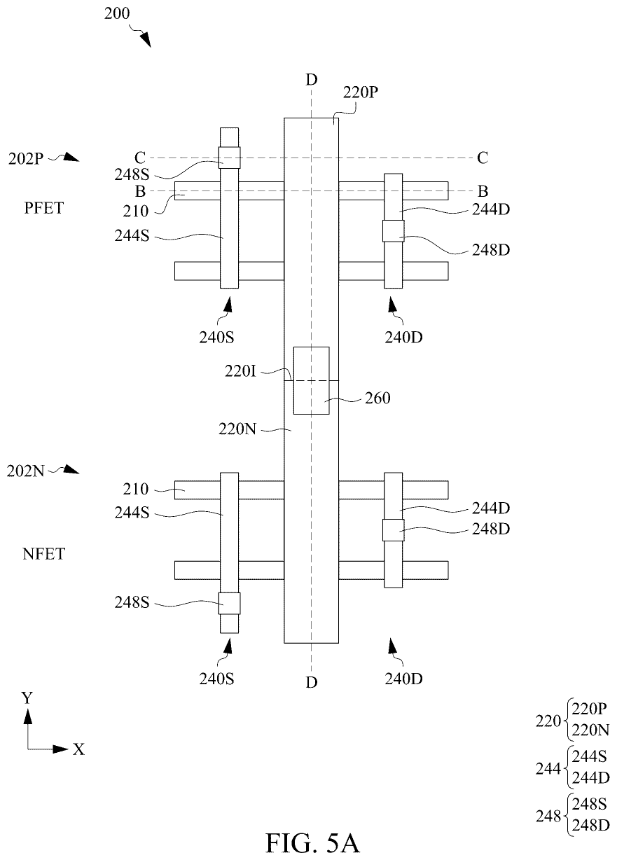

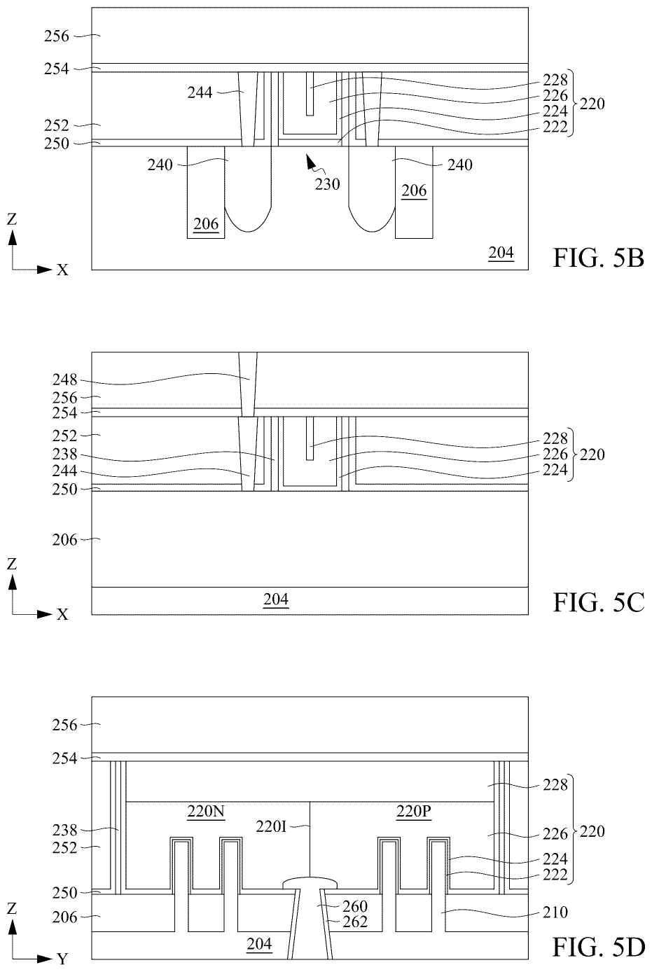

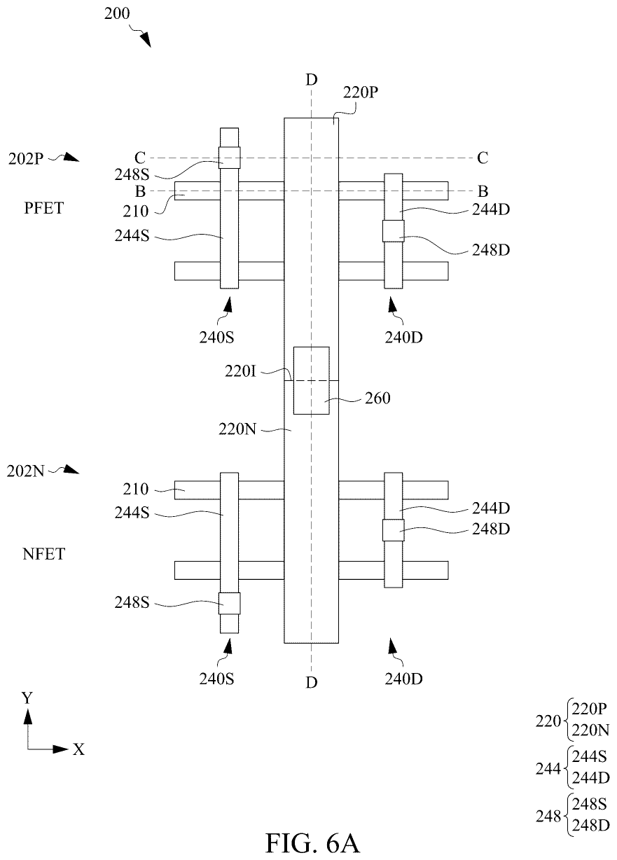

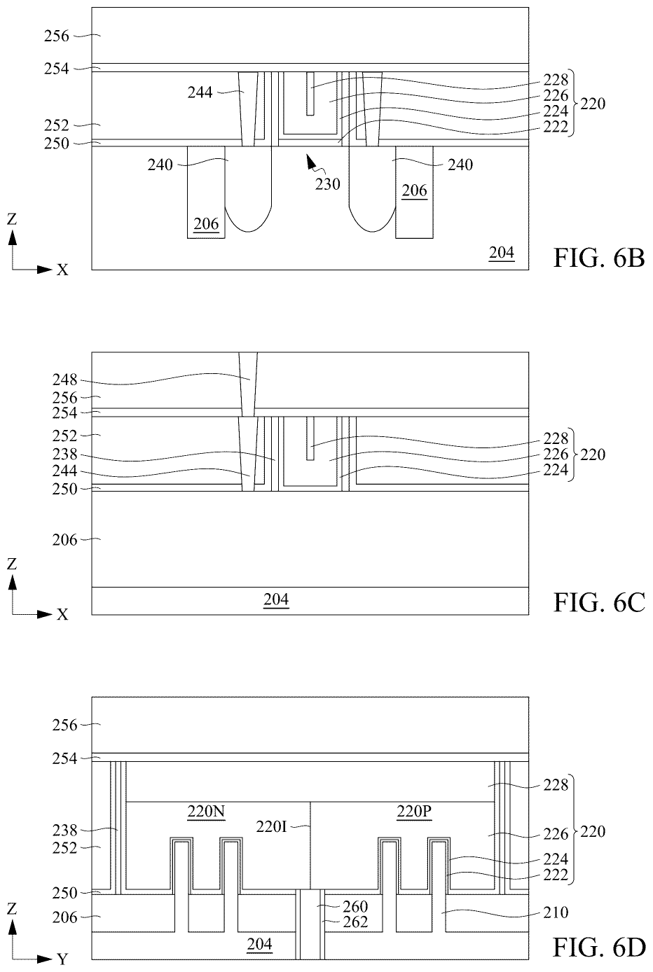

Reference is now made to FIGS. 4A-4D, which illustrate top and cross-sectional views of an embodiment of a semiconductor device (or device) 200 that includes a pair of CMOS transistors with gate structures coupled to each other in the context of FinFET construction. The device 200 may be a portion of an IC chip, a system on chip (SoC), or portion thereof, that includes various passive and active microelectronic devices such as resistors, capacitors, inductors, diodes, bipolar junction transistors (BJTs), NFETs, PFETs, memory devices, other suitable components, or combinations thereof. FIG. 4A illustrates the top view of a portion of the device 200, and FIGS. 4B, 4C, 4D correspond to cross-sectional views along B-B, C-C, D-D lines in FIG. 4A, respectively. Particularly, the B-B line is cut along the lengthwise direction (X-direction) of one of the active regions 210, the C-C line is parallel to the B-B line and cut into an isolation region (or STI region) outside of two adjacent active regions 210, and the D-D line is cut along the lengthwise direction (Y-direction) of the gate structures 220N and 220P. Unless otherwise specified, these cross-sectional view definitions are consistently applied in the cross-sectional views of subsequent figure sets, such as FIGS. 5A-5D, 6A-6D, and so forth. The illustrated portion of the device 200 may be part of an inverter, a NAND, a NOR, and other logic circuits in a standard cells array, such as the standard cells array 100 in FIG. 3.

The device 200 includes at least an NFET 202N and a PFET 202P. The NFET 202N is formed over a p-type well and resides at an intersection region where the gate structure 220N crosses its corresponding active regions 210. Similarly, the PFET 202P is formed over an n-type well and resides at an intersection region where the gate structure 220P crosses its corresponding active regions 210. The gate structures 220N and 220P extend longitudinally along the Y-direction and meet at an interface 220I. Thus, the gate structures 220N and 220P may also be considered as two segments of a single, continuous gate structure 220. The gate structure 220 is also referred to as a common gate structure 220. Each active region 210 defines a channel region 230 positioned between two source/drain regions (or source/drain features) 240. The source/drain regions 240 includes a source region 240S and a drain region 240D. In the illustrated embodiment, each active region 210 is configured as a semiconductor fin (hereafter also referred to simply as “fin”). The number of fins 210 implemented in a transistor directly influences the transistor's strength, such that an increase in the number of fins 210 corresponds to enhanced transistor's strength. For illustration purposes, FIG. 4A depicts the PFET 202P and NFET 202N each having two fins 210; however, this configuration is not intended to limit the scope of the disclosure beyond what is explicitly recited in the claims. It should be understood that the number of fins 210 may vary and can be independently determined for NFET 202N and PFET 202P as needed.

Still referring to FIGS. 4A-4D collectively, the device 200 includes substrate 204 at its backside and various elements built on the front surface of the substrate 204. These elements include an isolation structure (such as a shallow trench isolation (STI) feature) 206 over the substrate 204, fins 210 protruding upwardly from the substrate 204 and through the isolation structure 206, source/drain features 240 over the fins 210, gate structure 220 between the source/drain features 240. The device 200 further includes gate spacers 238 over sidewalls of the gate structure 220, a first contact etch stop layer (CESL) 250 adjacent to the gate spacers 238 and over the source/drain features 240 and the isolation structure 206, a first inter-layer dielectric (ILD) layer 252 over the first CESL 250, a second CESL 254 over the first ILD layer 252 and the gate structure 220, and a second ILD layer 256 over the second CESL 254. Over the source/drain features 240, the device 200 further includes source/drain contacts 244, including source contact 244S over the source region 240S and drain contact 244D over the drain region 240D. Although not depicted, stacked between the source/drain features 240 and the source/drain contacts 244, the device 200 may include a silicide feature, which reduces contact resistance therebetween. Over the source/drain contacts 244, the device 200 further includes source/drain contact vias 248, including source contact via 248S over the source contact 244S and drain contact via 248D over the drain contact 244D. In the depicted embodiment, the source contact 244S has a length measured in Y-direction greater than that of the drain contact 244D; the drain contact via 248D is positioned between two adjacent fins 210, and the source contact via 248S is positioned on the same side of the fins 210 and distant away from the other transistor. The arrangement for the source/drain contacts 244 and the source/drain contact vias 248 is not arbitrary nor trivial but for the benefits of layout efficiency, routing convenience, and device performance.

In some embodiments, the substrate 204 is a bulk silicon substrate (i.e., including bulk single-crystalline silicon). The substrate 204 may include other semiconductor materials in various embodiment, such as germanium, silicon carbide, gallium arsenide, gallium phosphide, indium phosphide, indium arsenide, indium antimonide, SiGe, GaAsP, AlInAs, AlGaAs, GaInAs, GaInP, GaInAsP, or combinations thereof. In an alternative embodiment, substrate 204 is a semiconductor-on-insulator substrate, such as a silicon-on-insulator (SOI) substrate, a silicon germanium-on-insulator (SGOI) substrate, or a germanium-on-insulator (GOI) substrate.

In some embodiments, the fins 210 may include silicon, silicon germanium, germanium, or other suitable semiconductor, and may be doped n-type or p-type dopants. The fins 210 may be patterned by any suitable method. For example, the fins 210 may be patterned using one or more photolithography processes, including double-patterning or multi-patterning processes.

In some embodiments, the isolation structure 206 may include silicon oxide, silicon nitride, silicon oxynitride, other suitable isolation material (for example, including silicon, oxygen, nitrogen, carbon, or other suitable isolation constituent), or combinations thereof. The isolation structure 206 can include different structures, such as shallow trench isolation (STI) features and/or deep trench isolation (DTI) features. In some embodiments, the isolation structure 206 comprises a dielectric constant between about 3 and about 5. In an embodiment, the isolation structure 206 can be formed by filling the trenches between fins 210 with insulator material (for example, by using a CVD process or a spin-on glass process), performing a chemical mechanical polishing (CMP) process to remove excessive insulator material and/or planarize a top surface of the insulator material layer, and etching back the insulator material layer to form the isolation structure 206. In some embodiments, the isolation structure 206 includes multiple dielectric layers, such as a silicon nitride layer disposed over a thermal oxide liner layer.

In some embodiments, the gate structure 220 includes an interfacial layer 222, a high-k dielectric layer 224 disposed on the interfacial layer 222, and a gate electrode layer 226 disposed on the high-k dielectric layer 224. The gate structure 220 may also include a metal fill layer 228. The interfacial layer 222 may include a dielectric material such as silicon oxide, hafnium silicate, or silicon oxynitride. The interfacial layer 222 may be formed by chemical oxidation, thermal oxidation, atomic layer deposition (ALD), chemical vapor deposition (CVD), and/or other suitable method. Notably, in the illustrated embodiment, the interfacial layer 222 is selectively formed on semiconductor surfaces but not on dielectric surfaces. Thus, the inner sidewalls of the gate spacers 238 and the top surface of the isolation structure 206 may be free of the interfacial layer 222. The high-k dielectric layer 224 may include a high-k dielectric material such as HfO₂, HfSiO, HfSiO₄, HfSiON, HfLaO, HfTaO, HfTiO, HfZrO, HfAlOₓ, ZrO, ZrO₂, ZrSiO₂, AlO, AlSiO, Al₂O₃, TiO, TiO₂, LaO, LaSiO, Ta₂O₃, Ta₂O₅, Y₂O₃, SrTiO₃, BaZrO, BaTiO₃ (BTO), (Ba,Sr)TiO₃ (BST), Si₃N₄, hafnium dioxide-alumina (HfO₂-Al₂O₃) alloy, other suitable high-k dielectric material, or combinations thereof. High-k dielectric material generally refers to dielectric materials having a high dielectric constant, for example, greater than that of silicon oxide (k≈3.9). The high-k gate dielectric layer 224 may be formed by chemical oxidation, thermal oxidation, atomic layer deposition (ALD), chemical vapor deposition (CVD), and/or other suitable methods. The interfacial layer 222 and the high-k dielectric layer 224 may collectively be referred to as a gate dielectric layer. A dielectric constant of the gate dielectric layer is greater than a dielectric constant of the gate spacers 238.

In some embodiments, the gate electrode layer 226 may include an n-type or a p-type work function layer. For example, the gate electrode layer 226 in the NFET 202N includes an n-type work function layer. The n-type work function layer may comprise a metal with sufficiently low effective work function such as titanium, aluminum, tantalum carbide, tantalum carbide nitride, tantalum silicon nitride, or combinations thereof. The gate electrode layer 226 in the PFET 202P includes a p-type work function layer. The p-type work function layer may comprise a metal with a sufficiently large effective work function, such as titanium nitride, tantalum nitride, ruthenium, molybdenum, tungsten, platinum, or combinations thereof. The gate electrode layer 226 may be formed by CVD, PVD, plating, and/or other suitable processes. In some embodiments, the metal fill layer 228 may include aluminum, tungsten, cobalt, copper, and/or other suitable materials. As depicted in FIG. 4D, the metal fill layer 228 extends across the interface 220I between the gate structures 220N and 220P. The gate structures 220N and 220P are electrically connected to each other through the interface 220I and the metal fill layer 228. Since the gate structure includes a high-k dielectric layer and metal layer(s), it is also referred to as a high-k metal gate (HKMG).

In some embodiments, the gate spacers 238 include a dielectric material such as a dielectric material including silicon, oxygen, carbon, nitrogen, other suitable material, or combinations thereof (e.g., silicon oxide, silicon nitride, silicon oxynitride (SiON), silicon carbide, silicon carbon nitride (SiCN), silicon oxycarbide (SiOC), silicon oxycarbon nitride (SiOCN)). In embodiments, the gate spacers 238 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s). For example, a dielectric layer including silicon and nitrogen, such as a silicon nitride layer, can be deposited over a dummy gate stack (which is subsequently replaced by the high-k metal gate) and subsequently etched (e.g., anisotropically etched) to form the gate spacers 238. In some embodiments, the gate spacers 238 include a multi-layer structure, such as a first dielectric layer that includes silicon nitride and a second dielectric layer that includes silicon oxide. In some embodiments, more than one set of spacers, such as seal spacers, offset spacers, sacrificial spacers, dummy spacers, and/or main spacers, are formed adjacent to the gate structure 220. A thickness of the gate spacers 238 is greater than a thickness of the gate dielectric layer.

In some embodiments, the source/drain features 240 may include epitaxially grown semiconductor materials such as epitaxially grown silicon, germanium, or silicon germanium. The source/drain features 240 can be formed by any epitaxy processes including chemical vapor deposition (CVD) techniques (for example, vapor phase epitaxy and/or Ultra-High Vacuum CVD), molecular beam epitaxy, other suitable epitaxial growth processes, or combinations thereof. The source/drain features 240 may be doped with n-type dopants and/or p-type dopants. In some embodiments, for NFET 202N, the source/drain features 240 include silicon and can be doped with carbon, phosphorous, arsenic, other n-type dopant, or combinations thereof (for example, forming Si:C epitaxial features, Si:P epitaxial features, or Si:C:P epitaxial features). In some embodiments, for PFET 202P, the source/drain features 240 include silicon germanium or germanium, and can be doped with boron, other p-type dopant, or combinations thereof (for example, forming Si:Ge:B epitaxial features). The source/drain features 240 may include multiple epitaxial semiconductor layers having different levels of dopant density. In some embodiments, annealing processes (e.g., rapid thermal annealing (RTA) and/or laser annealing) are performed to activate dopants in the source/drain features 240.

In some embodiments, the source/drain contacts 244 may include a conductive barrier layer and a metal fill layer over the conductive barrier layer. The conductive barrier layer may include titanium (Ti), tantalum (Ta), tungsten (W), cobalt (Co), ruthenium (Ru), or a conductive nitride such as titanium nitride (TiN), titanium aluminum nitride (TiAlN), tungsten nitride (WN), tantalum nitride (TaN), or combinations thereof, and may be formed by CVD, PVD, ALD, and/or other suitable processes. The metal fill layer may include tungsten (W), cobalt (Co), molybdenum (Mo), ruthenium (Ru), nickel (Ni), copper (Cu), or other metals, and may be formed by CVD, PVD, ALD, plating, or other suitable processes. In some embodiments, the conductive barrier layer is omitted in the source/drain contacts 244. In furtherance of some embodiments, the device 200 includes a silicide feature vertically stacked between the source/drain features 240 and the source/drain contacts 244. The silicide feature may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds. The silicide feature reduces the contact resistance between the source/drain features 240 and the source/drain contacts 244.

In some embodiments, either of the first CESL 250 and the second CESL 254 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s); and may be formed by CVD, PVD, ALD, or other suitable methods. The first CESL 250 and the second CESL 254 may include the same or different compositions. Either of the first ILD layer 252 and the second ILD layer 256 may comprise tetraethylorthosilicate (TEOS) oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof; and may be formed by plasma enhanced CVD (PE-CVD), flowable CVD (F-CVD), or other suitable methods. The first ILD layer 252 and the second ILD layer 256 may include the same or different compositions.

In some embodiments, the source/drain contact vias 248 may include a conductive barrier layer and a metal fill layer over the conductive barrier layer. The conductive barrier layer may include titanium (Ti), tantalum (Ta), tungsten (W), cobalt (Co), ruthenium (Ru), or a conductive nitride such as titanium nitride (TiN), titanium aluminum nitride (TiAlN), tungsten nitride (WN), tantalum nitride (TaN), or combinations thereof, and may be formed by CVD, PVD, ALD, and/or other suitable processes. The metal fill layer may include tungsten (W), cobalt (Co), molybdenum (Mo), ruthenium (Ru), nickel (Ni), copper (Cu), or other metals, and may be formed by CVD, PVD, ALD, plating, or other suitable processes. In some embodiments, the conductive barrier layer is omitted in the source/drain contact vias 248.

The device 200 further includes a backside gate contact 260 formed in the BV0 level (FIG. 2) and electrically connecting the gate structure 220 to a BM0 metal line formed in the BM0 level (FIG. 2). In some embodiments, backside gate contacts are the only backside vias formed in the BV0 level, while source/drain contacts are all formed in the frontside of the device 200. In some embodiments, besides the backside gate contacts, the backside vias formed on the BV0 level may also include one or more backside source/drain contacts formed directly under the source/drain features and coupled to those source/drain features by way of a backside silicide layer. In some embodiments, all the gate structures 220 are coupled to metal lines solely through the backside gate contacts 260. In some embodiments, some of the gate structures 220 are still coupled to metal lines through frontside gate contacts due to routing constraints. In some embodiments, a gate structure 220 may include both a frontside gate contact coupled to a frontside M0 metal line and a backside gate contact 260 coupled to a backside BM0 metal line for reducing routing resistance by leveraging dual gate contacts for one gate structure.

The backside gate contact 260 may include a conductive barrier layer and a metal fill layer over the conductive barrier layer. The conductive barrier layer may include titanium (Ti), tantalum (Ta), tungsten (W), cobalt (Co), ruthenium (Ru), or a conductive nitride such as titanium nitride (TiN), titanium aluminum nitride (TiAlN), tungsten nitride (WN), tantalum nitride (TaN), or combinations thereof, and may be formed by CVD, PVD, ALD, and/or other suitable processes. The metal fill layer may include tungsten (W), cobalt (Co), molybdenum (Mo), ruthenium (Ru), nickel (Ni), copper (Cu), or other metals, and may be formed by CVD, PVD, ALD, plating, or other suitable processes. In some embodiments, the conductive barrier layer is omitted in the backside gate contact 260.

The device 200 may further include a dielectric liner 262 on sidewalls of the backside gate contact 260. The dielectric liner 262 separates the backside gate contact 260 from interfacing the substrate 204 and blocks the diffusion of metal elements in the backside gate contact 260 into the substrate 204. The dielectric liner 262 may include SiN, SiOCN, SiOC, SiCN, SiO₂, SiC, ZnO, ZrN, Zr₂Al₃O₉, TiO₂, TaO₂, ZrO₂, HfO₂, Y₂O₃, La₂O₃, Al₂O₃, AlON, TaCN, ZrSi, combinations thereof, or other suitable material(s). The dielectric liner 262 may be deposited using ALD, CVD, or other suitable methods. In some embodiments, the dielectric liner 262 is conformally deposited to form a substantially uniform thickness along the various surfaces of a backside opening, which is configured to accommodate the backside gate contact 260. A breakthrough (BT) etching process is then performed to remove the horizontal portions of the dielectric liner 262. Following the BT etching, the dielectric liner 262 remains on the sidewalls of the backside opening. The backside gate contact 260 is subsequently deposited into the backside opening.

Referring to FIGS. 4A and 4D, in the depicted embodiment, the backside gate contact 260 is positioned directly under the interface 220I between the gate structures 220N and 220P. Further, the backside gate contact 260 breaks through the high-k dielectric layer 224 and interfaces the bottom surfaces of the gate structures 220N and 220P. The dielectric liner 262 also interfaces with the high-k dielectric layer 224. By breaking the high-k dielectric layer 224 along the interface 220I, the device performance regarding metal boundary effect (BME) is improved. This is because the high-k dielectric layer 224 provides a transfer path of some metal elements (such as Al) from n-type metal gate to p-type metal gate, which is now choked by the formation of the backside gate contact 260. In the depicted embodiment in FIG. 4A, a width (along the X-direction) of a top surface of the backside gate contact 260 interfacing the bottom surface of the gate structure 220 is narrower than a width of the gate structure 220. Alternatively, this width (along the X-direction) of the backside gate contact 260 may be the same or even wider than the width of the gate structure 220, such that the high-k dielectric layer 224 is fully cut off at the bottom surface of the gate structure 220. In the depicted embodiment in FIG. 4D, the backside gate contact 260 has slanted sidewalls (tapered profile). In the Y-Z plane, the width (along the Y-direction) of the backside gate contact 260 gradually narrows from its wider base portion embedded within the substrate 204 toward its narrower upper portion, which may be due to loading effect during a backside etching process in creating a backside opening through the substrate 204 for accommodating the backside gate contact 260. In the depicted embodiment, in the Y-Z plane, the largest width (along the Y-direction) of the backside gate contact 260 is greater than a width of the active regions 210. Alternatively, in the Y-Z plane, the largest width (along the Y-direction) of the backside gate contact 260 may be equal to or smaller than a width of the active regions 210.

Reference is now made to FIGS. 5A-5D, which illustrate top and cross-sectional views of another embodiment of the device 200 that includes a pair of CMOS transistors with gate structures coupled to each other in the context of FinFET construction. Many aspects of the device 200 as depicted in FIGS. 5A-5D are the same as or similar to those counterparts depicted in FIGS. 4A-4D. Reference numerals are repeated for ease of understanding. Such same or similar aspects are not repeated in the interest of conciseness. Some differences are discussed below.

In the depicted embodiment as shown in FIG. 5D, the backside gate contact 260 has slanted sidewalls with tapered profile and further has a flange-like top portion. The curvature top surface of the flange-like top portion increases the contact area between the backside gate contact 260 and the gate structure 220 and thus reduces contact resistance. Specifically, after penetrating the isolation structure 206 and the high-k dielectric layer 224, the backside gate contact 260 increases in its width, forming a horizontally extended, flange-like region in its uppermost end, resulting in a distinct T-shaped or mushroom-shaped cross-sectional profile. In the illustrated embodiment, this upper expanded portion has a width greater than that of the lower region embedded in the isolation structure 206 but less than that of the lowest portion embedded in the substrate 204. Alternatively, the largest width of the whole backside gate contact 260 may reside in its flange-like region above the high-k dielectric layer 224. The flange-like region may be created by an over-etching process after the BT etching process in forming the dielectric liner 262 to create an expanded cavity above the high-k dielectric layer 224 and subsequently depositing the backside gate contact 260 into the backside opening and the expanded cavity. In the depicted embodiment, the dielectric liner 262 does not extend above the high-k dielectric layer 224.

Reference is now made to FIGS. 6A-6D, which illustrate top and cross-sectional views of another embodiment of the device 200 that includes a pair of CMOS transistors with gate structures coupled to each other in the context of FinFET construction. Many aspects of the device 200 as depicted in FIGS. 6A-6D are the same as or similar to those counterparts depicted in FIGS. 4A-4D. Reference numerals are repeated for ease of understanding. Such same or similar aspects are not repeated in the interest of conciseness. One difference is that the backside gate contact 260 as depicted in FIG. 6D has substantially straight sidewalls. In other words, the backside gate contact 260 may have a uniform width from top to bottom, which may be due to a highly directional etching process applied in creating the backside opening that accommodates the backside gate contact 260. In the depicted embodiment, the width of the backside gate contact 260 is greater than a width of the active regions 210. Alternatively, the width of the backside gate contact 260 may be equal to or smaller than a width of the active regions 210.

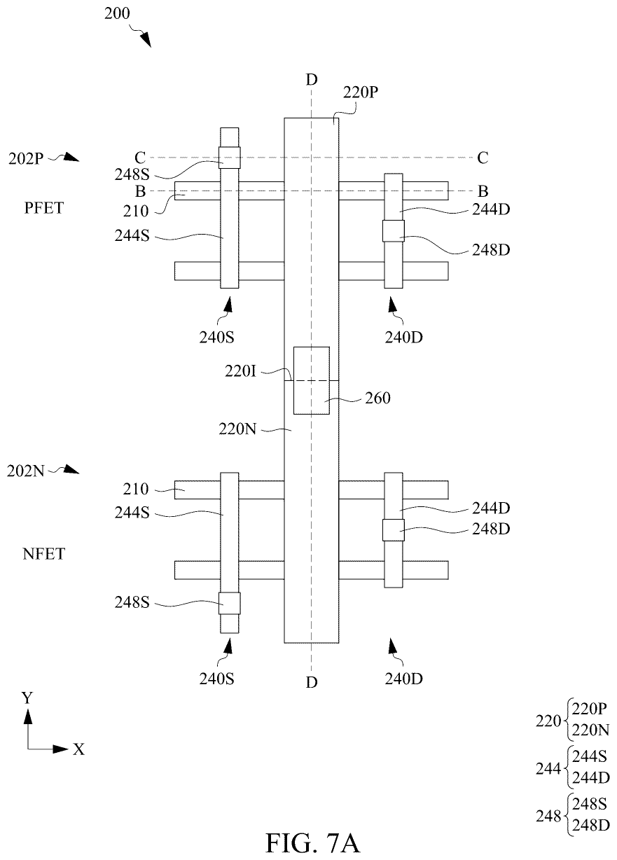

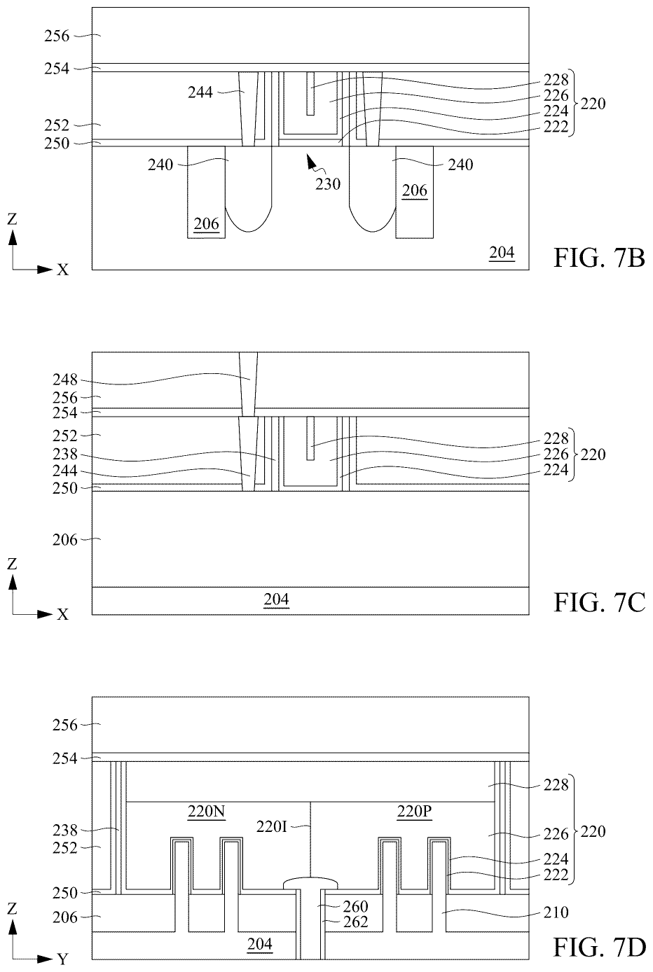

Reference is now made to FIGS. 7A-7D, which illustrate top and cross-sectional views of another embodiment of the device 200 that includes a pair of CMOS transistors with gate structures coupled to each other in the context of FinFET construction. Many aspects of the device 200 as depicted in FIGS. 7A-7D are the same as or similar to those counterparts depicted in FIGS. 5A-5D. Reference numerals are repeated for ease of understanding. Such same or similar aspects are not repeated in the interest of conciseness. One difference is that the backside gate contact 260 as depicted in FIG. 7D has substantially straight sidewalls. In other words, the backside gate contact 260 may have a uniform width from top to bottom, which may be due to a highly directional etching process applied in creating the backside opening that accommodates the backside gate contact 260.

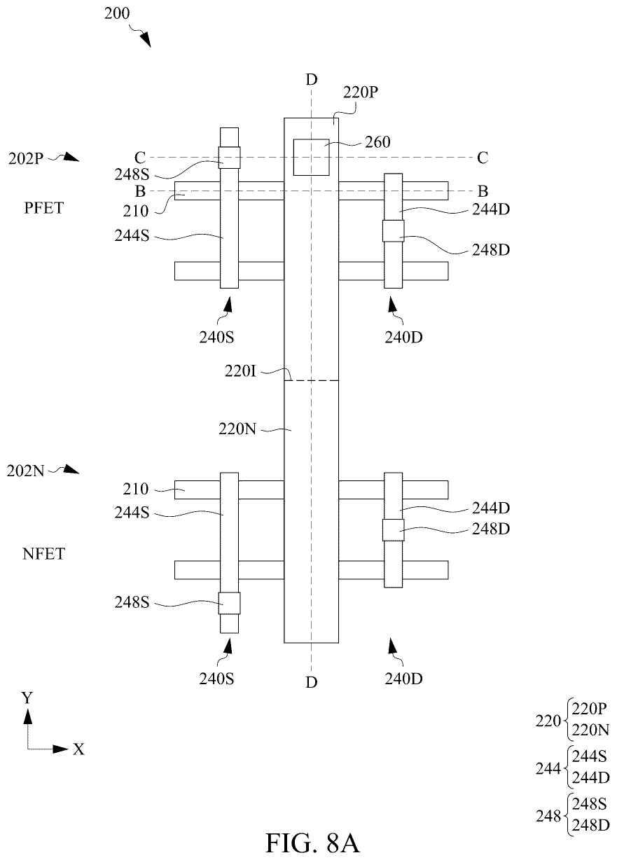

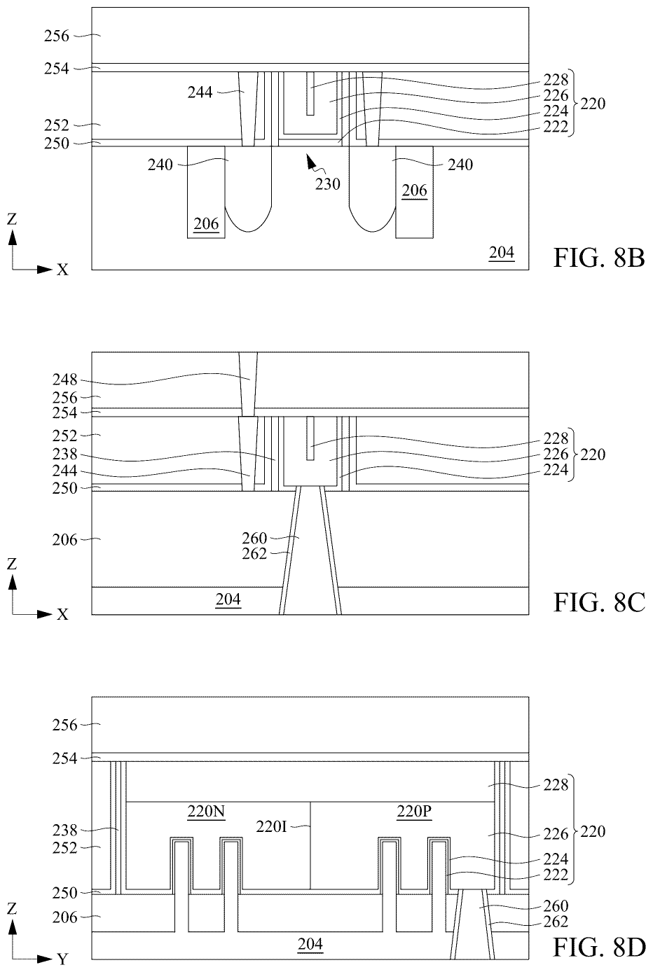

Reference is now made to FIGS. 8A-8D, which illustrate top and cross-sectional views of another embodiment of the device 200 that includes a pair of CMOS transistors with gate structures coupled to each other in the context of FinFET construction. Many aspects of the device 200 as depicted in FIGS. 8A-8D are the same as or similar to those counterparts depicted in FIGS. 4A-4D. Reference numerals are repeated for ease of understanding. Such same or similar aspects are not repeated in the interest of conciseness. One difference is that the backside gate contact 260 as depicted in FIGS. 8A and 8D is positioned at a location outside the fins 210, such that the backside gate contact 260 is positioned on the same side of all the fins 210, rather than interleaved between them. Since the region outside the fins 210 may provide a larger area for routing, positioning the backside gate contact 260 offset from the fins 210 can enlarge the process window for overlay control. In the depicted embodiment, the backside gate contact 260 and the source contact via 248S is aligned along the C-C line. FIGS. 8A and 8C also depict the backside gate contact 260 having a larger width than either the source/drain contact 244 or the source/drain contact via 248 due to the less routing density on the backside of the device 200, which effectively reduces the gate contact resistance.

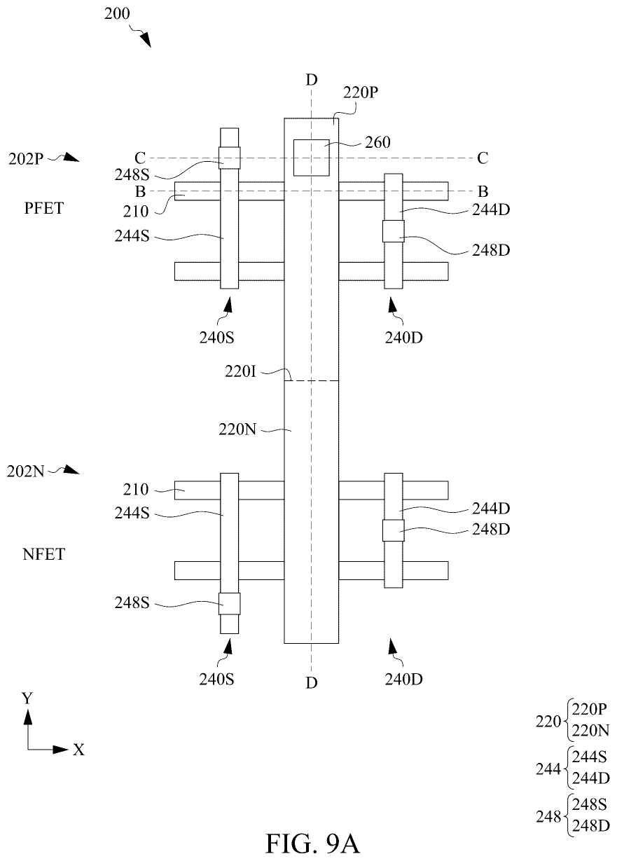

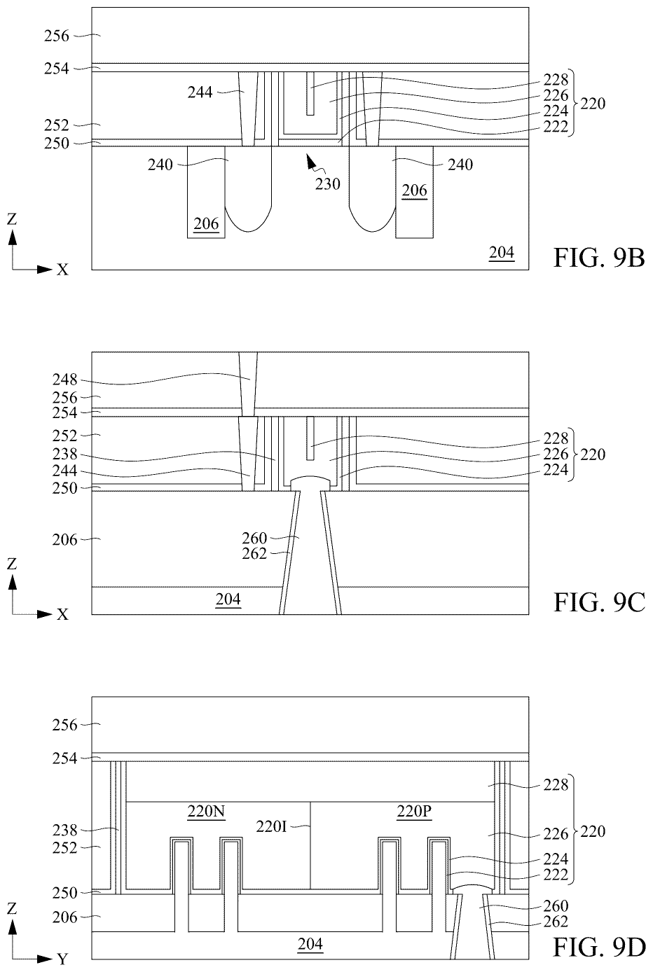

Reference is now made to FIGS. 9A-9D, which illustrate top and cross-sectional views of another embodiment of the device 200 that includes a pair of CMOS transistors with gate structures coupled to each other in the context of FinFET construction. Many aspects of the device 200 as depicted in FIGS. 9A-9D are the same as or similar to those counterparts depicted in FIGS. 8A-8D. Reference numerals are repeated for ease of understanding. Such same or similar aspects are not repeated in the interest of conciseness. Some differences are discussed below.

In the depicted embodiment as shown in FIG. 9D, the backside gate contact 260 has slanted sidewalls with tapered profile and further has a flange-like top portion. The curvature top surface of the flange-like top portion increases the contact area between the backside gate contact 260 and the gate structure 220 and thus reduces contact resistance. Specifically, after penetrating the isolation structure 206 and the high-k dielectric layer 224, the backside gate contact 260 increases in its width, forming a horizontally extended, flange-like region in its uppermost end, resulting in a distinct T-shaped or mushroom-shaped cross-sectional profile. In the illustrated embodiment, this upper expanded portion has a width greater than that of the lower region embedded in the isolation structure 206 but less than that of the lowest portion embedded in the substrate 204. Alternatively, the largest width of the whole backside gate contact 260 may reside in its flange-like region above the high-k dielectric layer 224. The flange-like region may be created by an over-etching process after the breakthrough (BT) etching process in forming dielectric liner 262 to create an expanded cavity above the high-k dielectric layer 224 and subsequently depositing the backside gate contact 260 into the backside opening and the expanded cavity. In the depicted embodiment, the dielectric liner 262 does not extend above the high-k dielectric layer 224.

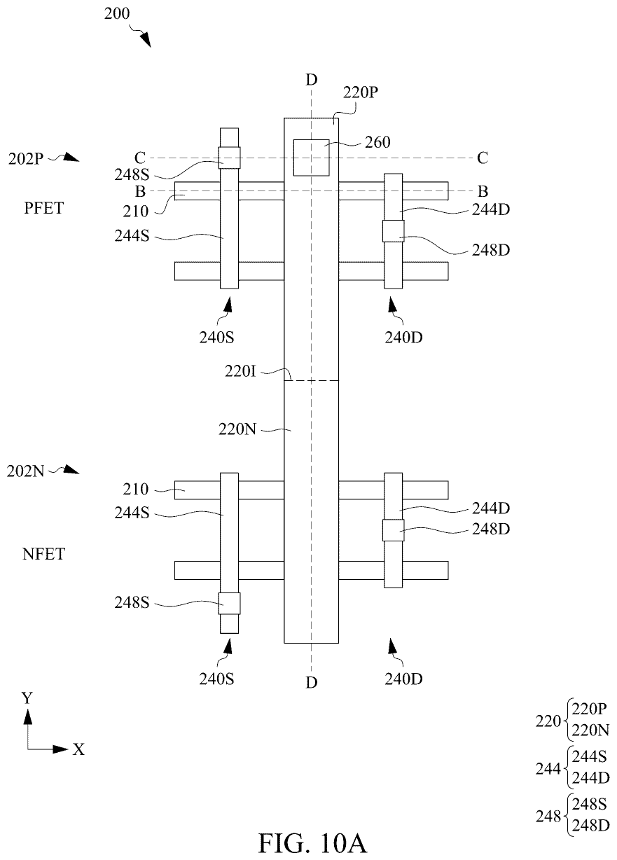

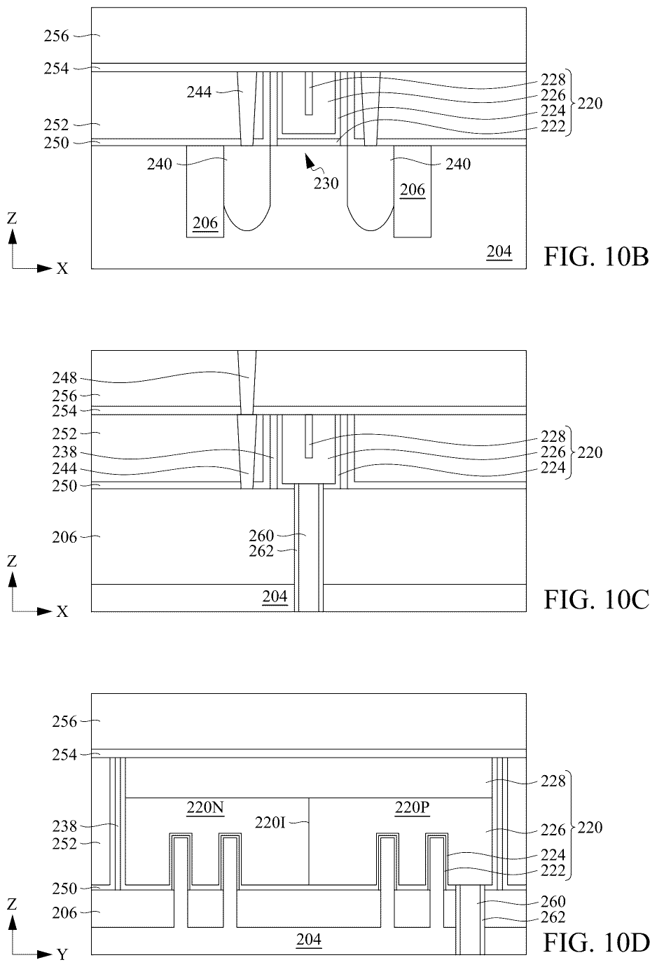

Reference is now made to FIGS. 10A-10D, which illustrate top and cross-sectional views of another embodiment of the device 200 that includes a pair of CMOS transistors with gate structures coupled to each other in the context of FinFET construction. Many aspects of the device 200 as depicted in FIGS. 10A-10D are the same as or similar to those counterparts depicted in FIGS. 8A-8D. Reference numerals are repeated for ease of understanding. Such same or similar aspects are not repeated in the interest of conciseness. One difference is that the backside gate contact 260 as depicted in FIG. 10D has substantially straight sidewalls. In other words, the backside gate contact 260 may have a uniform width from top to bottom, which may be due to a highly directional etching process applied in creating the backside opening that accommodates the backside gate contact 260.

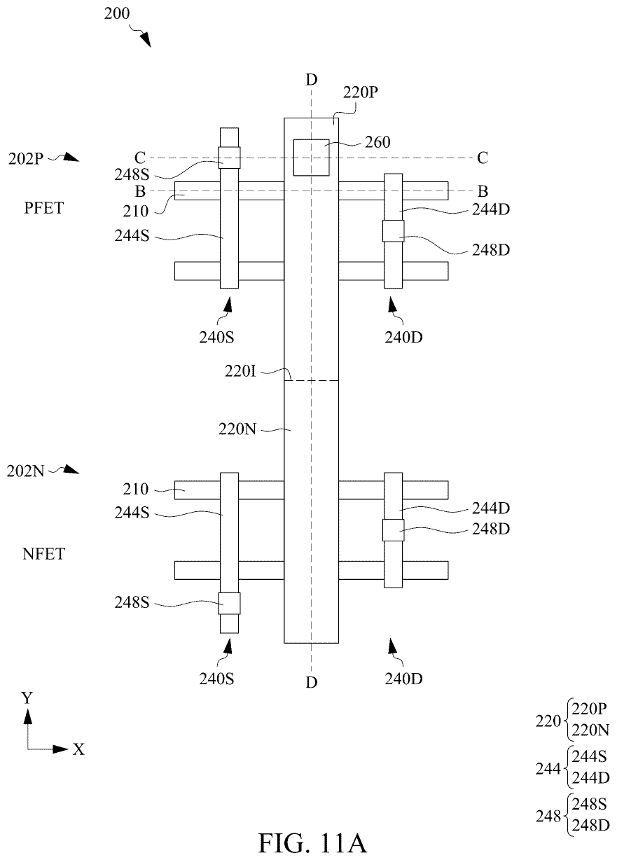

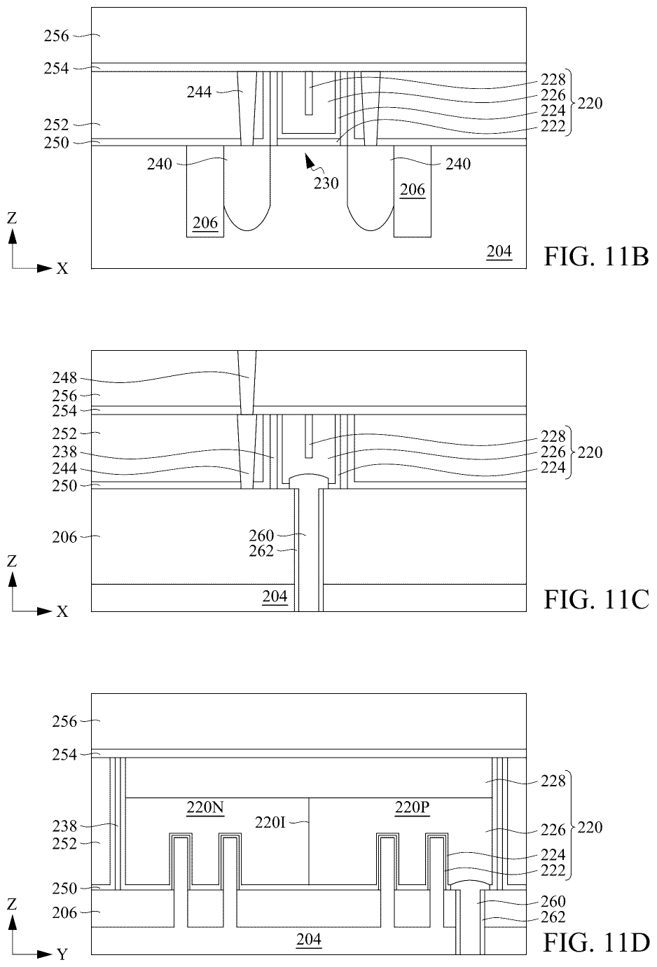

Reference is now made to FIGS. 11A-11D, which illustrate top and cross-sectional views of another embodiment of the device 200 that includes a pair of CMOS transistors with gate structures coupled to each other in the context of FinFET construction. Many aspects of the device 200 as depicted in FIGS. 11A-11D are the same as or similar to those counterparts depicted in FIGS. 9A-9D. Reference numerals are repeated for ease of understanding. Such same or similar aspects are not repeated in the interest of conciseness. One difference is that the backside gate contact 260 as depicted in FIG. 11D has substantially straight sidewalls. In other words, the backside gate contact 260 may have a uniform width from top to bottom, which may be due to a highly directional etching process applied in creating the backside opening that accommodates the backside gate contact 260.

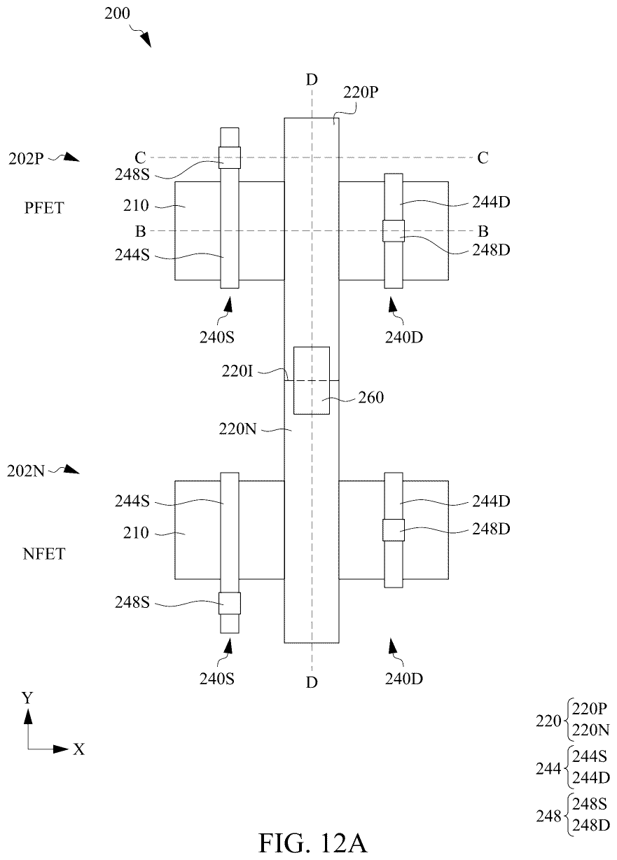

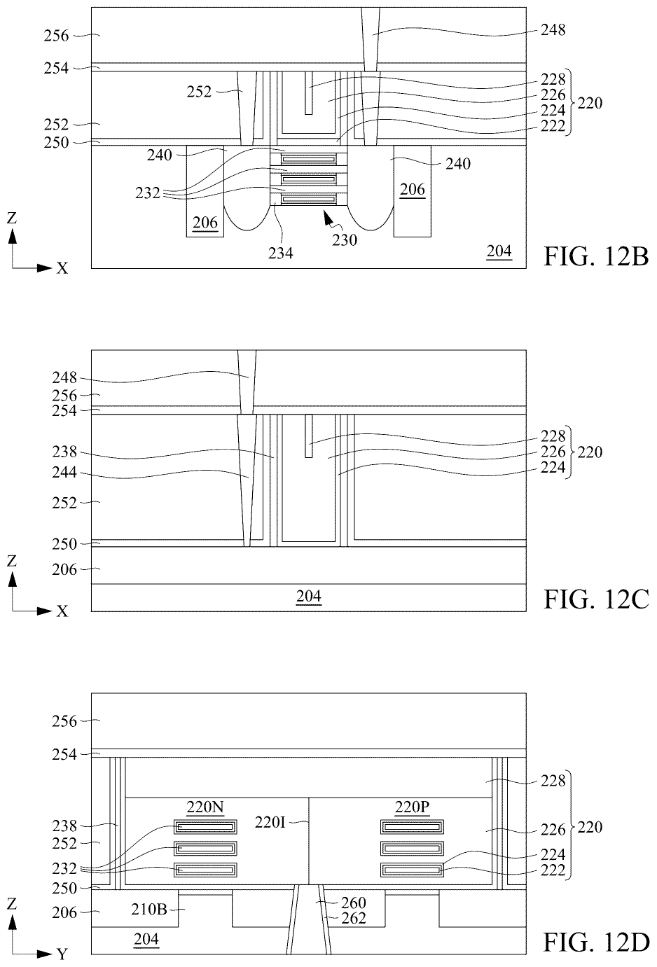

Reference is now made to FIGS. 12A-12D, which illustrate top and cross-sectional views of another embodiment of the device 200 that includes a pair of CMOS transistors with gate structures coupled to each other in the context of GAA construction. Many aspects of the device 200 as depicted in FIGS. 12A-12D are the same as or similar to those counterparts depicted in FIGS. 4A-4D. Reference numerals are repeated for ease of understanding. Such same or similar aspects are not repeated in the interest of conciseness. Some differences are discussed below.

Instead of having active regions with channel regions residing in fins, the NFET 202N and PFET 202P each has a wider active region 210 with respective channel region 230 residing in multiple vertically stacked channel layers 232. In the depicted embodiment, the channel layers 232 of the same stack are suspended on a fin-shaped base 210B. In some embodiments, the channel layers 232 includes a semiconductor material suitable for transistor channels, such as silicon, silicon germanium, or other semiconductor material(s). The channel layers 232 may be in the shape of rods, bars, sheets, or other shapes in various embodiments. In some embodiments, the channel layers 232 are initially part of a stack of semiconductor layers that include the channel layers 232 and other sacrificial semiconductor layers alternately stacked layer-by-layer. The sacrificial semiconductor layers and the channel layers 232 include different material compositions (such as different semiconductor materials, different constituent atomic percentages, and/or different constituent weight percentages) to achieve etching selectivity. During a gate replacement process to form the gate structure 220, the sacrificial semiconductor layers are selectively removed, leaving the channel layers 232 suspended over a fin-shaped base 210B. The gate structures 220 wraps around each of the channel layers 232. In some embodiments, the largest width of the backside gate contact 260 is greater than a width of the active regions 210. Alternatively, the largest width of the backside gate contact 260 may be equal to or smaller than a width of the active regions 210.

The device 200 also includes inner spacers 234 interposing the source/drain features 240 and the gate structure 220. The inner spacers 234 separate the source/drain features 240 from interfacing the gate structure 220. The inner spacers 234 may include a dielectric material selected from silicon, oxygen, carbon, nitrogen, other suitable material, or combinations thereof (for example, silicon oxide, silicon nitride, silicon oxynitride, silicon carbide, or silicon oxycarbonitride). In some embodiments, the inner spacers 234 include a low-k dielectric material. The inner spacers 234 may be formed by deposition and etching processes. For example, after source/drain trenches are etched and before the source/drain features 240 are epitaxially grown from the source/drain trenches, an etch process may be used to recess the sacrificial semiconductor layers between the adjacent channel layers 232 to form gaps vertically between the adjacent channel layers 232. Then, one or more dielectric materials are deposited (using CVD or ALD for example) to fill the gaps. Another etching process is performed to remove the dielectric materials outside the gaps, thereby forming the inner spacers 234.

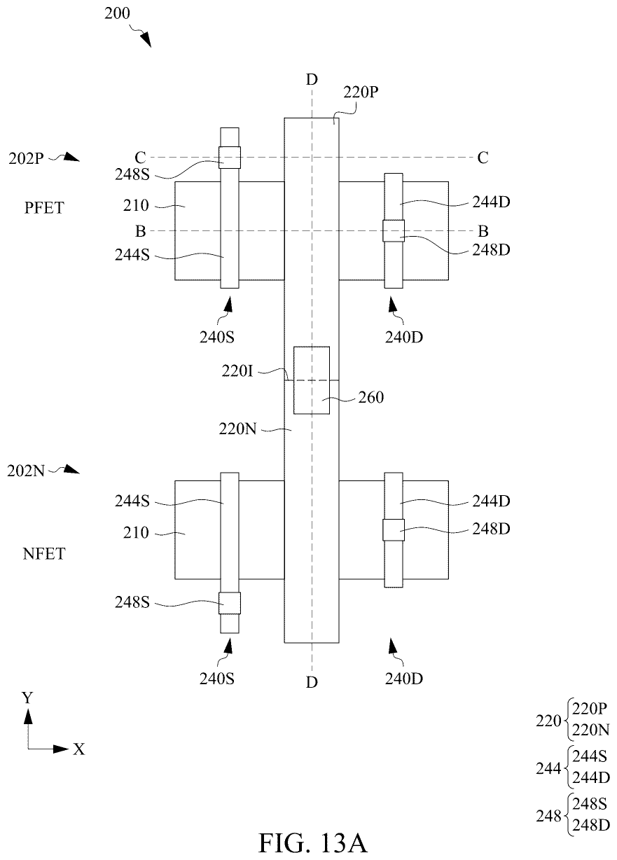

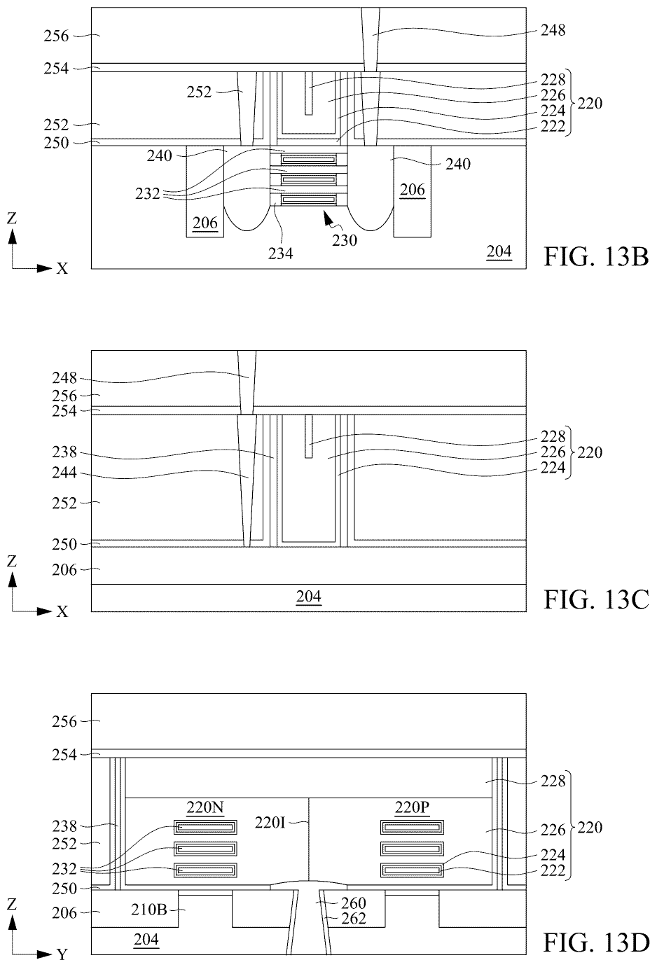

Reference is now made to FIGS. 13A-13D, which illustrate top and cross-sectional views of another embodiment of the device 200 that includes a pair of CMOS transistors with gate structures coupled to each other in the context of GAA construction. Many aspects of the device 200 as depicted in FIGS. 13A-13D are the same as or similar to those counterparts depicted in FIGS. 12A-12D. Reference numerals are repeated for ease of understanding. Such same or similar aspects are not repeated in the interest of conciseness. Some differences are discussed below.

In the depicted embodiment as shown in FIG. 13D, the backside gate contact 260 has slanted sidewalls with tapered profile and further has a flange-like top portion. The curvature top surface of the flange-like top portion increases the contact area between the backside gate contact 260 and the gate structure 220 and thus reduces contact resistance. Specifically, after penetrating the isolation structure 206 and the high-k dielectric layer 224, the backside gate contact 260 increases in its width, forming a horizontally extended, flange-like region in its uppermost end, resulting in a distinct T-shaped or mushroom-shaped cross-sectional profile. In the illustrated embodiment, this upper expanded portion has a width greater than that of the lower region embedded in the isolation structure 206 but less than that of the lowest portion embedded in the substrate 204. Alternatively, the largest width of the whole backside gate contact 260 may reside in its flange-like region above the high-k dielectric layer 224. The flange-like region may be created by an over-etching process after the breakthrough (BT) etching process in forming dielectric liner 262 to create an expanded cavity above the high-k dielectric layer 224 and subsequently depositing the backside gate contact 260 into the backside opening and the expanded cavity. In the depicted embodiment, the dielectric liner 262 does not extend above the high-k dielectric layer 224. In some embodiments, the largest width of the lower portion of the backside gate contact 260 is smaller than a width of the active regions 210, while the largest width of the flange-like upper portion of the backside gate contact 260 is greater than a width of the active regions 210. Alternatively, the largest widths of the lower and upper portions of the backside gate contact 260 may be both greater than a width of the active regions 210.

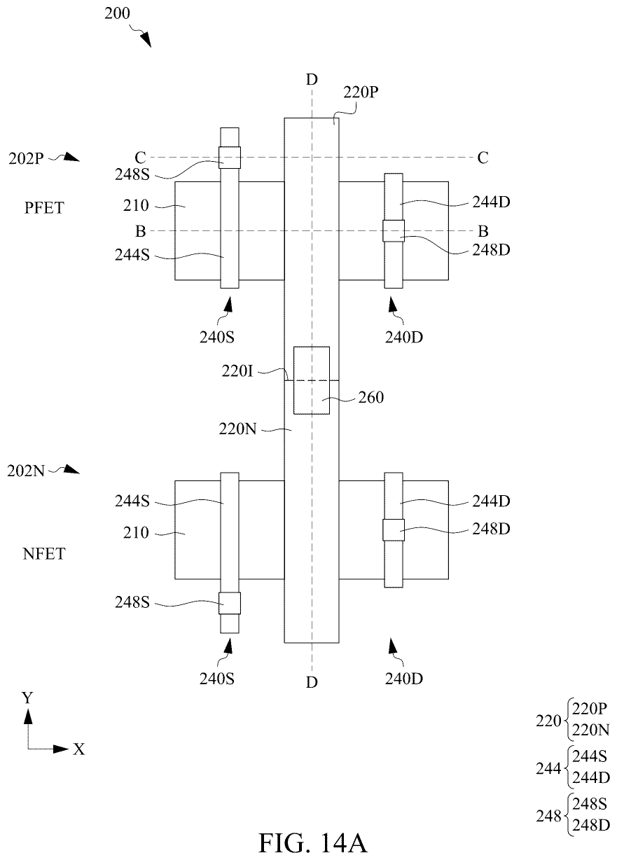

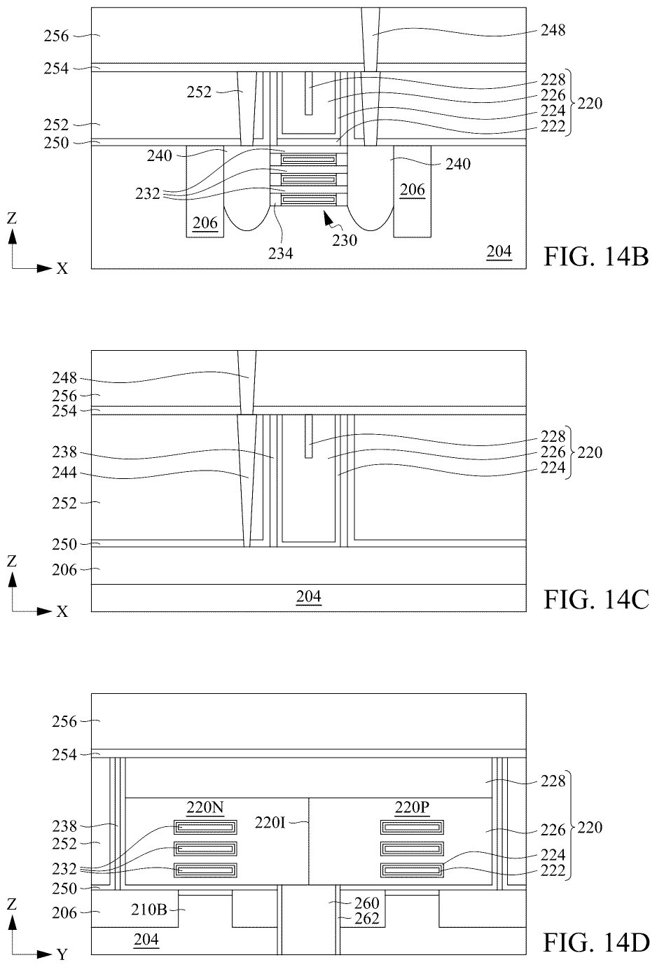

Reference is now made to FIGS. 14A-14D, which illustrate top and cross-sectional views of another embodiment of the device 200 that includes a pair of CMOS transistors with gate structures coupled to each other in the context of GAA construction. Many aspects of the device 200 as depicted in FIGS. 14A-14D are the same as or similar to those counterparts depicted in FIGS. 12A-12D. Reference numerals are repeated for ease of understanding. Such same or similar aspects are not repeated in the interest of conciseness. One difference is that the backside gate contact 260 as depicted in FIG. 14D has substantially straight sidewalls. In other words, the backside gate contact 260 may have a uniform width from top to bottom, which may be due to a highly directional etching process applied in creating the backside opening that accommodates the backside gate contact 260. In some embodiments, the width of the backside gate contact 260 is greater than a width of the active regions 210. Alternatively, the width of the backside gate contact 260 may be equal to or smaller than a width of the active regions 210.

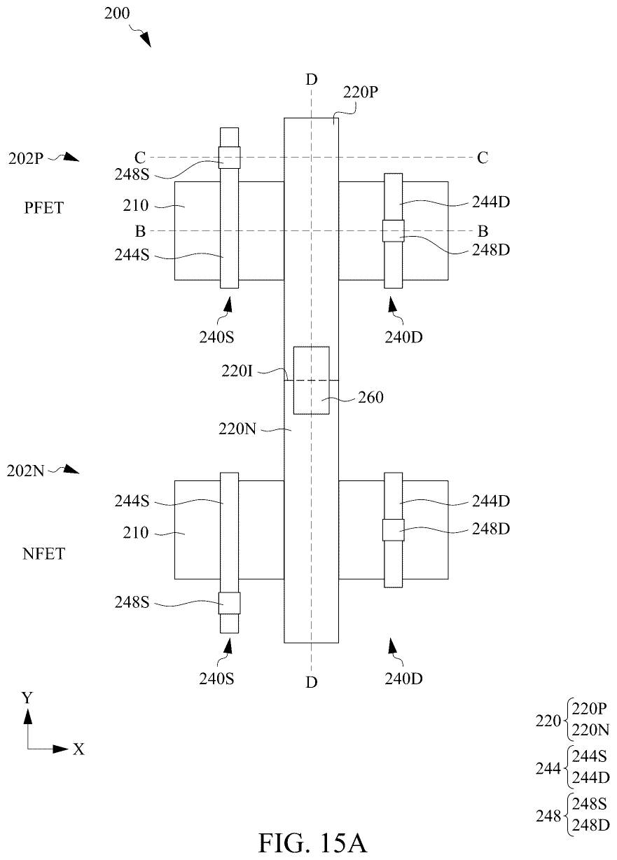

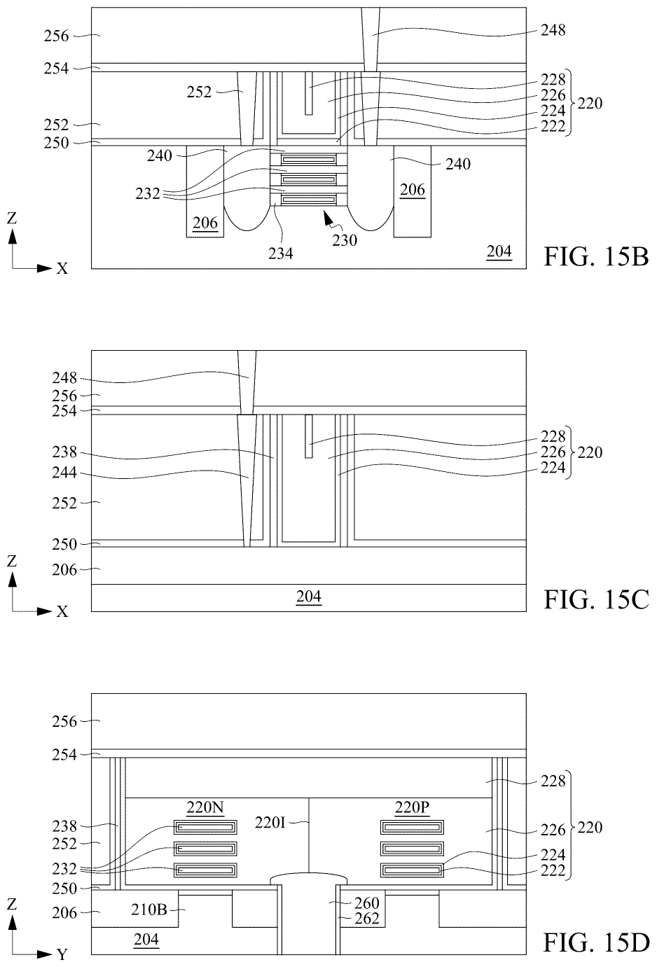

Reference is now made to FIGS. 15A-15D, which illustrate top and cross-sectional views of another embodiment of the device 200 that includes a pair of CMOS transistors with gate structures coupled to each other in the context of GAA construction. Many aspects of the device 200 as depicted in FIGS. 15A-15D are the same as or similar to those counterparts depicted in FIGS. 13A-13D. Reference numerals are repeated for ease of understanding. Such same or similar aspects are not repeated in the interest of conciseness. One difference is that the backside gate contact 260 as depicted in FIG. 15D has substantially straight sidewalls. In other words, the backside gate contact 260 may have a uniform width from top to bottom, which may be due to a highly directional etching process applied in creating the backside opening that accommodates the backside gate contact 260. In some embodiments, the width of the lower portion of the backside gate contact 260 is smaller than a width of the active regions 210, while the largest width of the flange-like upper portion of the backside gate contact 260 is greater than a width of the active regions 210. Alternatively, the widths of the lower and upper portions of the backside gate contact 260 may be both greater than a width of the active regions 210.

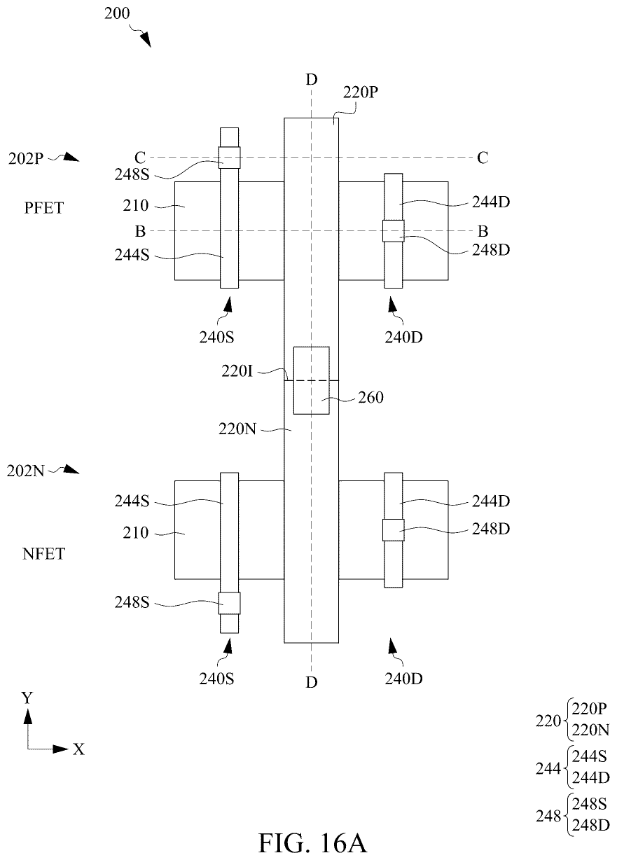

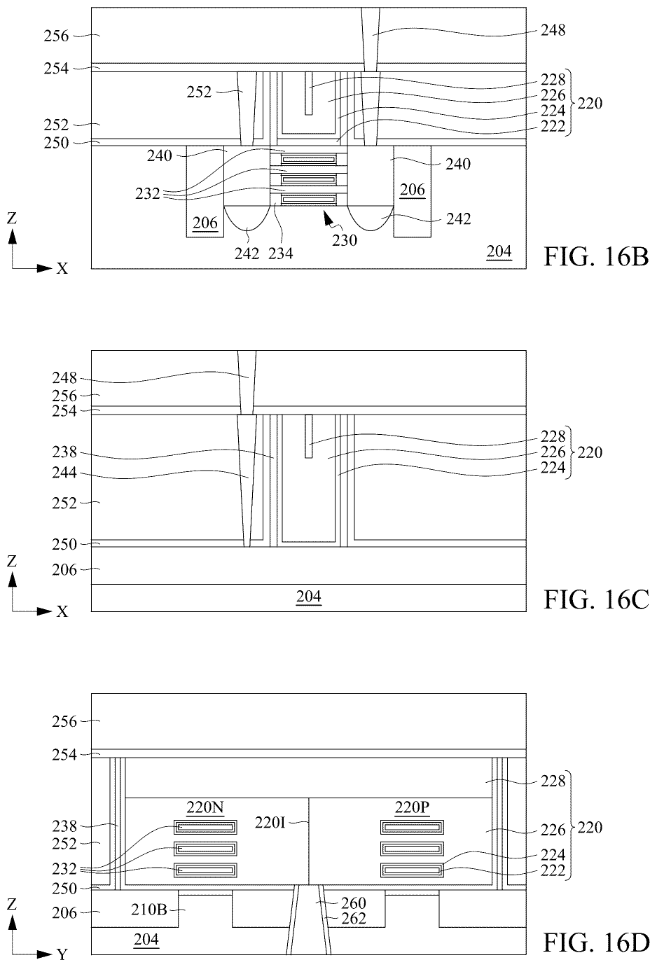

Reference is now made to FIGS. 16A-16D, which illustrate top and cross-sectional views of another embodiment of the device 200 that includes a pair of CMOS transistors with gate structures coupled to each other in the context of GAA construction. Many aspects of the device 200 as depicted in FIGS. 16A-16D are the same as or similar to those counterparts depicted in FIGS. 12A-12D. Reference numerals are repeated for ease of understanding. Such same or similar aspects are not repeated in the interest of conciseness. One difference is that the device 200 further includes a bottom dielectric layer 242 underneath the source/drain features 240. The bottom dielectric layer 242 increases resistance in the source/drain regions and suppresses the leakage current into the substrate. Because the bottom dielectric layer 242 may interface source/drain features 240 and oxygen content may oxidize source/drain features, the bottom dielectric layer 242 may be formed of an oxygen-free dielectric material, such as an oxygen-free nitride. In an example process, a chlorine-containing silicon nitride layer is deposited over the source/drain trenches. The bottom dielectric layer 242 may interface the bottommost inner spacer 234.

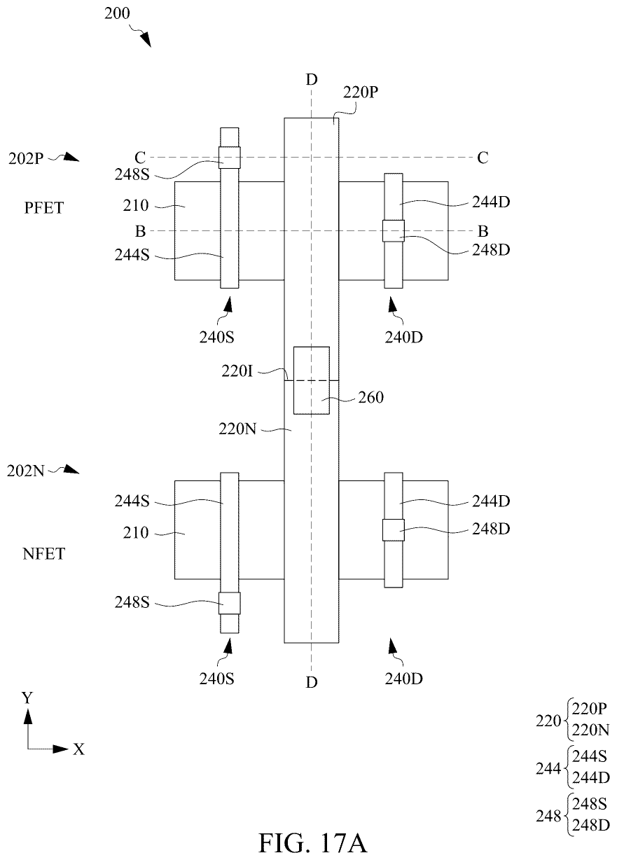

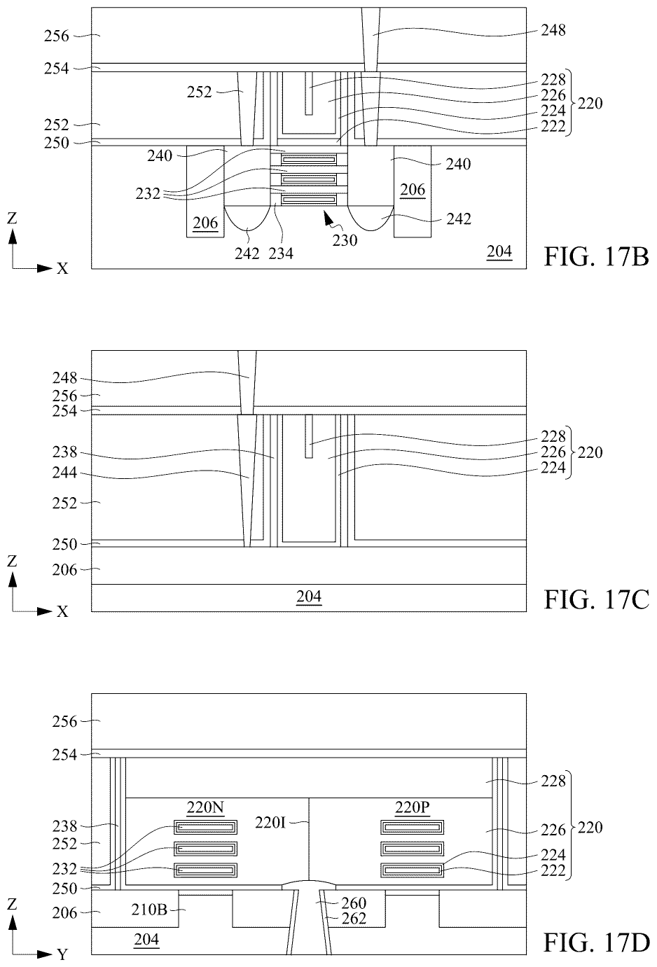

Reference is now made to FIGS. 17A-17D, which illustrate top and cross-sectional views of another embodiment of the device 200 that includes a pair of CMOS transistors with gate structures coupled to each other in the context of GAA construction. Many aspects of the device 200 as depicted in FIGS. 17A-17D are the same as or similar to those counterparts depicted in FIGS. 13A-13D. Reference numerals are repeated for ease of understanding. Such same or similar aspects are not repeated in the interest of conciseness. One difference is that the device 200 further includes a bottom dielectric layer 242 underneath the source/drain features 240. The bottom dielectric layer 242 increases resistance in the source/drain regions and suppresses the leakage current into the substrate. Because the bottom dielectric layer 242 may interface source/drain features 240 and oxygen content may oxidize source/drain features, the bottom dielectric layer 242 may be formed of an oxygen-free dielectric material, such as an oxygen-free nitride. In an example process, a chlorine-containing silicon nitride layer is deposited over the source/drain trenches. The bottom dielectric layer 242 may interface the bottommost inner spacer 234.

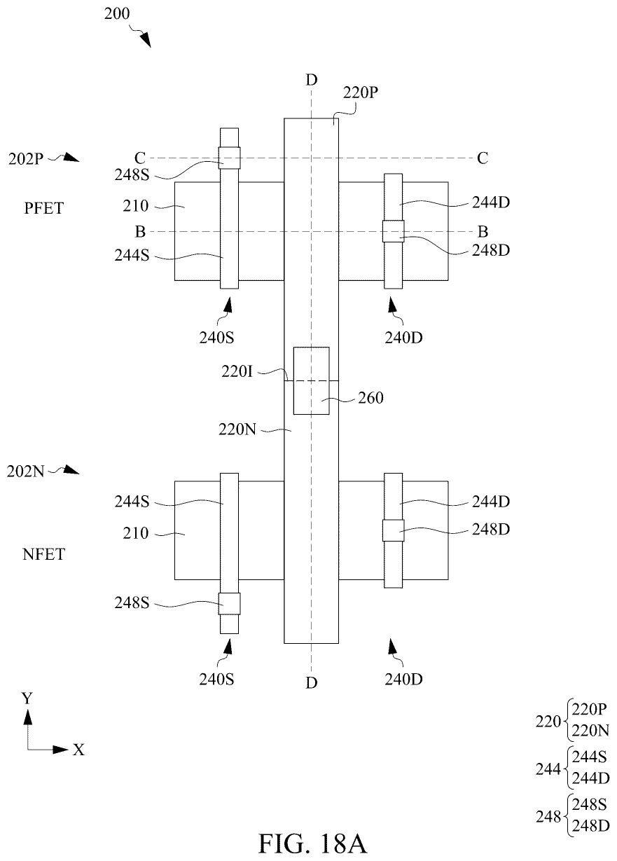

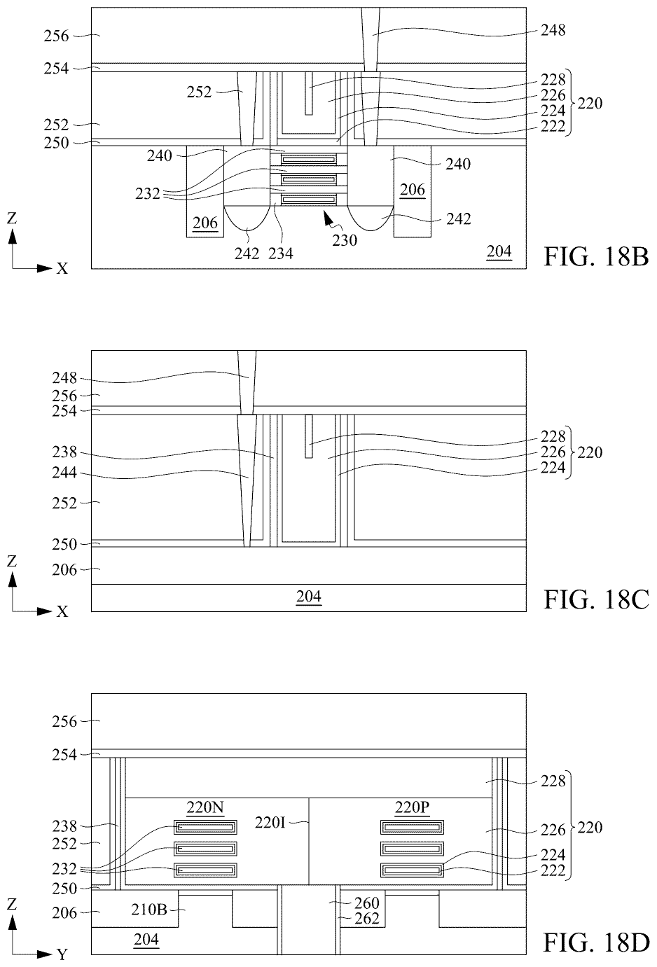

Reference is now made to FIGS. 18A-18D, which illustrate top and cross-sectional views of another embodiment of the device 200 that includes a pair of CMOS transistors with gate structures coupled to each other in the context of GAA construction. Many aspects of the device 200 as depicted in FIGS. 18A-18D are the same as or similar to those counterparts depicted in FIGS. 14A-14D. Reference numerals are repeated for ease of understanding. Such same or similar aspects are not repeated in the interest of conciseness. One difference is that the device 200 further includes a bottom dielectric layer 242 underneath the source/drain features 240. The bottom dielectric layer 242 increases resistance in the source/drain regions and suppresses the leakage current into the substrate. Because the bottom dielectric layer 242 may interface source/drain features 240 and oxygen content may oxidize source/drain features, the bottom dielectric layer 242 may be formed of an oxygen-free dielectric material, such as an oxygen-free nitride. In an example process, a chlorine-containing silicon nitride layer is deposited over the source/drain trenches. The bottom dielectric layer 242 may interface the bottommost inner spacer 234.

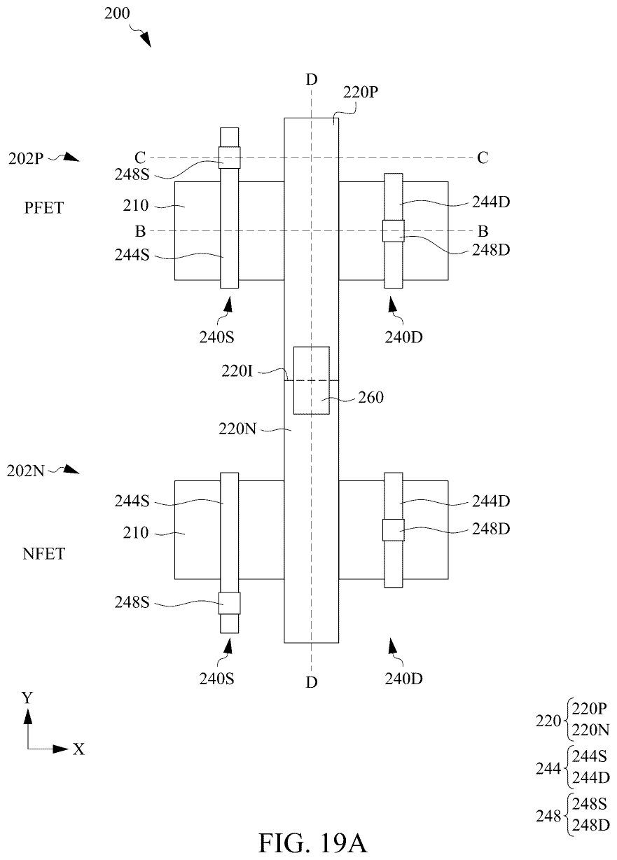

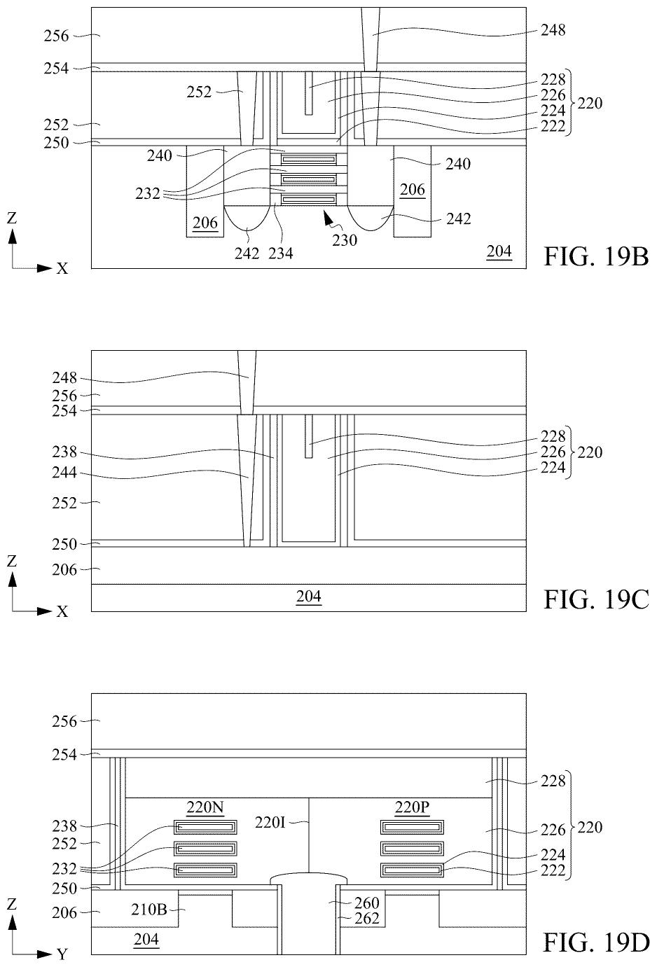

Reference is now made to FIGS. 19A-19D, which illustrate top and cross-sectional views of another embodiment of the device 200 that includes a pair of CMOS transistors with gate structures coupled to each other in the context of GAA construction. Many aspects of the device 200 as depicted in FIGS. 19A-19D are the same as or similar to those counterparts depicted in FIGS. 15A-15D. Reference numerals are repeated for ease of understanding. Such same or similar aspects are not repeated in the interest of conciseness. One difference is that the device 200 further includes a bottom dielectric layer 242 underneath the source/drain features 240. The bottom dielectric layer 242 increases resistance in the source/drain regions and suppresses the leakage current into the substrate. Because the bottom dielectric layer 242 may interface source/drain features 240 and oxygen content may oxidize source/drain features, the bottom dielectric layer 242 may be formed of an oxygen-free dielectric material, such as an oxygen-free nitride. In an example process, a chlorine-containing silicon nitride layer is deposited over the source/drain trenches. The bottom dielectric layer 242 may interface the bottommost inner spacer 234.

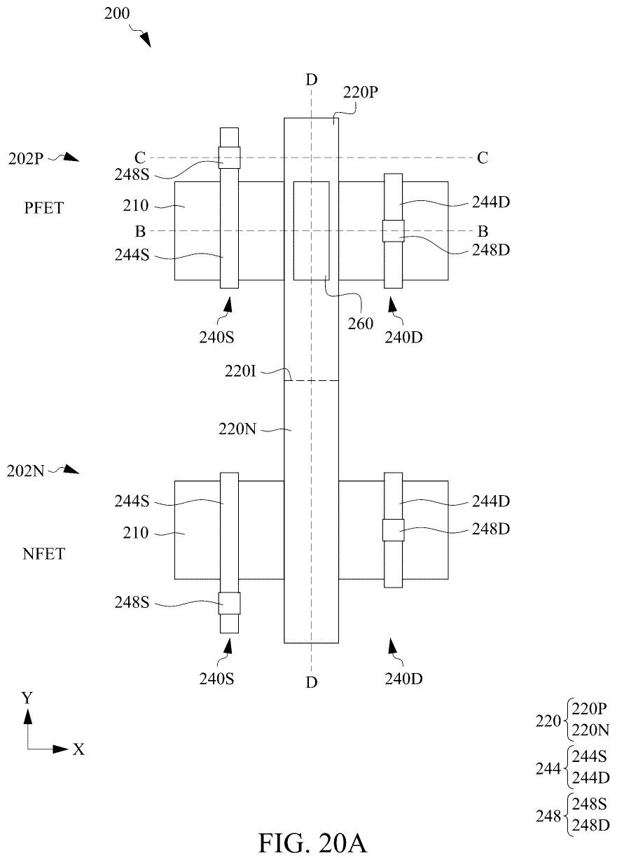

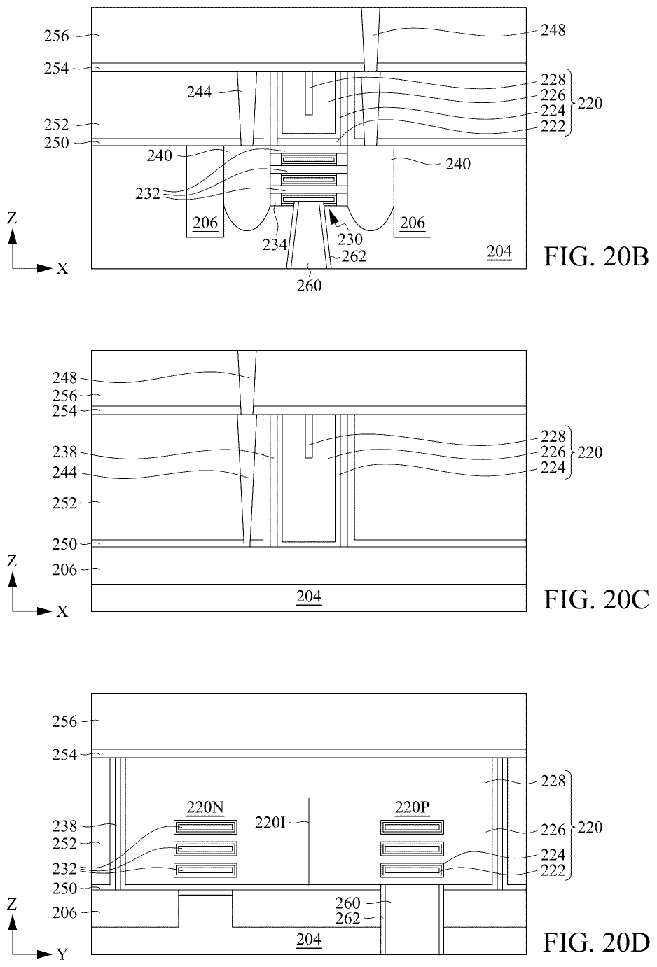

Reference is now made to FIGS. 20A-20D, which illustrate top and cross-sectional views of another embodiment of the device 200 that includes a pair of CMOS transistors with gate structures coupled to each other in the context of GAA construction. Many aspects of the device 200 as depicted in FIGS. 20A-20D are the same as or similar to those counterparts depicted in FIGS. 12A-12D. Reference numerals are repeated for ease of understanding. Such same or similar aspects are not repeated in the interest of conciseness. Some differences are discussed below. In the depicted embodiment, the backside gate contact 260 is positioned directly under the active region 210 of either the PFET 202P or the NFET 202N, such as shown in FIG. 20A. The backside gate contact 260 extends through the high-k dielectric layer 224 and the interfacial layer 222 wrapping around the bottommost channel layer 232 and thus directly interfaces the gate electrode layer 226, such as shown in FIG. 20B. The backside gate contact 260 may be formed by replacing one of the fin-shaped bases 210B, such as by selectively etching the respective fin-shaped base 210B to form a backside opening and depositing conductive material(s) in the backside opening. Accordingly, in the Y-Z plane, the backside gate contact 260 may inherit the sidewall profiles of the fin-shaped base 210B, such as having a substantially straight sidewall, such as shown in FIG. 20D. In the Y-Z plane, the width of the backside gate contact 260 is also substantially equal to the width of the active region 210. As a comparison, in the X-Z plane, the sidewalls of the backside gate contact 260 may still exhibit a tapered profile. By replacing the fin-shaped base 210B in the channel region with the backside gate contact 260, the leakage current path through the fin-shaped base 210B into the substrate is suppressed.

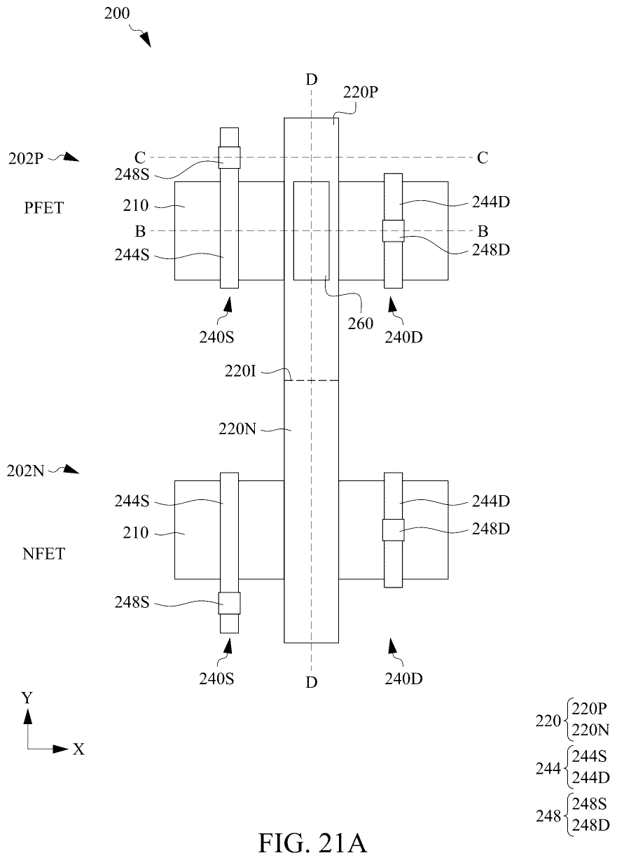

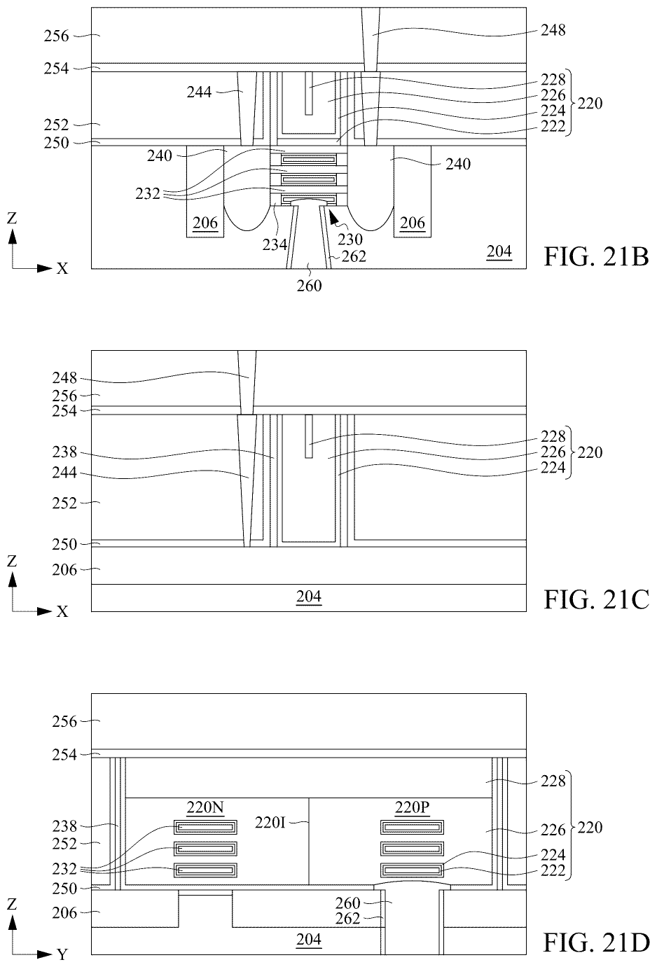

Reference is now made to FIGS. 21A-21D, which illustrate top and cross-sectional views of another embodiment of the device 200 that includes a pair of CMOS transistors with gate structures coupled to each other in the context of GAA construction. Many aspects of the device 200 as depicted in FIGS. 21A-1D are the same as or similar to those counterparts depicted in FIGS. 20A-20D. Reference numerals are repeated for ease of understanding. Such same or similar aspects are not repeated in the interest of conciseness. Some differences are discussed below. In the depicted embodiment as shown in FIGS. 21B and 21D, the backside gate contact 260 has a flange-like top portion. The curvature top surface of the flange-like top portion increases the contact area between the backside gate contact 260 and the gate structure 220 and thus reduces contact resistance. Specifically, after penetrating the high-k dielectric layer 224, the backside gate contact 260 increases in its width, forming a horizontally extended, flange-like region in its uppermost end, resulting in a distinct T-shaped or mushroom-shaped cross-sectional profile. In the X-Z plane, the sidewalls of the backside gate contact 260 may still exhibit a tapered profile, and the upper expanded portion may have a width greater than that of the lower region but less than that of the lowest portion embedded in the substrate 204. Alternatively, in the X-Z plane, the largest width of the whole backside gate contact 260 may reside in its flange-like region above the high-k dielectric layer 224. The flange-like region may be created by an over-etching process after the breakthrough (BT) etching process in forming dielectric liner 262 to create an expanded cavity above the high-k dielectric layer 224 and subsequently depositing the backside gate contact 260 into the backside opening and the expanded cavity. In the depicted embodiment, the dielectric liner 262 does not extend above the high-k dielectric layer 224. In the Y-Z plane, the largest width of the flange-like upper portion of the backside gate contact 260 is greater than a width of the active regions 210.

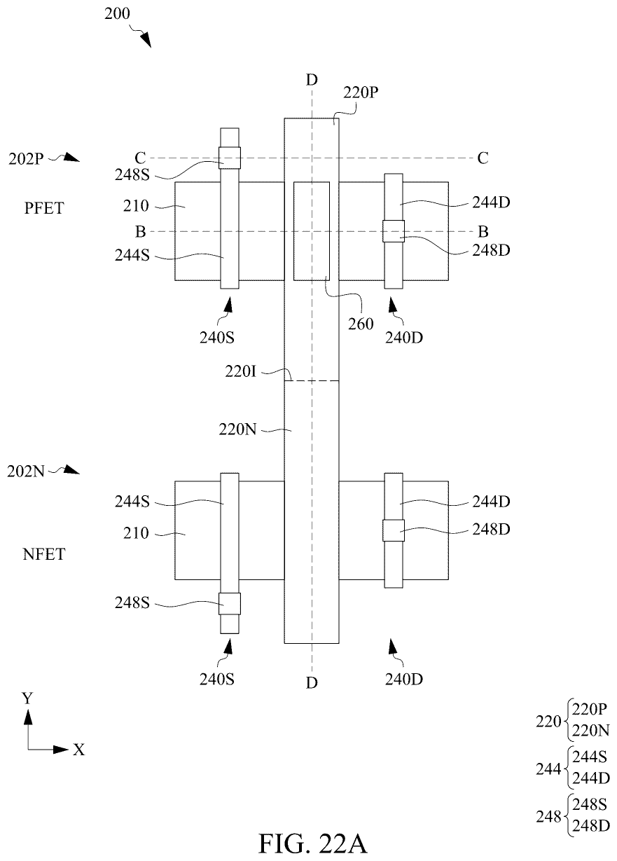

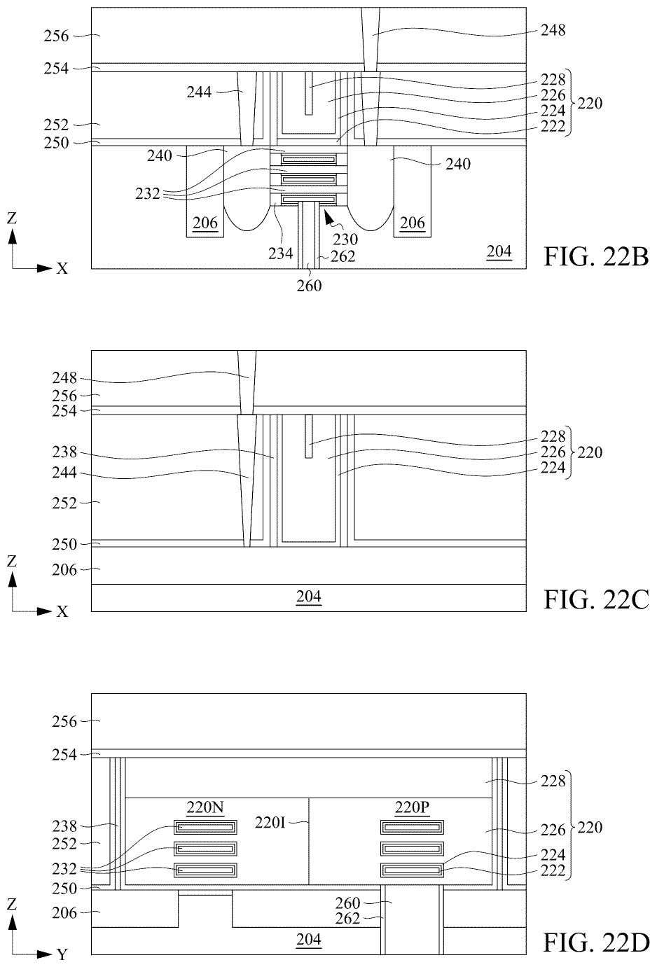

Reference is now made to FIGS. 22A-22D, which illustrate top and cross-sectional views of another embodiment of the device 200 that includes a pair of CMOS transistors with gate structures coupled to each other in the context of GAA construction. Many aspects of the device 200 as depicted in FIGS. 22A-22D are the same as or similar to those counterparts depicted in FIGS. 20A-20D. Reference numerals are repeated for ease of understanding. Such same or similar aspects are not repeated in the interest of conciseness. One difference is that the backside gate contact 260 as depicted in FIG. 22B has substantially straight sidewalls. In other words, the backside gate contact 260 may have a uniform width from top to bottom in the X-Z plane as in the Y-Z plane, which may be due to a highly directional etching process applied in creating the backside opening that accommodates the backside gate contact 260.

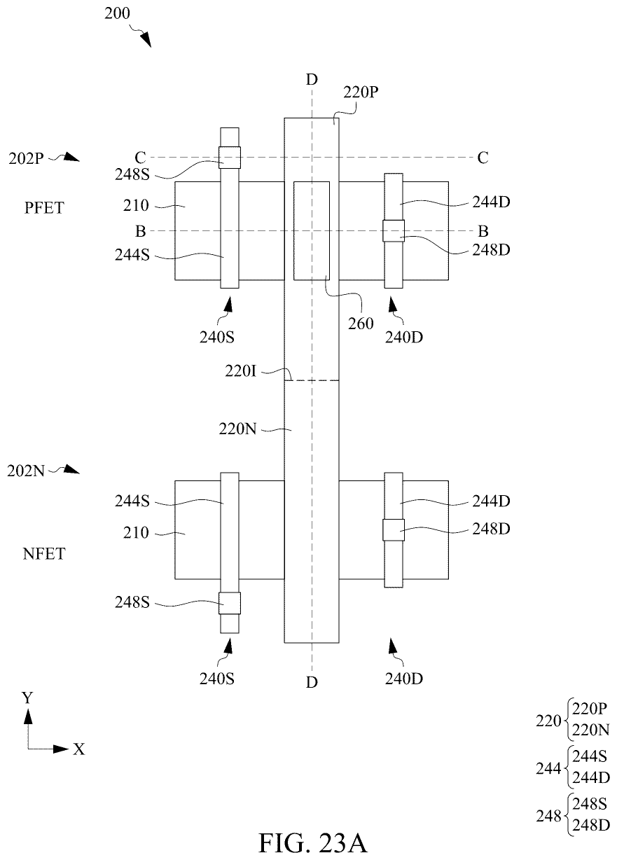

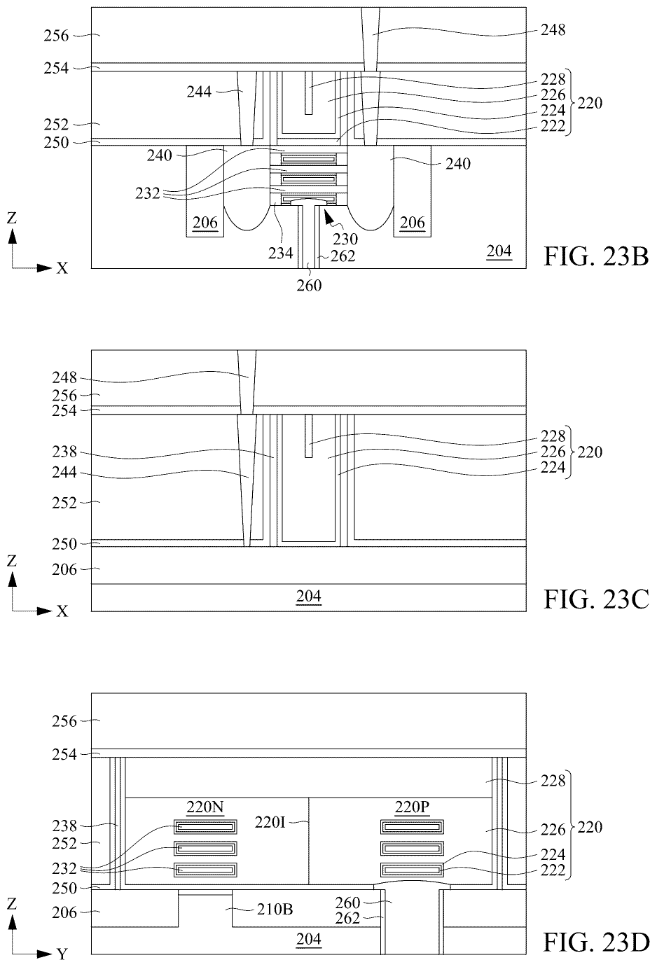

Reference is now made to FIGS. 23A-23D, which illustrate top and cross-sectional views of another embodiment of the device 200 that includes a pair of CMOS transistors with gate structures coupled to each other in the context of GAA construction. Many aspects of the device 200 as depicted in FIGS. 23A-23D are the same as or similar to those counterparts depicted in FIGS. 21A-21D. Reference numerals are repeated for ease of understanding. Such same or similar aspects are not repeated in the interest of conciseness. One difference is that the backside gate contact 260 as depicted in FIG. 23B has substantially straight sidewalls. In other words, the backside gate contact 260 may have a uniform width in its lower portion in the X-Z plane as in the Y-Z plane, which may be due to a highly directional etching process applied in creating the backside opening that accommodates the backside gate contact 260.

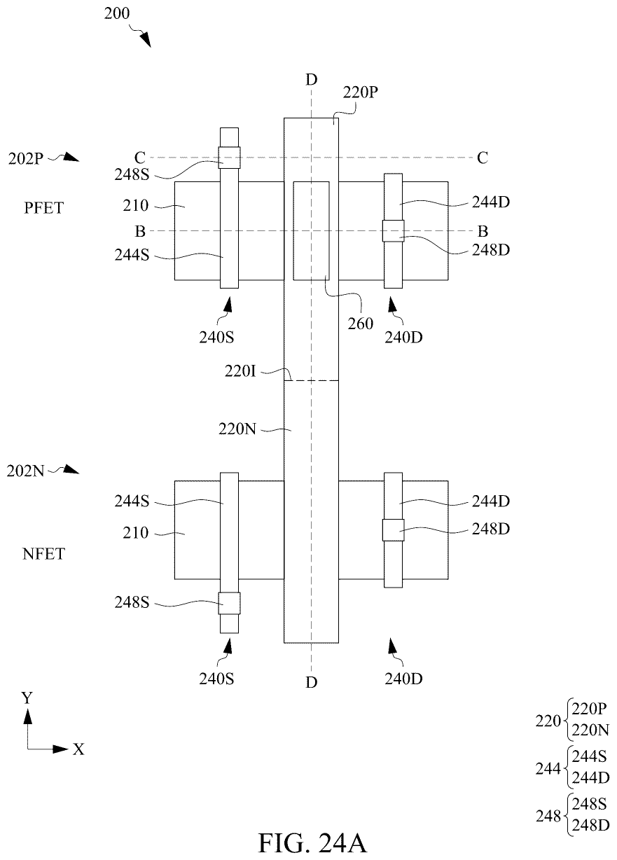

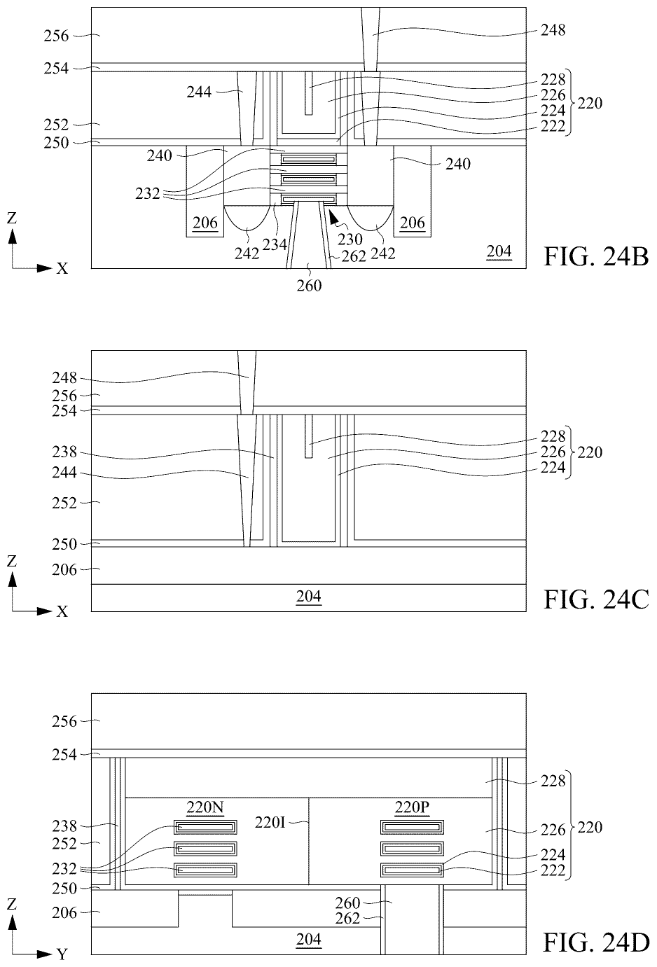

Reference is now made to FIGS. 24A-24D, which illustrate top and cross-sectional views of another embodiment of the device 200 that includes a pair of CMOS transistors with gate structures coupled to each other in the context of GAA construction. Many aspects of the device 200 as depicted in FIGS. 24A-24D are the same as or similar to those counterparts depicted in FIGS. 20A-20D. Reference numerals are repeated for ease of understanding. Such same or similar aspects are not repeated in the interest of conciseness. One difference is that the device 200 further includes a bottom dielectric layer 242 underneath the source/drain features 240. The bottom dielectric layer 242 increases resistance in the source/drain regions and suppresses the leakage current into the substrate. Because the bottom dielectric layer 242 may interface source/drain features 240 and oxygen content may oxidize source/drain features, the bottom dielectric layer 242 may be formed of an oxygen-free dielectric material, such as an oxygen-free nitride. In an example process, a chlorine-containing silicon nitride layer is deposited over the source/drain trenches. The bottom dielectric layer 242 may interface the bottommost inner spacer 234.

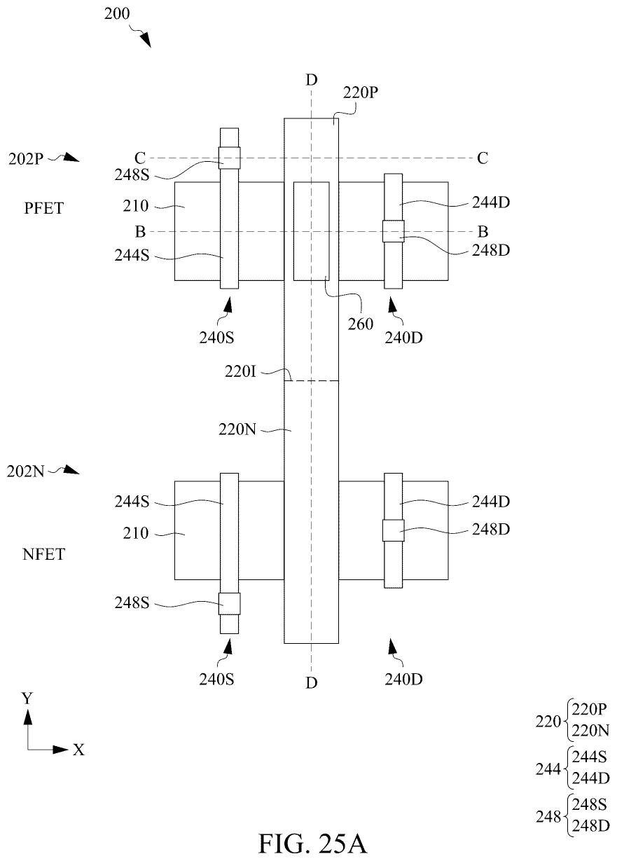

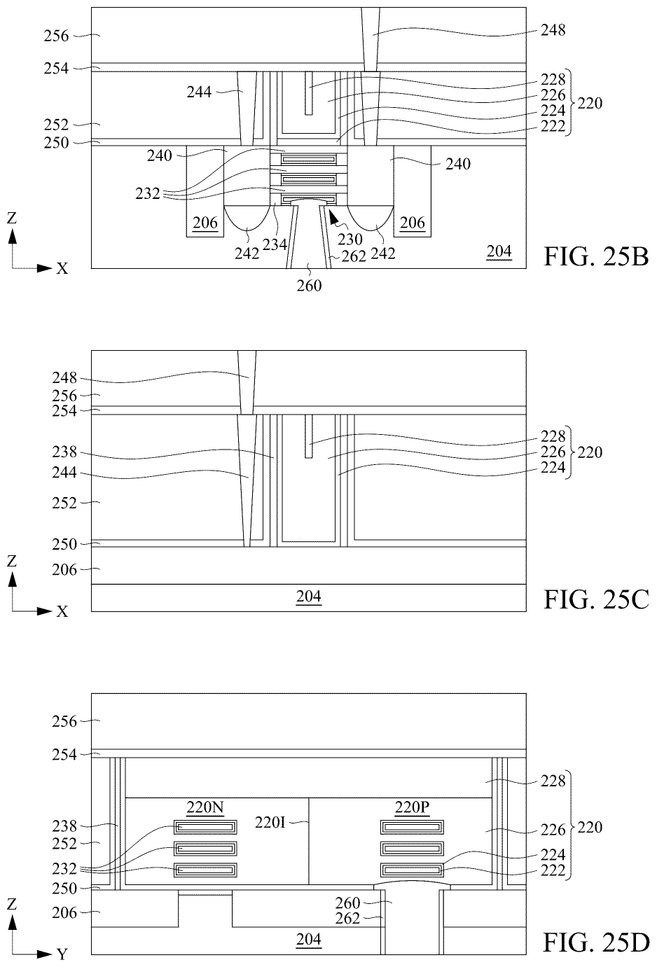

Reference is now made to FIGS. 25A-25D, which illustrate top and cross-sectional views of another embodiment of the device 200 that includes a pair of CMOS transistors with gate structures coupled to each other in the context of GAA construction. Many aspects of the device 200 as depicted in FIGS. 25A-25D are the same as or similar to those counterparts depicted in FIGS. 21A-21D. Reference numerals are repeated for ease of understanding. Such same or similar aspects are not repeated in the interest of conciseness. One difference is that the device 200 further includes a bottom dielectric layer 242 underneath the source/drain features 240. The bottom dielectric layer 242 increases resistance in the source/drain regions and suppresses the leakage current into the substrate. Because the bottom dielectric layer 242 may interface source/drain features 240 and oxygen content may oxidize source/drain features, the bottom dielectric layer 242 may be formed of an oxygen-free dielectric material, such as an oxygen-free nitride. In an example process, a chlorine-containing silicon nitride layer is deposited over the source/drain trenches. The bottom dielectric layer 242 may interface the bottommost inner spacer 234.

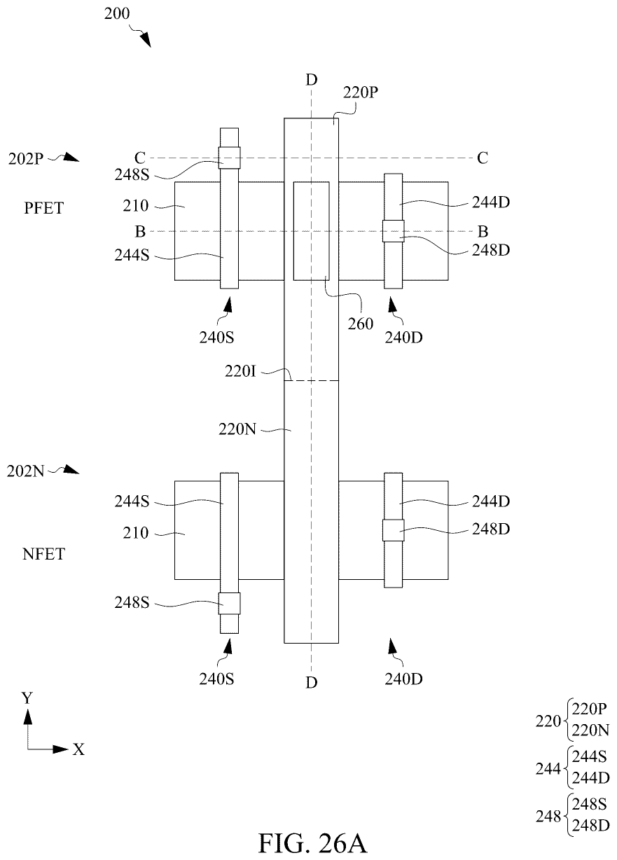

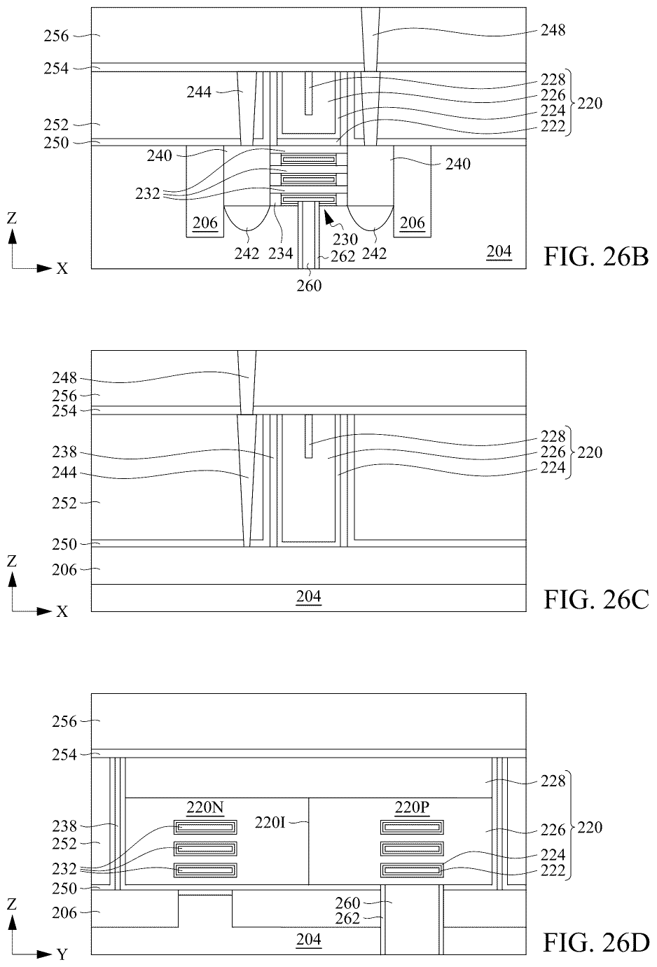

Reference is now made to FIGS. 26A-26D, which illustrate top and cross-sectional views of another embodiment of the device 200 that includes a pair of CMOS transistors with gate structures coupled to each other in the context of GAA construction. Many aspects of the device 200 as depicted in FIGS. 26A-26D are the same as or similar to those counterparts depicted in FIGS. 22A-22D. Reference numerals are repeated for ease of understanding. Such same or similar aspects are not repeated in the interest of conciseness. One difference is that the device 200 further includes a bottom dielectric layer 242 underneath the source/drain features 240. The bottom dielectric layer 242 increases resistance in the source/drain regions and suppresses the leakage current into the substrate. Because the bottom dielectric layer 242 may interface source/drain features 240 and oxygen content may oxidize source/drain features, the bottom dielectric layer 242 may be formed of an oxygen-free dielectric material, such as an oxygen-free nitride. In an example process, a chlorine-containing silicon nitride layer is deposited over the source/drain trenches. The bottom dielectric layer 242 may interface the bottommost inner spacer 234.

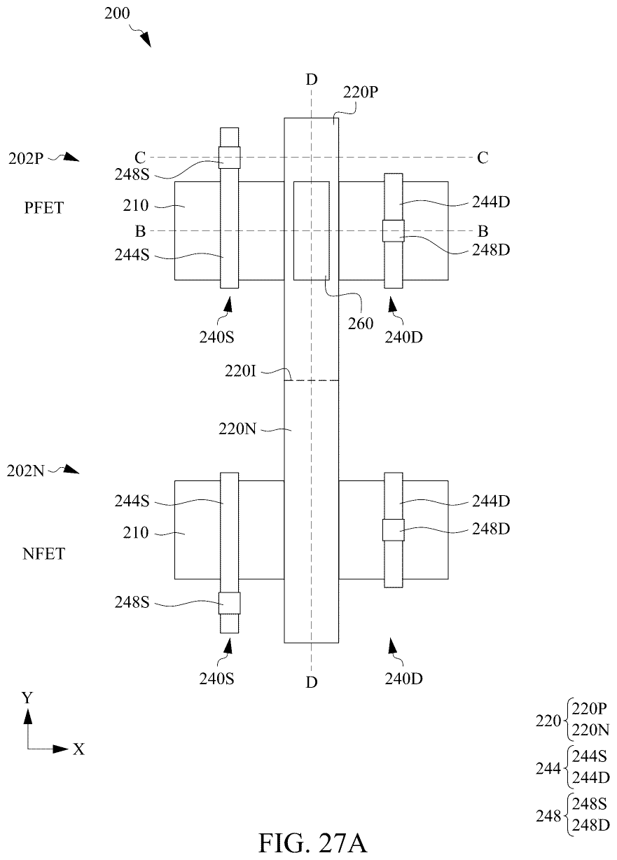

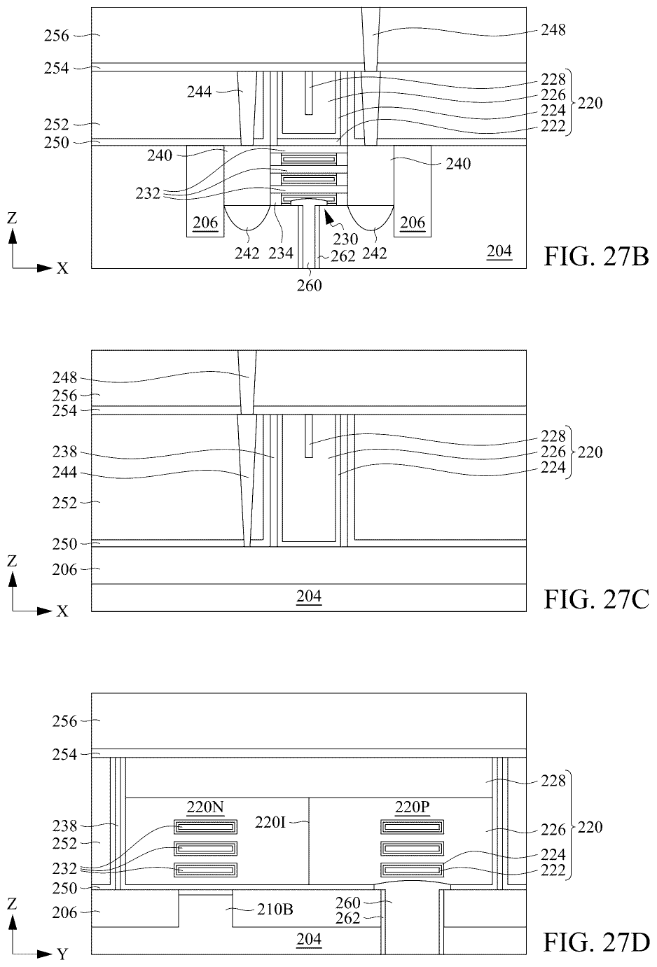

Reference is now made to FIGS. 27A-27D, which illustrate top and cross-sectional views of another embodiment of the device 200 that includes a pair of CMOS transistors with gate structures coupled to each other in the context of GAA construction. Many aspects of the device 200 as depicted in FIGS. 27A-27D are the same as or similar to those counterparts depicted in FIGS. 23A-23D. Reference numerals are repeated for ease of understanding. Such same or similar aspects are not repeated in the interest of conciseness. One difference is that the device 200 further includes a bottom dielectric layer 242 underneath the source/drain features 240. The bottom dielectric layer 242 increases resistance in the source/drain regions and suppresses the leakage current into the substrate. Because the bottom dielectric layer 242 may interface source/drain features 240 and oxygen content may oxidize source/drain features, the bottom dielectric layer 242 may be formed of an oxygen-free dielectric material, such as an oxygen-free nitride. In an example process, a chlorine-containing silicon nitride layer is deposited over the source/drain trenches. The bottom dielectric layer 242 may interface the bottommost inner spacer 234.

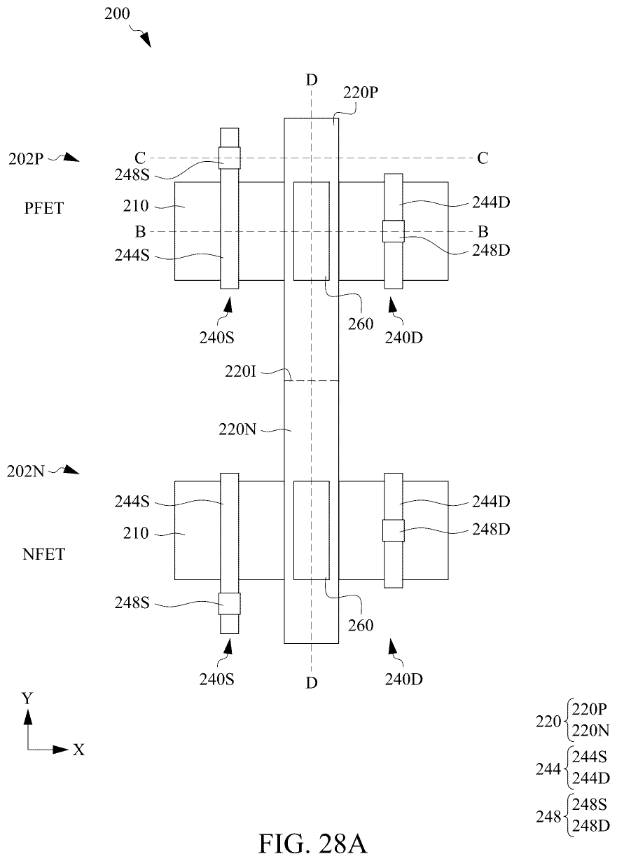

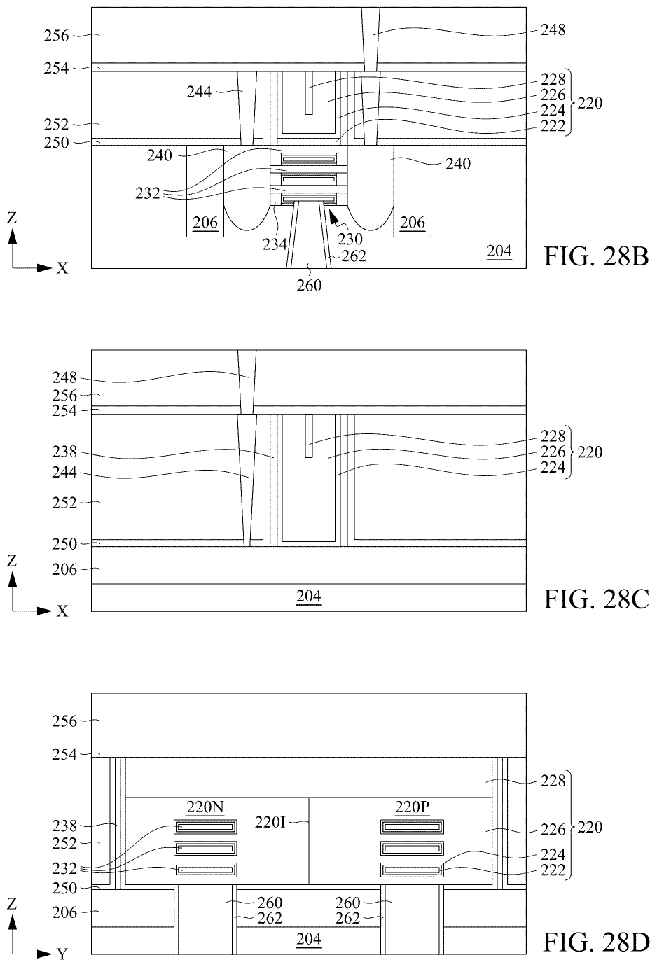

Reference is now made to FIGS. 28A-28D, which illustrate top and cross-sectional views of another embodiment of the device 200 that includes a pair of CMOS transistors with gate structures coupled to each other in the context of GAA construction. Many aspects of the device 200 as depicted in FIGS. 28A-28D are the same as or similar to those counterparts depicted in FIGS. 20A-20D. Reference numerals are repeated for ease of understanding. Such same or similar aspects are not repeated in the interest of conciseness. Some differences are discussed below. In the depicted embodiment, each active region 210 of the PFET 202P and the NFET 202N has a corresponding backside gate contact 260 positioned thereunder, such as shown in FIGS. 28A and 28D. The two backside gate contacts 260 are connected by a backside metal line in BM0 level (FIG. 2). By having two backside gate contacts 260, the routing resistance is further reduced. Also, by replacing both of the fin-shaped bases 210B in the channel regions, the leakage current into the substrate is further suppressed.

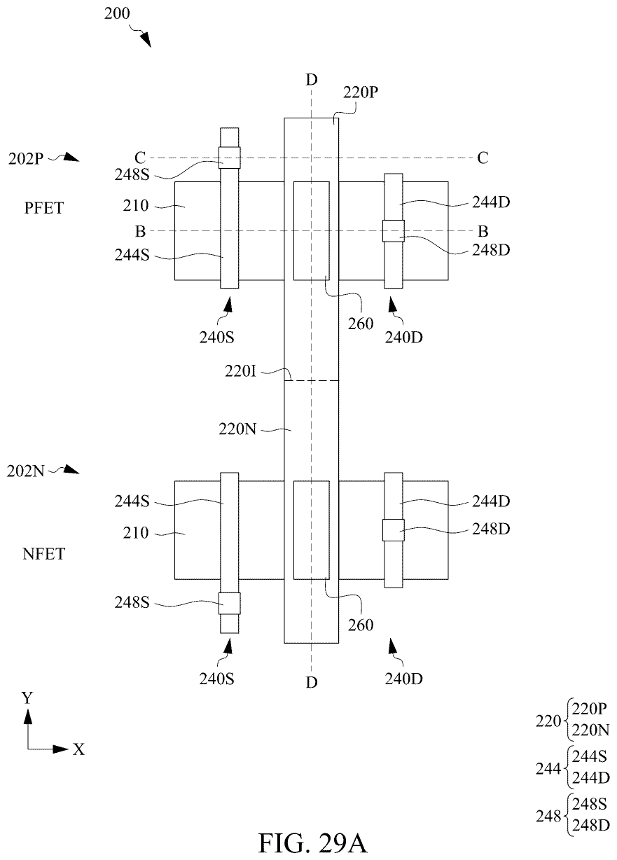

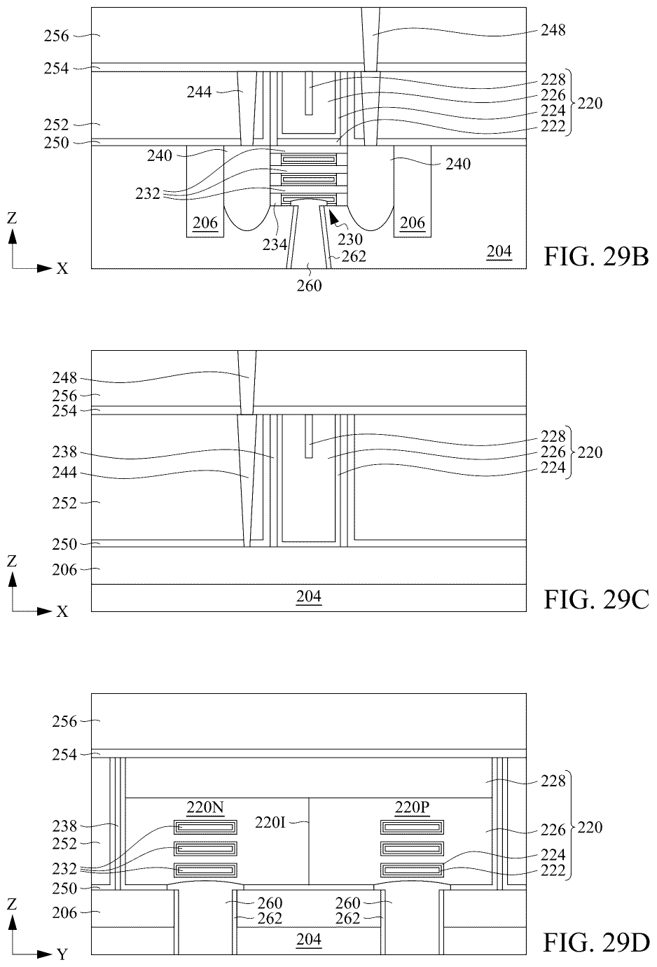

Reference is now made to FIGS. 29A-29D, which illustrate top and cross-sectional views of another embodiment of the device 200 that includes a pair of CMOS transistors with gate structures coupled to each other in the context of GAA construction. Many aspects of the device 200 as depicted in FIGS. 29A-9D are the same as or similar to those counterparts depicted in FIGS. 28A-28D. Reference numerals are repeated for ease of understanding. Such same or similar aspects are not repeated in the interest of conciseness. Some differences are discussed below. In the depicted embodiment as shown in FIGS. 29B and 29D, the backside gate contact 260 has a flange-like top portion. The curvature top surface of the flange-like top portion increases the contact area between the backside gate contact 260 and the gate structure 220 and thus reduces contact resistance. Specifically, after penetrating the high-k dielectric layer 224, the backside gate contact 260 increases in its width, forming a horizontally extended, flange-like region in its uppermost end, resulting in a distinct T-shaped or mushroom-shaped cross-sectional profile. In the X-Z plane, the sidewalls of the backside gate contact 260 may still exhibit a tapered profile, and the upper expanded portion may have a width greater than that of the lower region but less than that of the lowest portion embedded in the substrate 204. Alternatively, in the X-Z plane, the largest width of the whole backside gate contact 260 may reside in its flange-like region above the high-k dielectric layer 224. The flange-like region may be created by an over-etching process after the breakthrough (BT) etching process in forming dielectric liner 262 to create an expanded cavity above the high-k dielectric layer 224 and subsequently depositing the backside gate contact 260 into the backside opening and the expanded cavity. In the depicted embodiment, the dielectric liner 262 does not extend above the high-k dielectric layer 224. The largest width of the flange-like upper portion of the backside gate contact 260 is greater than a width of the active regions 210.

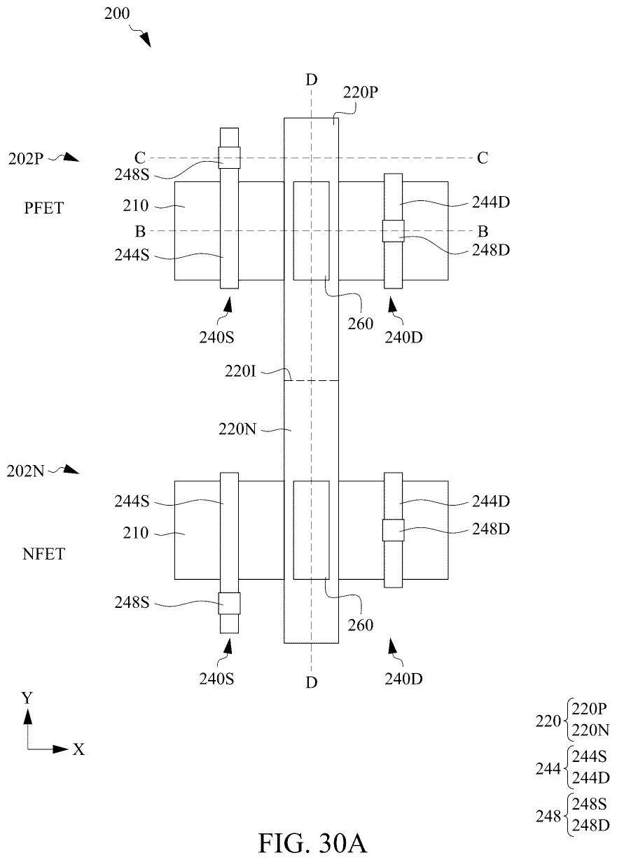

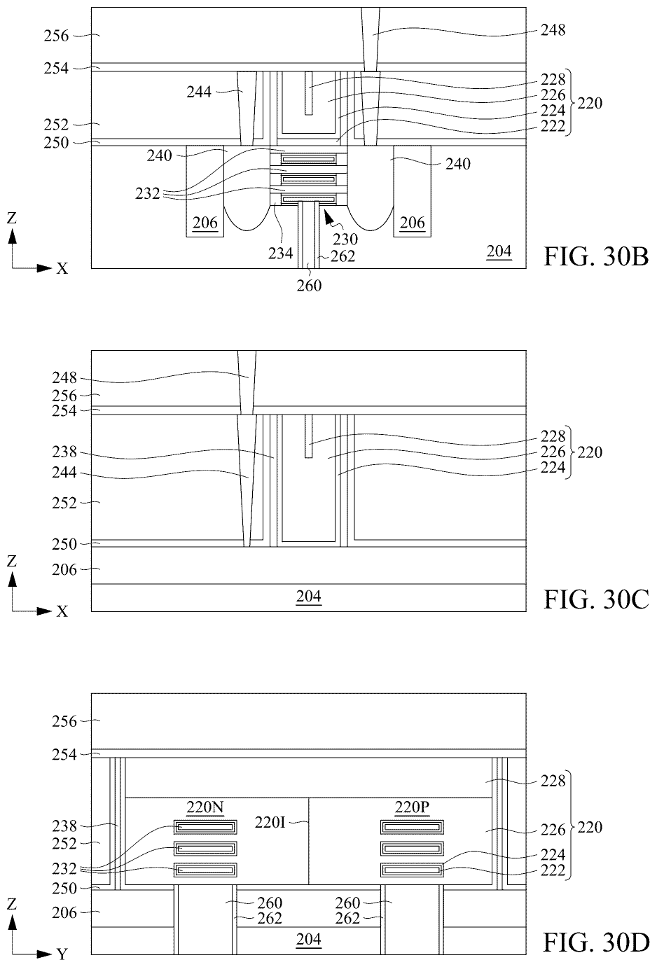

Reference is now made to FIGS. 30A-30D, which illustrate top and cross-sectional views of another embodiment of the device 200 that includes a pair of CMOS transistors with gate structures coupled to each other in the context of GAA construction. Many aspects of the device 200 as depicted in FIGS. 30A-30D are the same as or similar to those counterparts depicted in FIGS. 28A-28D. Reference numerals are repeated for ease of understanding. Such same or similar aspects are not repeated in the interest of conciseness. One difference is that each of the backside gate contacts 260 as depicted in FIG. 30B has substantially straight sidewalls. In other words, the backside gate contact 260 may have a uniform width from top to bottom in the X-Z plane as in the Y-Z plane, which may be due to a highly directional etching process applied in creating the backside opening that accommodates the backside gate contact 260.

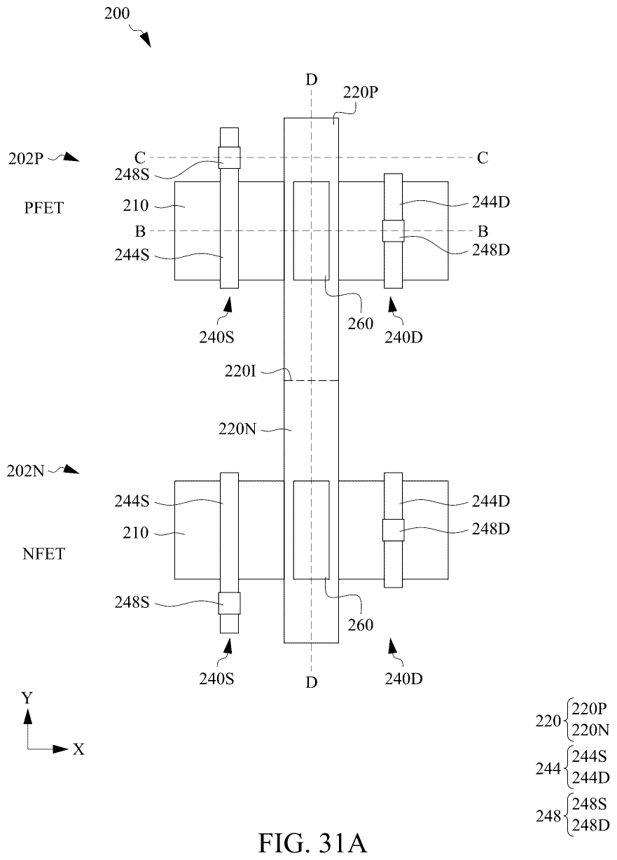

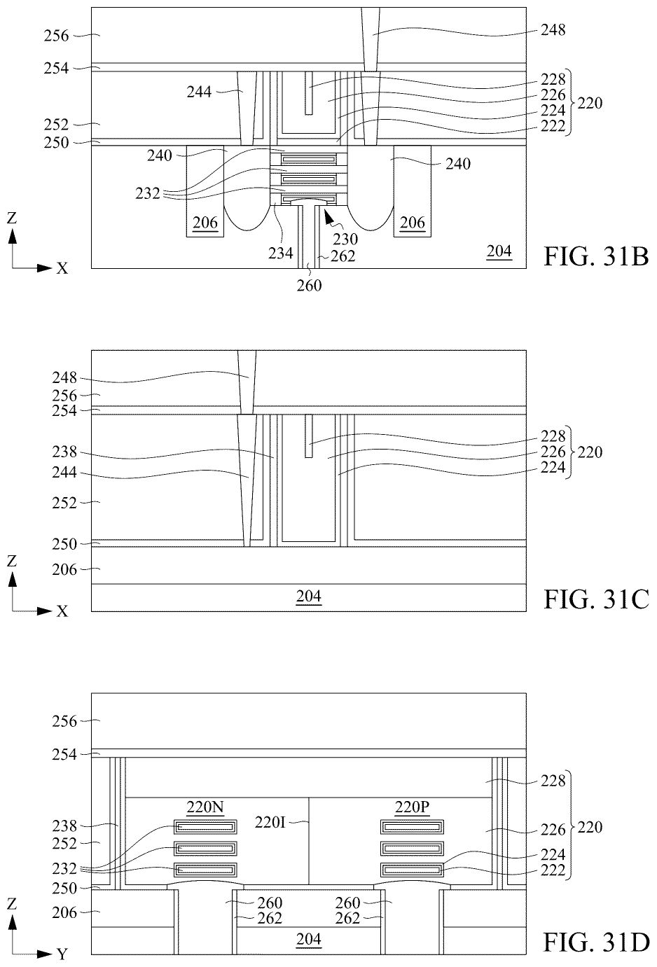

Reference is now made to FIGS. 31A-31D, which illustrate top and cross-sectional views of another embodiment of the device 200 that includes a pair of CMOS transistors with gate structures coupled to each other in the context of GAA construction. Many aspects of the device 200 as depicted in FIGS. 31A-31D are the same as or similar to those counterparts depicted in FIGS. 29A-29D. Reference numerals are repeated for ease of understanding. Such same or similar aspects are not repeated in the interest of conciseness. One difference is that the backside gate contact 260 as depicted in FIG. 31B has substantially straight sidewalls. In other words, each of the backside gate contacts 260 may have a uniform width in its lower portion in the X-Z plane as in the Y-Z plane, which may be due to a highly directional etching process applied in creating the backside opening that accommodates the backside gate contact 260.

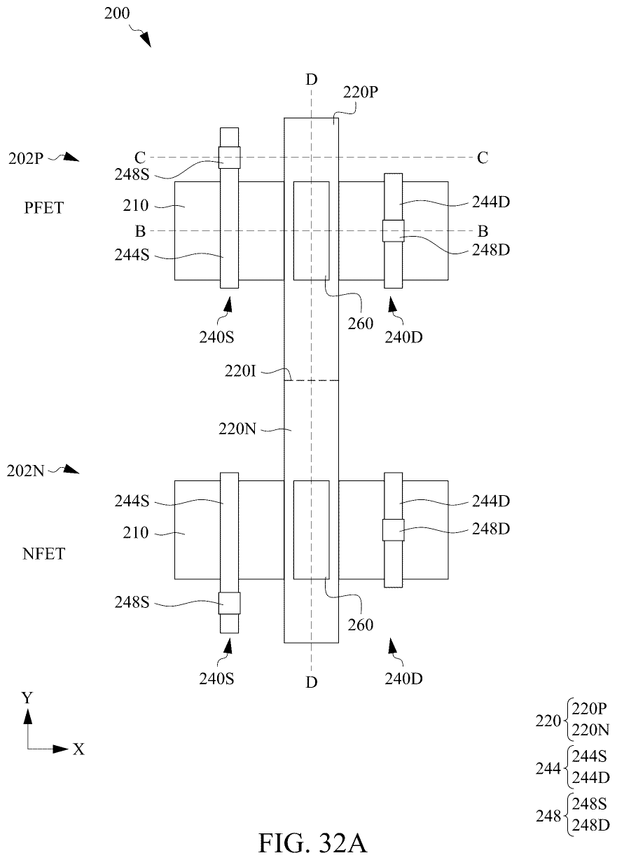

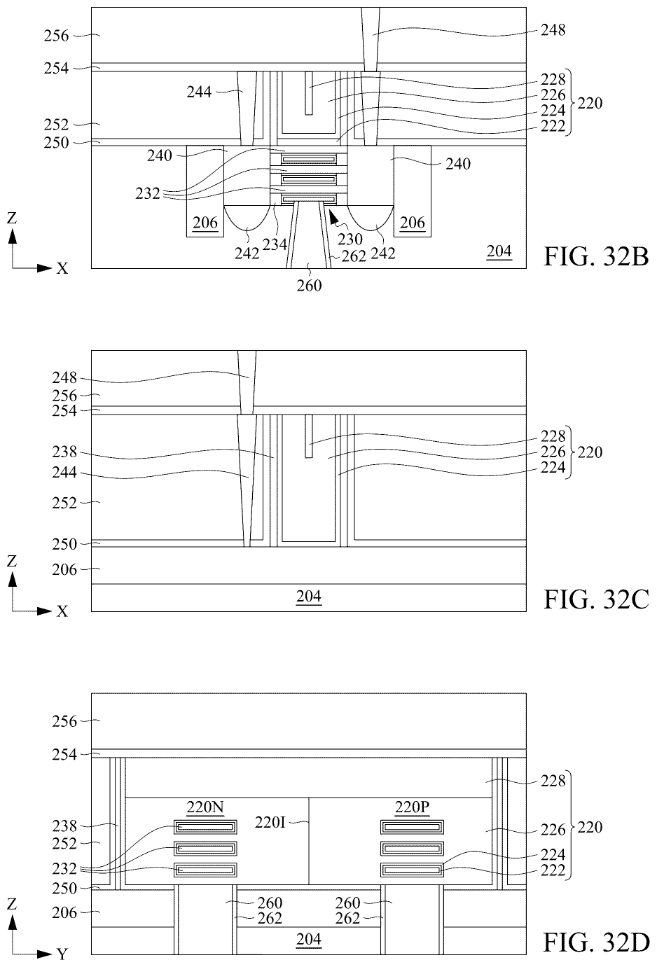

Reference is now made to FIGS. 32A-32D, which illustrate top and cross-sectional views of another embodiment of the device 200 that includes a pair of CMOS transistors with gate structures coupled to each other in the context of GAA construction. Many aspects of the device 200 as depicted in FIGS. 32A-32D are the same as or similar to those counterparts depicted in FIGS. 28A-28D. Reference numerals are repeated for ease of understanding. Such same or similar aspects are not repeated in the interest of conciseness. One difference is that the device 200 further includes a bottom dielectric layer 242 underneath the source/drain features 240. The bottom dielectric layer 242 increases resistance in the source/drain regions and suppresses the leakage current into the substrate. Because the bottom dielectric layer 242 may interface source/drain features 240 and oxygen content may oxidize source/drain features, the bottom dielectric layer 242 may be formed of an oxygen-free dielectric material, such as an oxygen-free nitride. In an example process, a chlorine-containing silicon nitride layer is deposited over the source/drain trenches. The bottom dielectric layer 242 may interface the bottommost inner spacer 234.

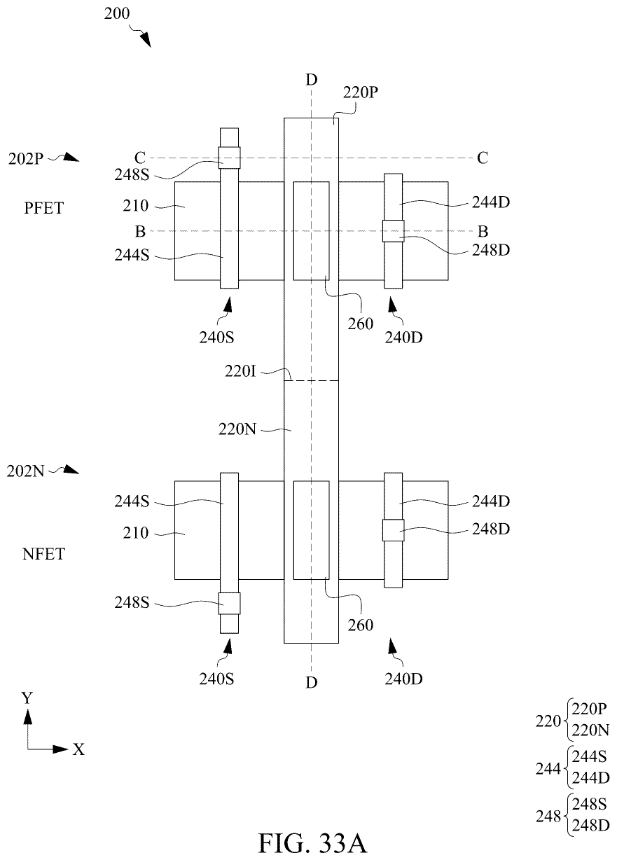

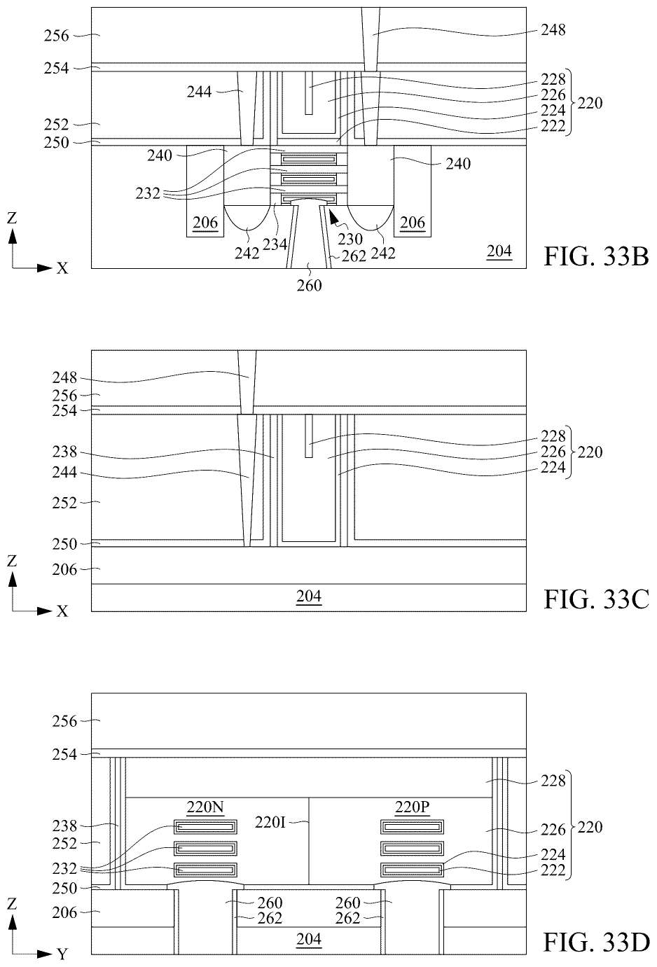

Reference is now made to FIGS. 33A-33D, which illustrate top and cross-sectional views of another embodiment of the device 200 that includes a pair of CMOS transistors with gate structures coupled to each other in the context of GAA construction. Many aspects of the device 200 as depicted in FIGS. 33A-33D are the same as or similar to those counterparts depicted in FIGS. 29A-29D. Reference numerals are repeated for ease of understanding. Such same or similar aspects are not repeated in the interest of conciseness. One difference is that the device 200 further includes a bottom dielectric layer 242 underneath the source/drain features 240. The bottom dielectric layer 242 increases resistance in the source/drain regions and suppresses the leakage current into the substrate. Because the bottom dielectric layer 242 may interface source/drain features 240 and oxygen content may oxidize source/drain features, the bottom dielectric layer 242 may be formed of an oxygen-free dielectric material, such as an oxygen-free nitride. In an example process, a chlorine-containing silicon nitride layer is deposited over the source/drain trenches. The bottom dielectric layer 242 may interface the bottommost inner spacer 234.

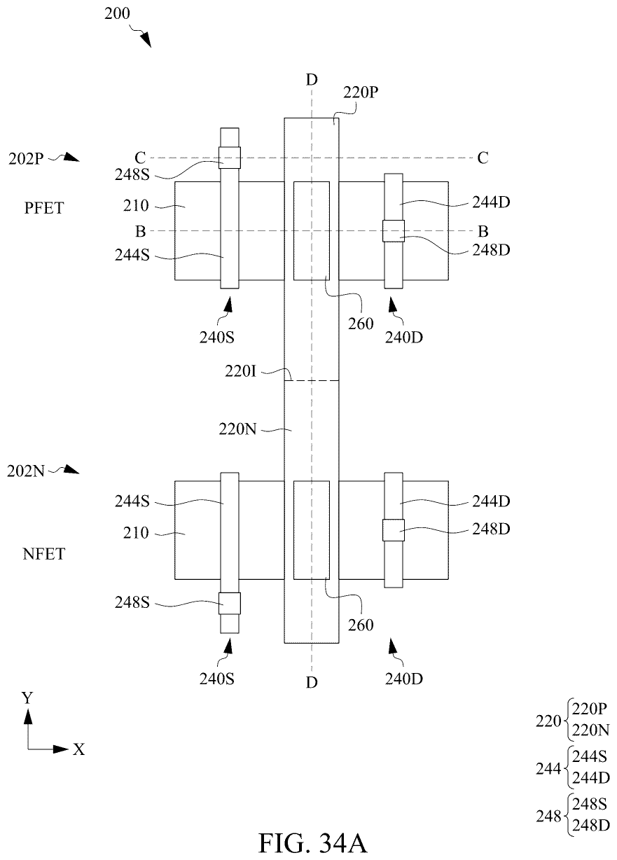

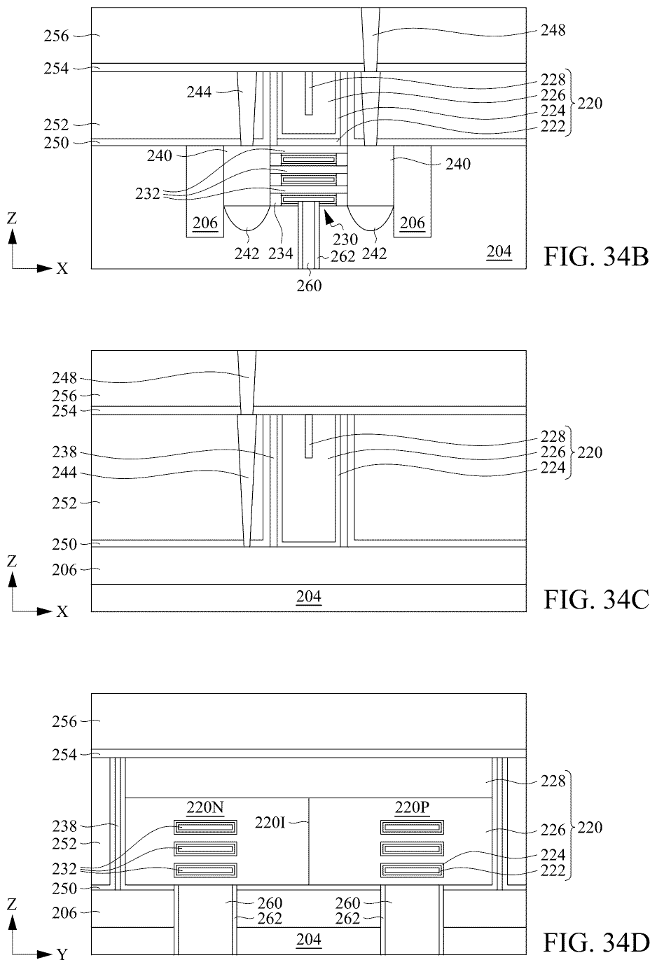

Reference is now made to FIGS. 34A-34D, which illustrate top and cross-sectional views of another embodiment of the device 200 that includes a pair of CMOS transistors with gate structures coupled to each other in the context of GAA construction. Many aspects of the device 200 as depicted in FIGS. 34A-34D are the same as or similar to those counterparts depicted in FIGS. 30A-30D. Reference numerals are repeated for ease of understanding. Such same or similar aspects are not repeated in the interest of conciseness. One difference is that the device 200 further includes a bottom dielectric layer 242 underneath the source/drain features 240. The bottom dielectric layer 242 increases resistance in the source/drain regions and suppresses the leakage current into the substrate. Because the bottom dielectric layer 242 may interface source/drain features 240 and oxygen content may oxidize source/drain features, the bottom dielectric layer 242 may be formed of an oxygen-free dielectric material, such as an oxygen-free nitride. In an example process, a chlorine-containing silicon nitride layer is deposited over the source/drain trenches. The bottom dielectric layer 242 may interface the bottommost inner spacer 234.

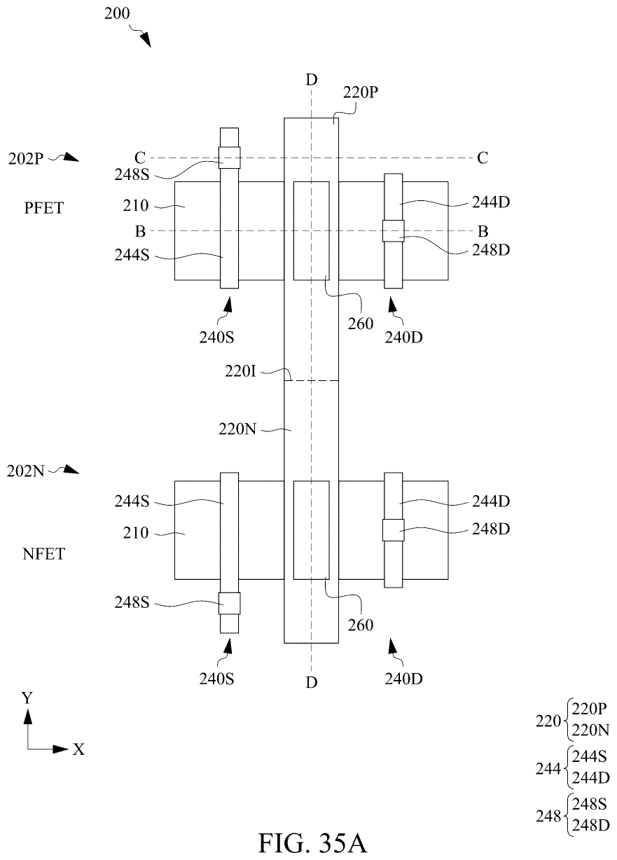

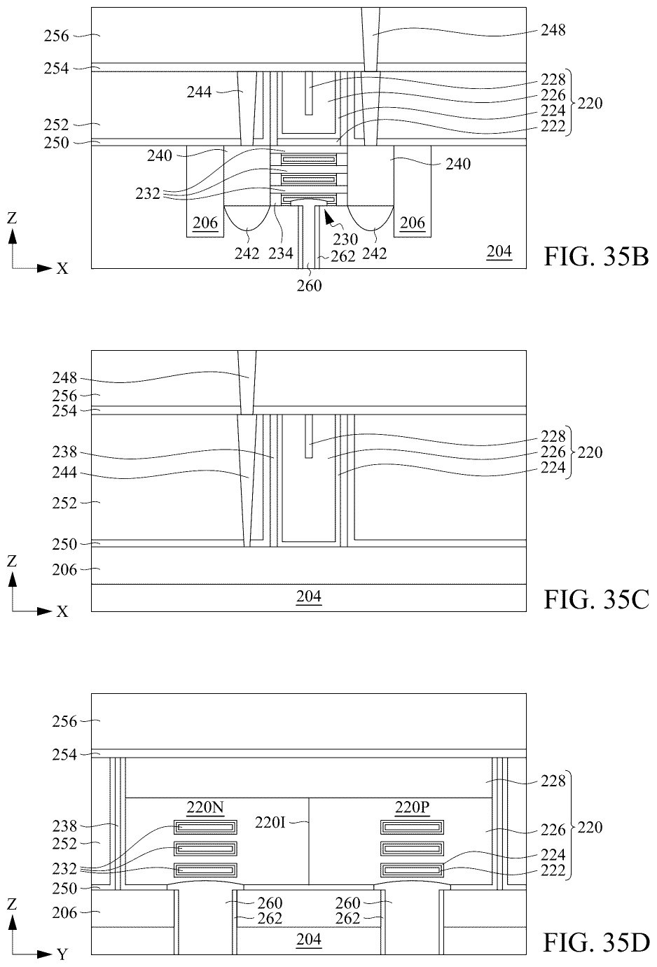

Reference is now made to FIGS. 35A-35D, which illustrate top and cross-sectional views of another embodiment of the device 200 that includes a pair of CMOS transistors with gate structures coupled to each other in the context of GAA construction. Many aspects of the device 200 as depicted in FIGS. 35A-35D are the same as or similar to those counterparts depicted in FIGS. 31A-31D. Reference numerals are repeated for ease of understanding. Such same or similar aspects are not repeated in the interest of conciseness. One difference is that the device 200 further includes a bottom dielectric layer 242 underneath the source/drain features 240. The bottom dielectric layer 242 increases resistance in the source/drain regions and suppresses the leakage current into the substrate. Because the bottom dielectric layer 242 may interface source/drain features 240 and oxygen content may oxidize source/drain features, the bottom dielectric layer 242 may be formed of an oxygen-free dielectric material, such as an oxygen-free nitride. In an example process, a chlorine-containing silicon nitride layer is deposited over the source/drain trenches. The bottom dielectric layer 242 may interface the bottommost inner spacer 234.

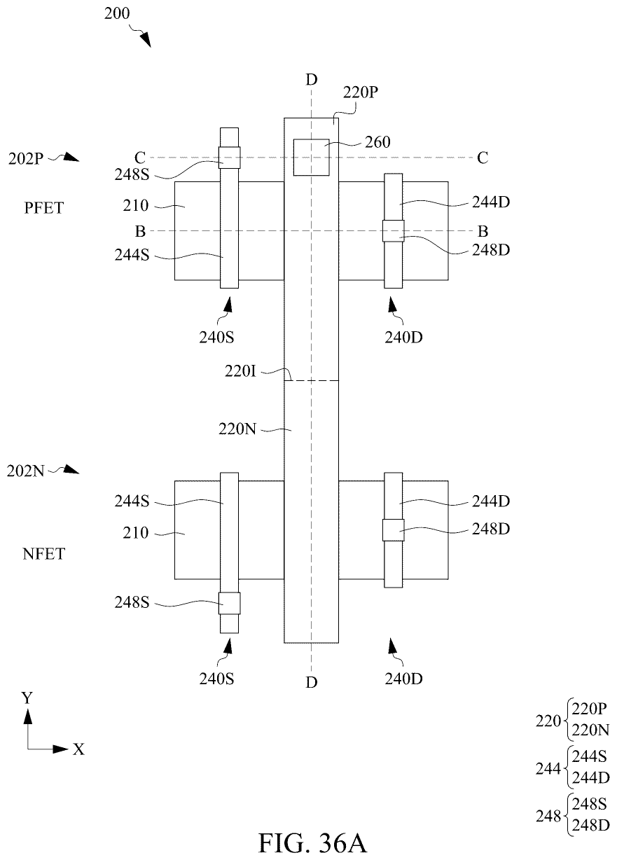

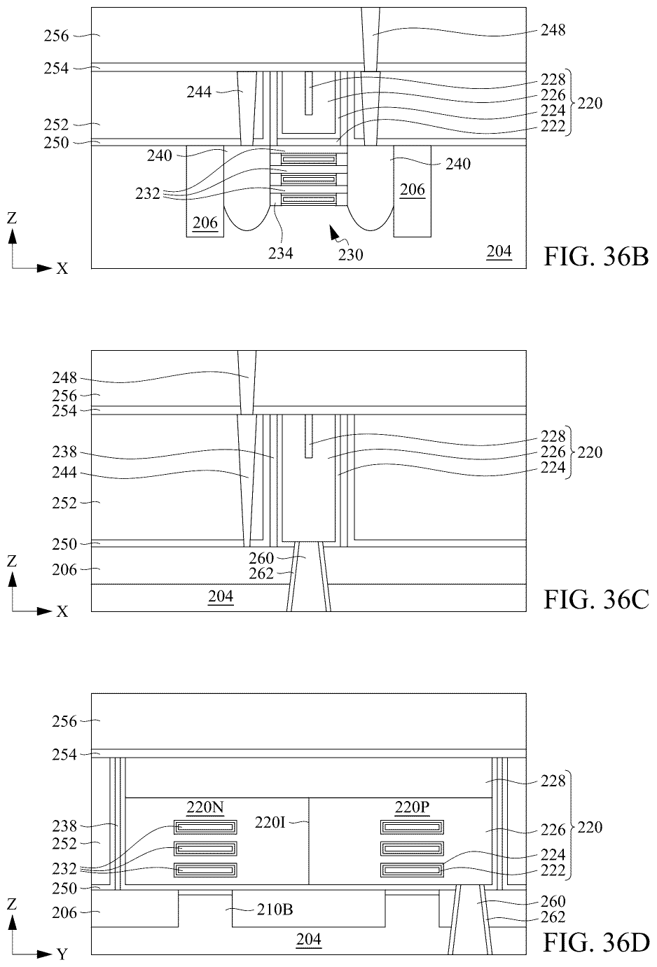

Reference is now made to FIGS. 36A-36D, which illustrate top and cross-sectional views of another embodiment of the device 200 that includes a pair of CMOS transistors with gate structures coupled to each other in the context of FinFET construction. Many aspects of the device 200 as depicted in FIGS. 36A-36D are the same as or similar to those counterparts depicted in FIGS. 12A-12D. Reference numerals are repeated for ease of understanding. Such same or similar aspects are not repeated in the interest of conciseness. One difference is that the backside gate contact 260 as depicted in FIGS. 36A and 36D is positioned at a location outside the active regions 210, such that the backside gate contact 260 is positioned on the same side of all the active regions 210, rather than interleaved between them. Since the region outside the active regions 210 may provide a larger area for routing, positioning the backside gate contact 260 offset from the active regions 210 can enlarge the process window for overlay control. In the depicted embodiment, the backside gate contact 260 and the source contact via 248S is aligned along the C-C line. FIGS. 36A and 36C also depict the backside gate contact 260 having a larger width than either the source/drain contact 244 or the source/drain contact via 248 due to the less routing density on the backside of the device 200, which effectively reduces the gate contact resistance.

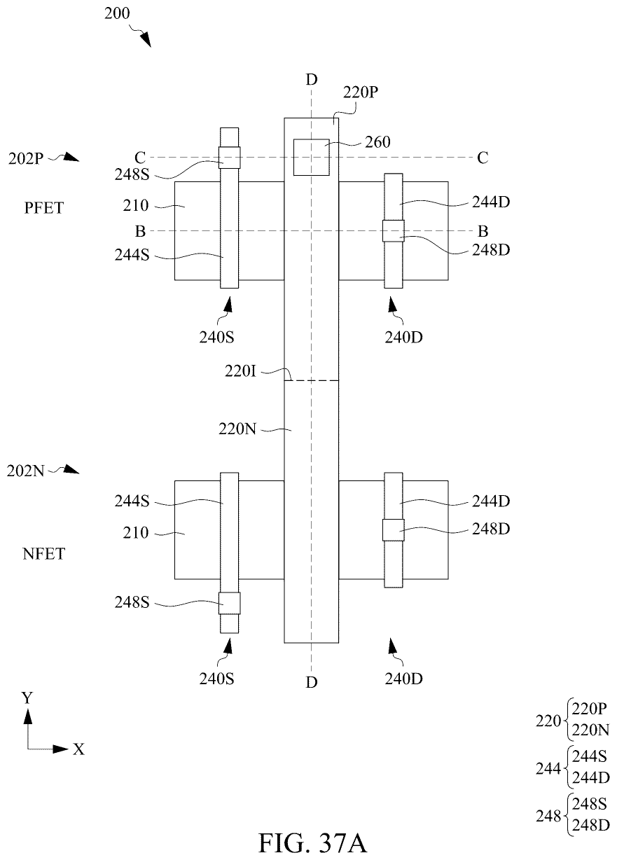

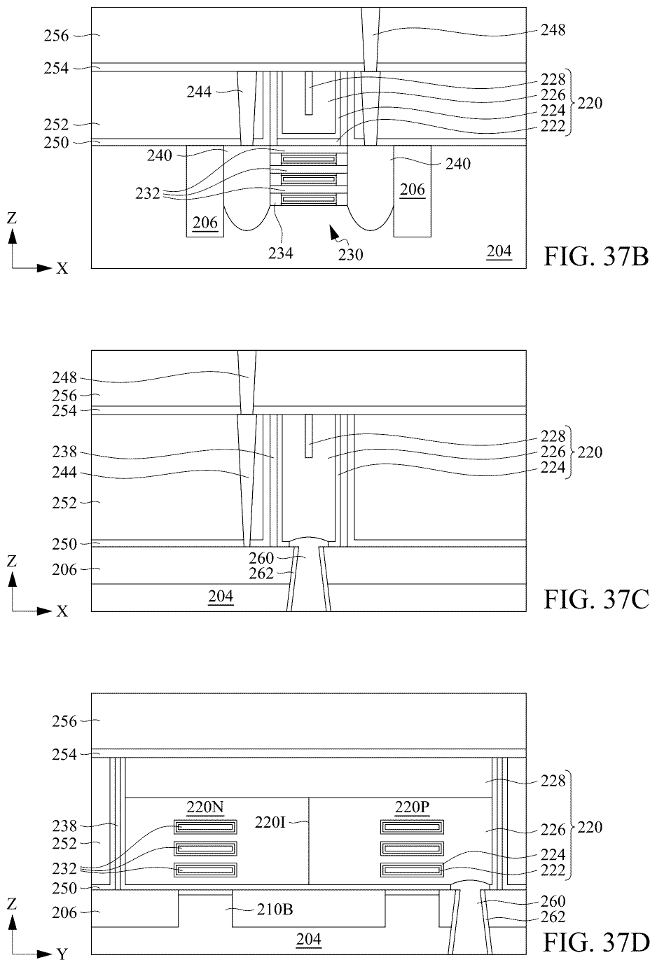

Reference is now made to FIGS. 37A-37D, which illustrate top and cross-sectional views of another embodiment of the device 200 that includes a pair of CMOS transistors with gate structures coupled to each other in the context of GAA construction. Many aspects of the device 200 as depicted in FIGS. 37A-37D are the same as or similar to those counterparts depicted in FIGS. 36A-36D. Reference numerals are repeated for ease of understanding. Such same or similar aspects are not repeated in the interest of conciseness. Some differences are discussed below. In the depicted embodiment as shown in FIGS. 37B and 37D, the backside gate contact 260 has a flange-like top portion. The curvature top surface of the flange-like top portion increases the contact area between the backside gate contact 260 and the gate structure 220 and thus reduces contact resistance. Specifically, after penetrating the high-k dielectric layer 224, the backside gate contact 260 increases in its width, forming a horizontally extended, flange-like region in its uppermost end, resulting in a distinct T-shaped or mushroom-shaped cross-sectional profile. In the illustrated embodiment, this upper expanded portion has a width greater than that of the lower region but less than that of the lowest portion embedded in the substrate 204. Alternatively, the largest width of the whole backside gate contact 260 may reside in its flange-like region above the high-k dielectric layer 224. The flange-like region may be created by an over-etching process after the breakthrough (BT) etching process in forming dielectric liner 262 to create an expanded cavity above the high-k dielectric layer 224 and subsequently depositing the backside gate contact 260 into the backside opening and the expanded cavity. In the depicted embodiment, the dielectric liner 262 does not extend above the high-k dielectric layer 224. The largest width of the flange-like upper portion of the backside gate contact 260 may be greater than a width of the active regions 210.

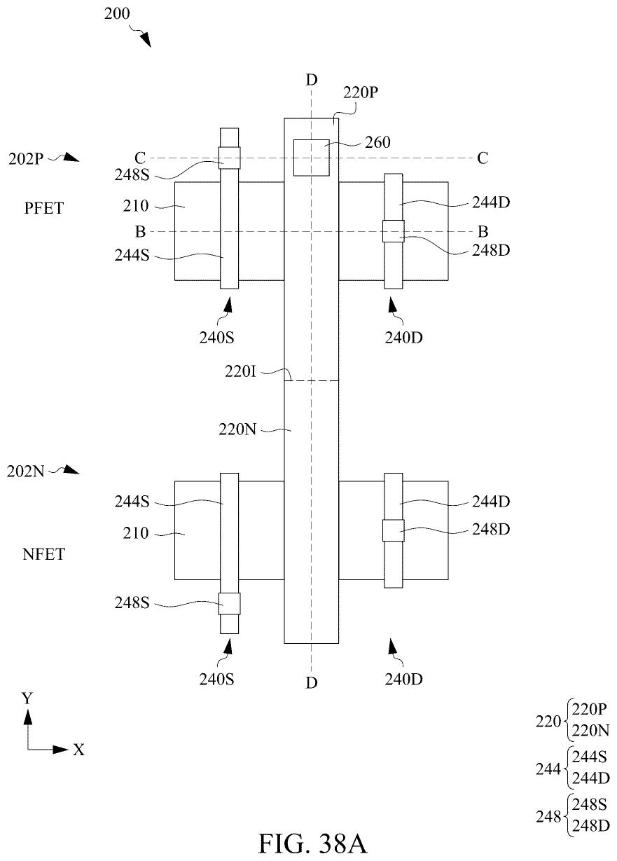

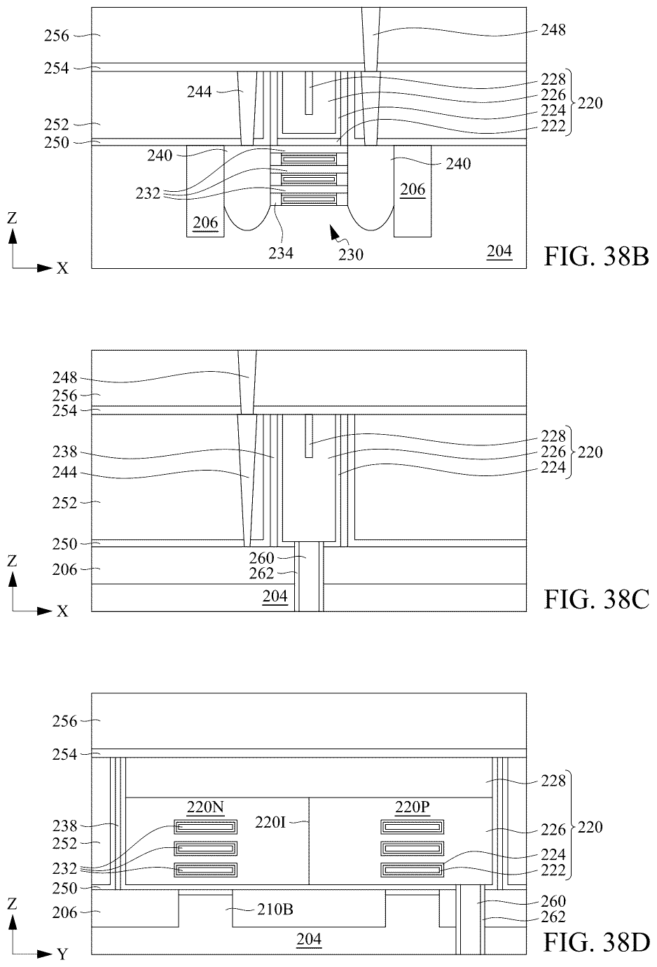

Reference is now made to FIGS. 38A-38D, which illustrate top and cross-sectional views of another embodiment of the device 200 that includes a pair of CMOS transistors with gate structures coupled to each other in the context of FinFET construction. Many aspects of the device 200 as depicted in FIGS. 38A-38D are the same as or similar to those counterparts depicted in FIGS. 36A-36D. Reference numerals are repeated for ease of understanding. Such same or similar aspects are not repeated in the interest of conciseness. One difference is that the backside gate contact 260 as depicted in FIGS. 38C and 38D has substantially straight sidewalls. In other words, the backside gate contact 260 may have a uniform width from top to bottom, which may be due to a highly directional etching process applied in creating the backside opening that accommodates the backside gate contact 260.

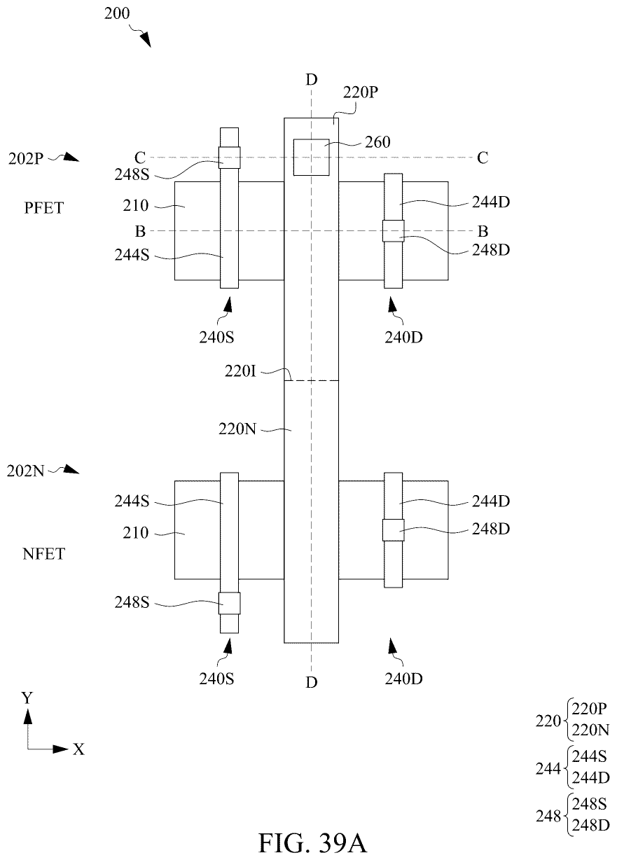

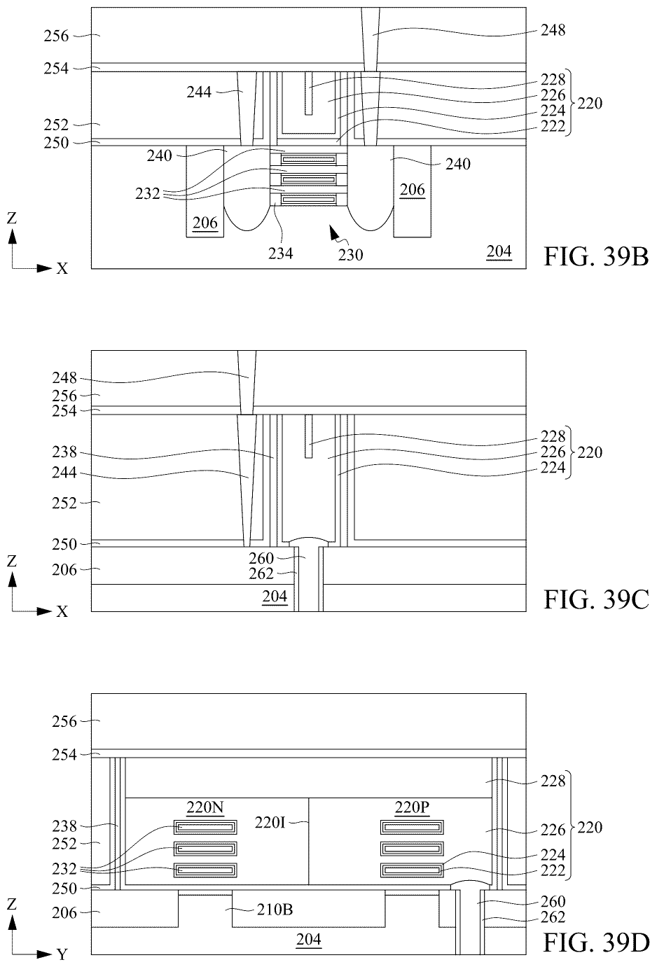

Reference is now made to FIGS. 39A-39D, which illustrate top and cross-sectional views of another embodiment of the device 200 that includes a pair of CMOS transistors with gate structures coupled to each other in the context of FinFET construction. Many aspects of the device 200 as depicted in FIGS. 39A-39D are the same as or similar to those counterparts depicted in FIGS. 37A-37D. Reference numerals are repeated for ease of understanding. Such same or similar aspects are not repeated in the interest of conciseness. One difference is that the backside gate contact 260 as depicted in FIGS. 39C and 39D has substantially straight sidewalls. In other words, the backside gate contact 260 may have a uniform width from top to bottom, which may be due to a highly directional etching process applied in creating the backside opening that accommodates the backside gate contact 260.

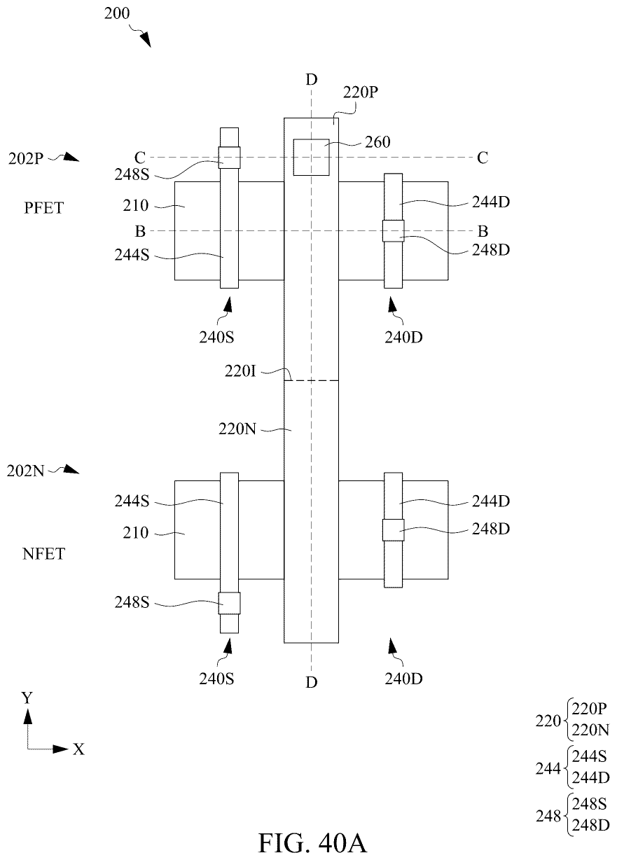

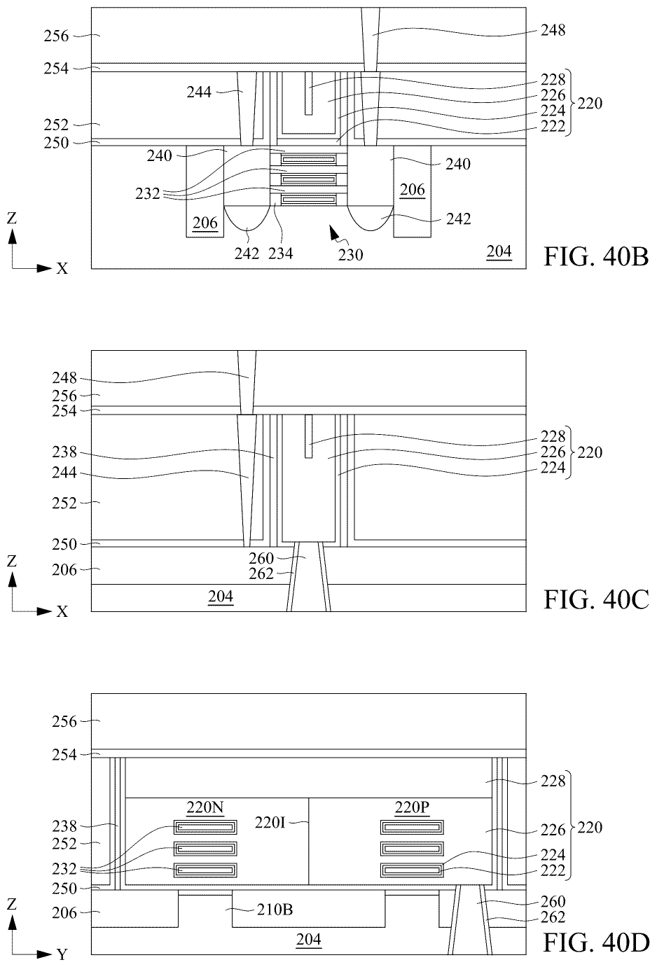

Reference is now made to FIGS. 40A-40D, which illustrate top and cross-sectional views of another embodiment of the device 200 that includes a pair of CMOS transistors with gate structures coupled to each other in the context of GAA construction. Many aspects of the device 200 as depicted in FIGS. 40A-40D are the same as or similar to those counterparts depicted in FIGS. 36A-36D. Reference numerals are repeated for ease of understanding. Such same or similar aspects are not repeated in the interest of conciseness. One difference is that the device 200 further includes a bottom dielectric layer 242 underneath the source/drain features 240. The bottom dielectric layer 242 increases resistance in the source/drain regions and suppresses the leakage current into the substrate. Because the bottom dielectric layer 242 may interface source/drain features 240 and oxygen content may oxidize source/drain features, the bottom dielectric layer 242 may be formed of an oxygen-free dielectric material, such as an oxygen-free nitride. In an example process, a chlorine-containing silicon nitride layer is deposited over the source/drain trenches. The bottom dielectric layer 242 may interface the bottommost inner spacer 234.

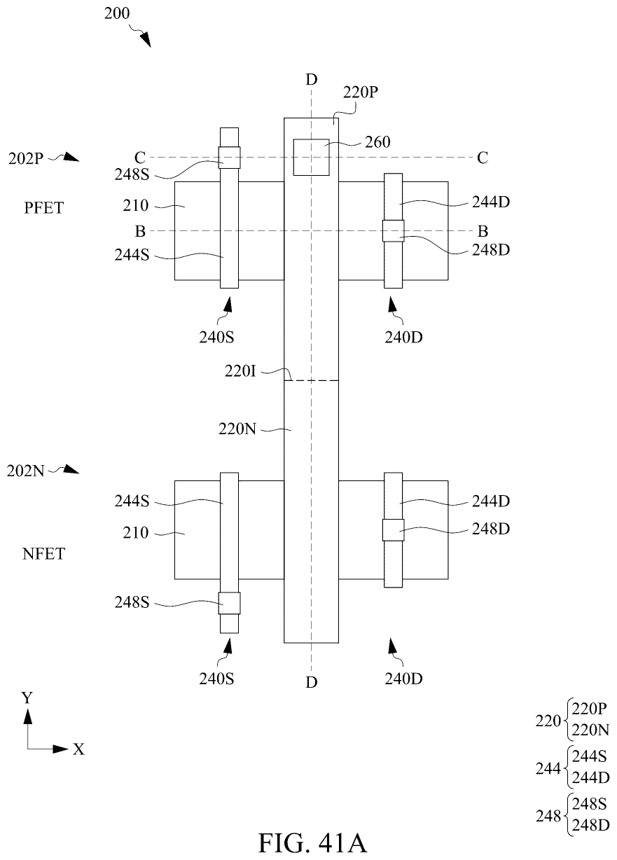

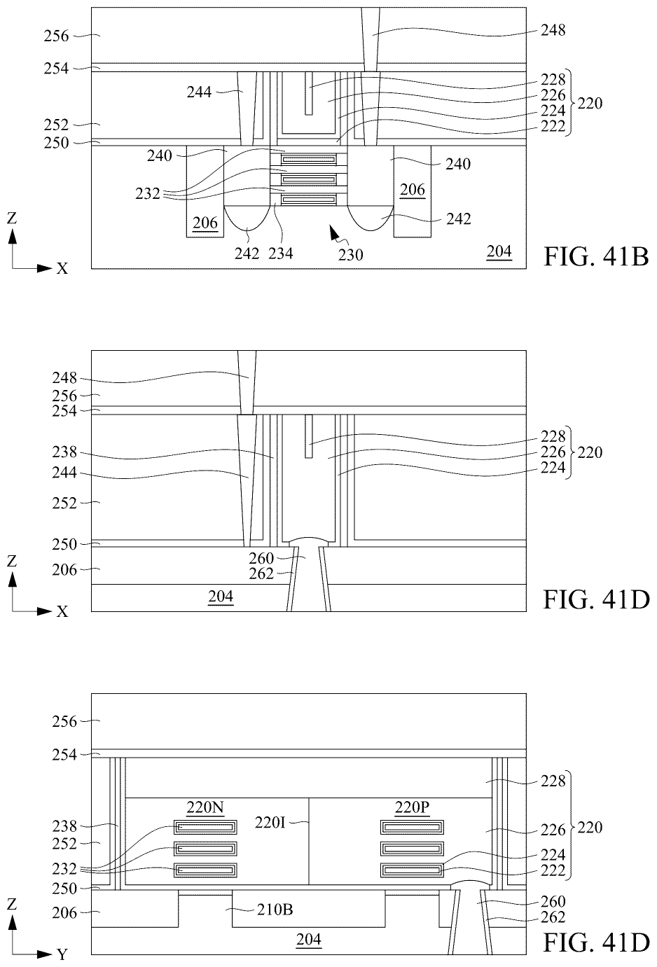

Reference is now made to FIGS. 41A-41D, which illustrate top and cross-sectional views of another embodiment of the device 200 that includes a pair of CMOS transistors with gate structures coupled to each other in the context of GAA construction. Many aspects of the device 200 as depicted in FIGS. 41A-41D are the same as or similar to those counterparts depicted in FIGS. 37A-37D. Reference numerals are repeated for ease of understanding. Such same or similar aspects are not repeated in the interest of conciseness. One difference is that the device 200 further includes a bottom dielectric layer 242 underneath the source/drain features 240. The bottom dielectric layer 242 increases resistance in the source/drain regions and suppresses the leakage current into the substrate. Because the bottom dielectric layer 242 may interface source/drain features 240 and oxygen content may oxidize source/drain features, the bottom dielectric layer 242 may be formed of an oxygen-free dielectric material, such as an oxygen-free nitride. In an example process, a chlorine-containing silicon nitride layer is deposited over the source/drain trenches. The bottom dielectric layer 242 may interface the bottommost inner spacer 234.

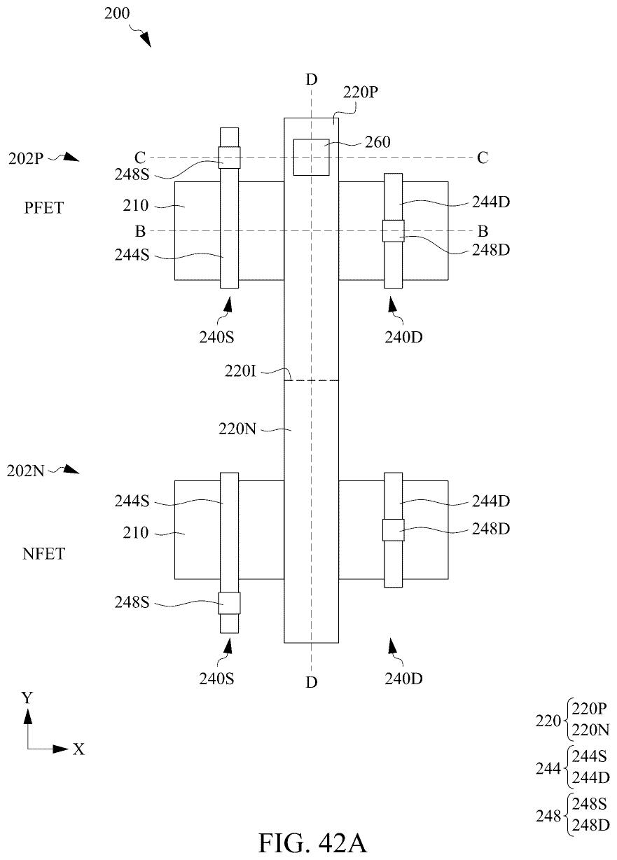

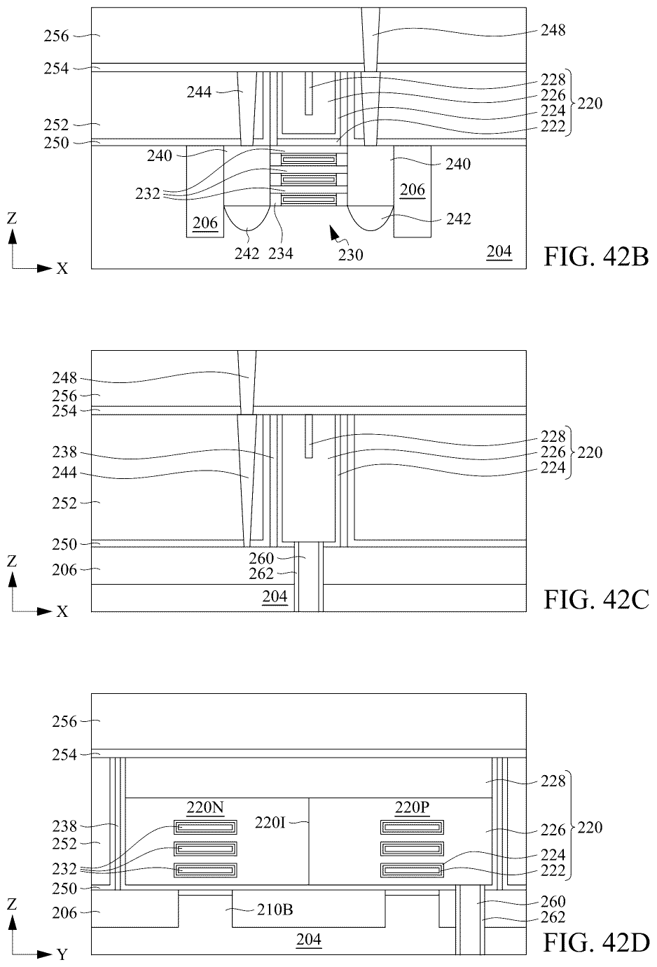

Reference is now made to FIGS. 42A-42D, which illustrate top and cross-sectional views of another embodiment of the device 200 that includes a pair of CMOS transistors with gate structures coupled to each other in the context of GAA construction. Many aspects of the device 200 as depicted in FIGS. 42A-42D are the same as or similar to those counterparts depicted in FIGS. 38A-38D. Reference numerals are repeated for ease of understanding. Such same or similar aspects are not repeated in the interest of conciseness. One difference is that the device 200 further includes a bottom dielectric layer 242 underneath the source/drain features 240. The bottom dielectric layer 242 increases resistance in the source/drain regions and suppresses the leakage current into the substrate. Because the bottom dielectric layer 242 may interface source/drain features 240 and oxygen content may oxidize source/drain features, the bottom dielectric layer 242 may be formed of an oxygen-free dielectric material, such as an oxygen-free nitride. In an example process, a chlorine-containing silicon nitride layer is deposited over the source/drain trenches. The bottom dielectric layer 242 may interface the bottommost inner spacer 234.

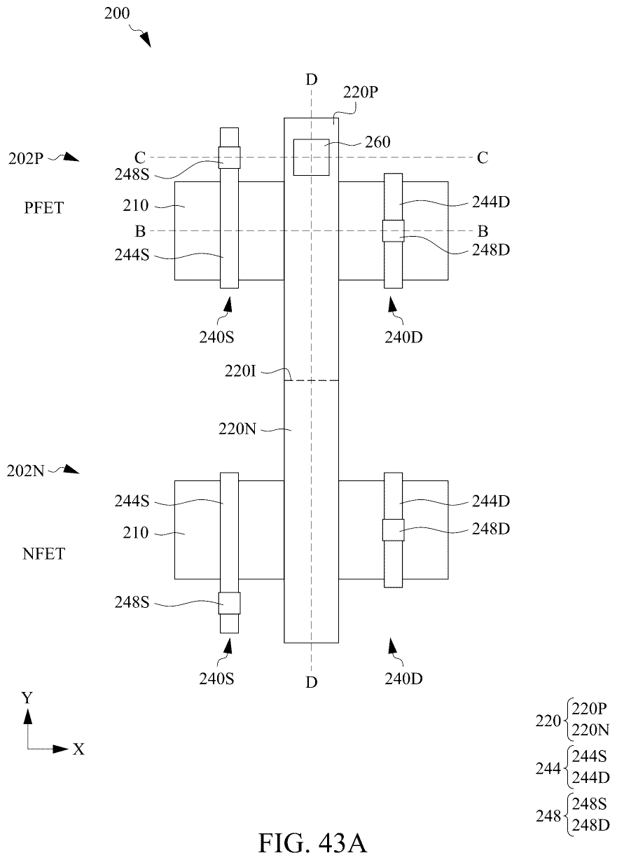

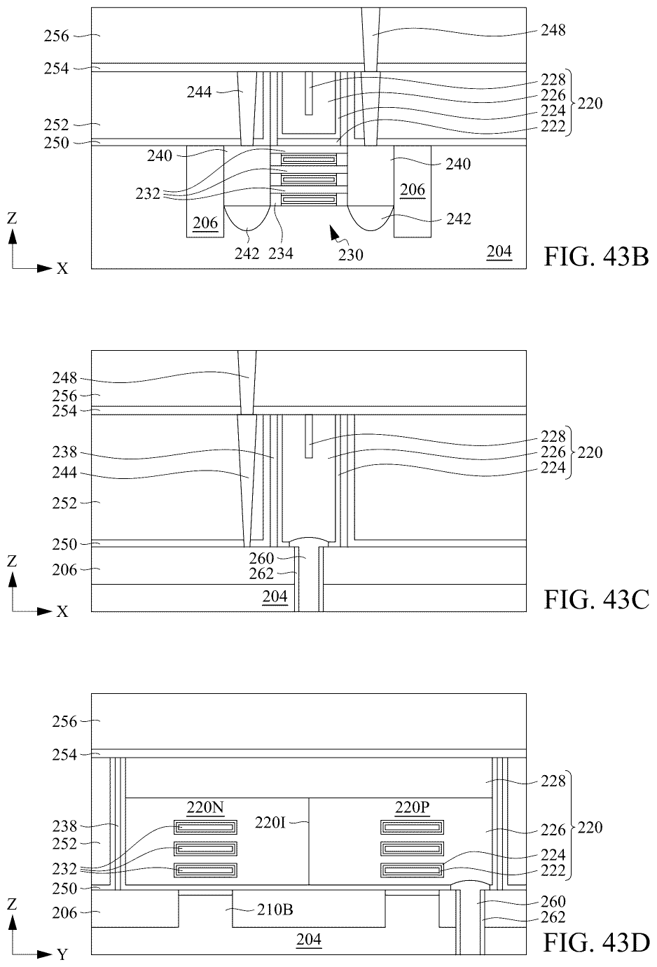

Reference is now made to FIGS. 43A-43D, which illustrate top and cross-sectional views of another embodiment of the device 200 that includes a pair of CMOS transistors with gate structures coupled to each other in the context of GAA construction. Many aspects of the device 200 as depicted in FIGS. 43A-43D are the same as or similar to those counterparts depicted in FIGS. 39A-39D. Reference numerals are repeated for ease of understanding. Such same or similar aspects are not repeated in the interest of conciseness. One difference is that the device 200 further includes a bottom dielectric layer 242 underneath the source/drain features 240. The bottom dielectric layer 242 increases resistance in the source/drain regions and suppresses the leakage current into the substrate. Because the bottom dielectric layer 242 may interface source/drain features 240 and oxygen content may oxidize source/drain features, the bottom dielectric layer 242 may be formed of an oxygen-free dielectric material, such as an oxygen-free nitride. In an example process, a chlorine-containing silicon nitride layer is deposited over the source/drain trenches. The bottom dielectric layer 242 may interface the bottommost inner spacer 234.

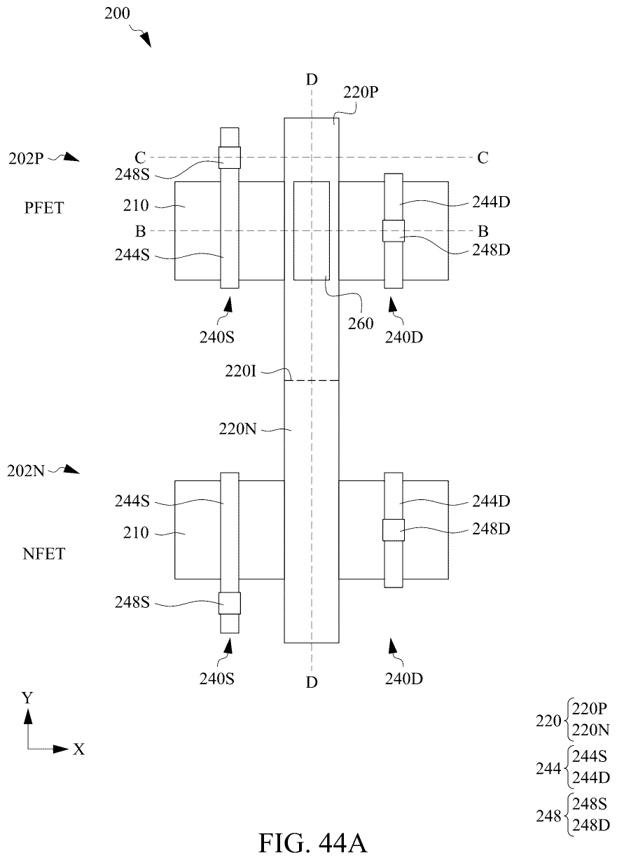

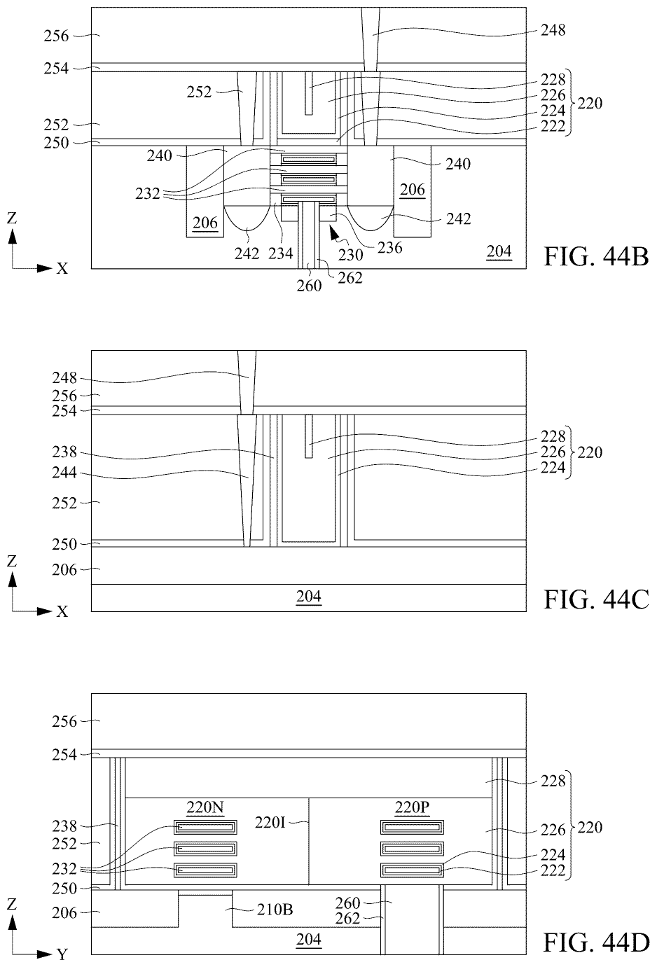

Reference is now made to FIGS. 44A-44D, which illustrate top and cross-sectional views of another embodiment of the device 200 that includes a pair of CMOS transistors with gate structures coupled to each other in the context of GAA construction. Many aspects of the device 200 as depicted in FIGS. 44A-44D are the same as or similar to those counterparts depicted in FIGS. 26A-26D. Reference numerals are repeated for ease of understanding. Such same or similar aspects are not repeated in the interest of conciseness. One difference is that the device 200 further includes an under-gate isolation structure 236 positioned directly under the gate structure 220. The under-gate isolation structure 236 may interface the bottom surface of the gate structure 220. The backside gate contact 260 extends through the under-gate isolation structure 236. In some embodiments, the under-gate isolation structure 236 may include oxide (such as silicon oxide), nitride (such as silicon nitride), or a combination thereof. In some embodiments, the under-gate isolation structure 236 may include the same material composition as the bottom dielectric layer 242. In the depicted embodiment, the under-gate isolation structure 236 and the bottom dielectric layer 242 are spaced apart from each other with inner spacers 234 interposing between. In some alternative embodiments, the under-gate isolation structure 236 and the bottom dielectric layer 242 are connected to each other forming a continuous dielectric isolation layer, such as being portions of a substrate-on-insulator (SOI) structure. For example, the continuous dielectric isolation layer may separate the bottommost inner spacer 234 from the substrate 204. In some alternative embodiments, instead of forming the under-gate isolation structure 236, the whole substrate 204 may be removed in a backside etching process and replaced with a backside dielectric layer by a backside deposition process.

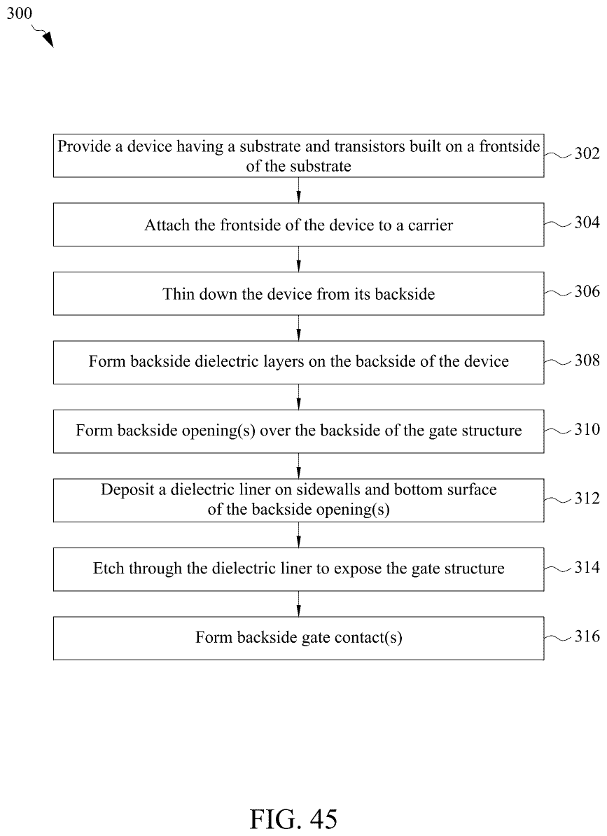

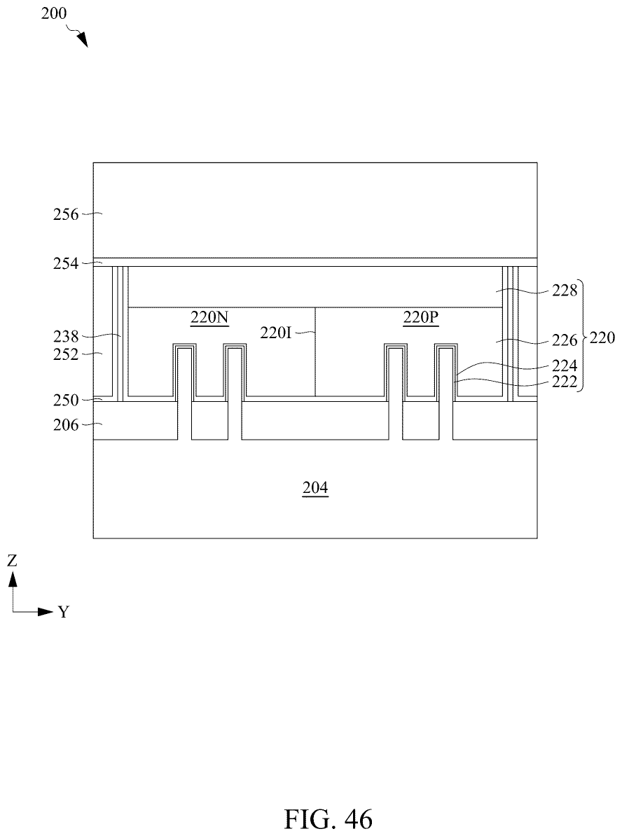

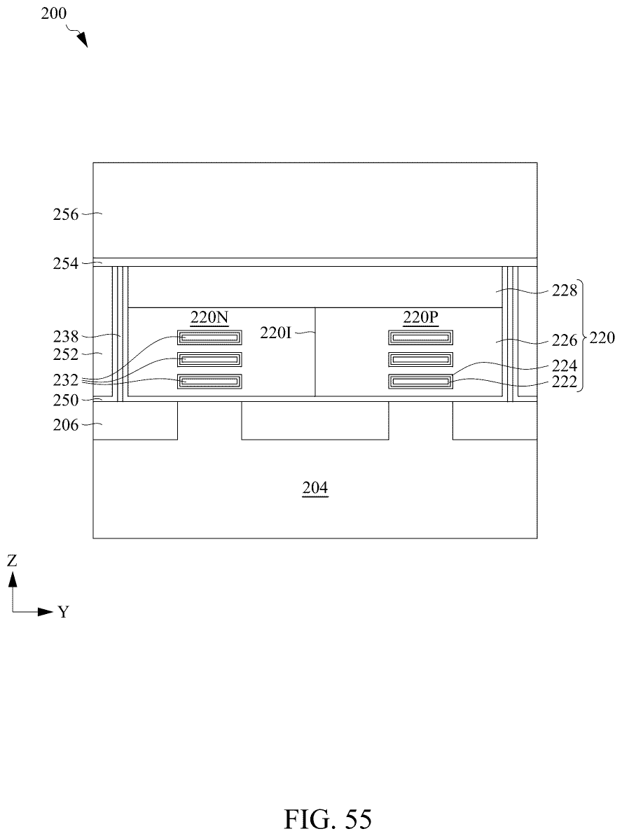

FIG. 45 illustrates a flow chart of a method 300 for fabricating a semiconductor device (or device) 200 in conjunction with FIGS. 46-54 and FIGS. 55-63. The device 200 as depicted in FIGS. 46-54 is substantially similar to the device as depicted in FIGS. 4A-4D, according to some embodiments of the present disclosure. The device 200 as depicted in FIGS. 55-63 is substantially similar to the device as depicted in FIGS. 28A-28D, according to some embodiments of the present disclosure. It is understood that the same operations can be applied to other embodiments shown in FIGS. 5A-27D and 29A-44D, which are not repeated in the interest of conciseness. Additional processing is contemplated by the present disclosure. Additional operations can be provided before, during, and after method 300, and some of the operations described can be moved, replaced, or eliminated for additional embodiments of method 300.

Referring to FIG. 45 and FIG. 46 (or FIG. 55), at operation 302, the method 300 provides the device 200 having a substrate 204 at its backside and various elements including transistors 202N and 202P built on its frontside. Many aspects of the device 200 as depicted in FIG. 46 are the same as or similar to those counterparts depicted in FIG. 4D; many aspects of the device 200 as depicted in FIG. 55 are the same as or similar to those counterparts depicted in FIG. 28D. Reference numerals are repeated for ease of understanding. Such same or similar aspects are not repeated in the interest of conciseness.

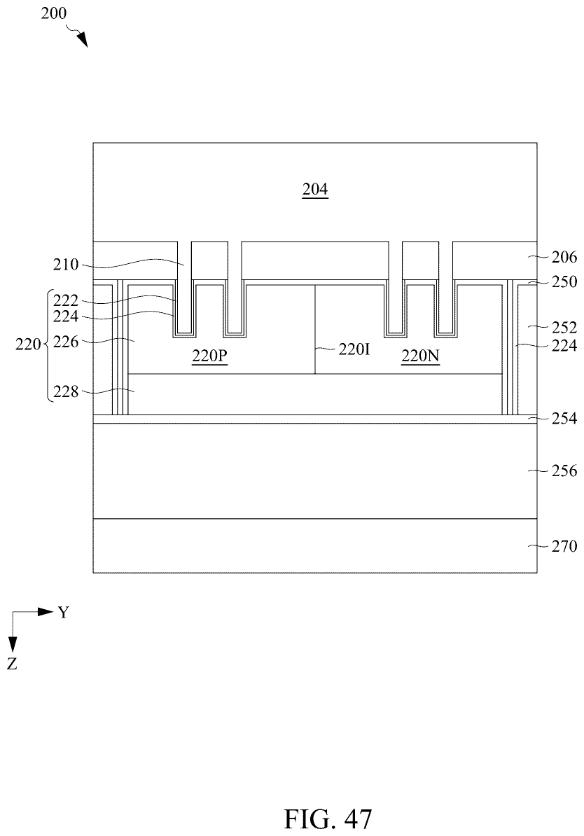

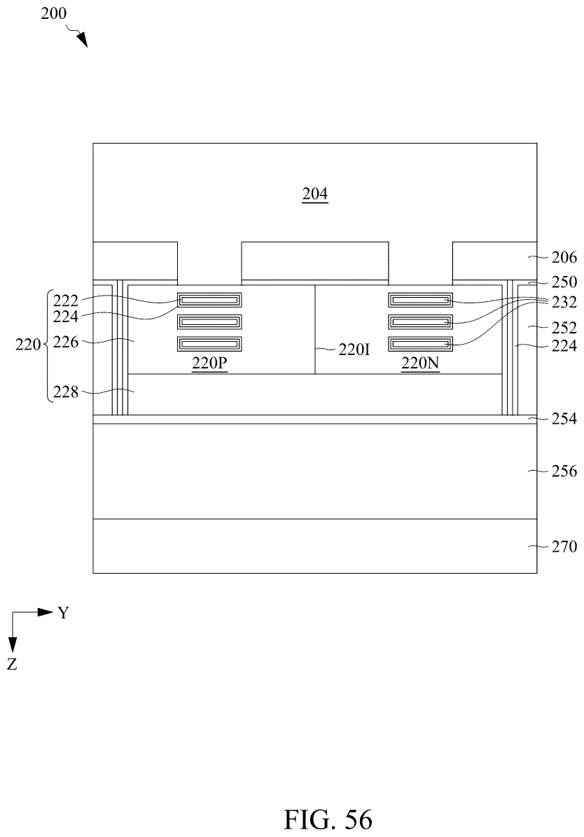

Referring to FIG. 45 and FIG. 47 (or FIG. 56), at operation 304, the method 300 attaches the frontside of the device 200 to a carrier 270 and flips the device 200 upside down and. This makes the device 200 accessible from the backside of the device 200 for further processing. The operation 304 may use any suitable attaching processes, such as direct bonding, hybrid bonding, using adhesive, or other bonding methods. The operation 304 may further include alignment, annealing, and/or other processes. The carrier 270 may be a silicon wafer in some embodiments.

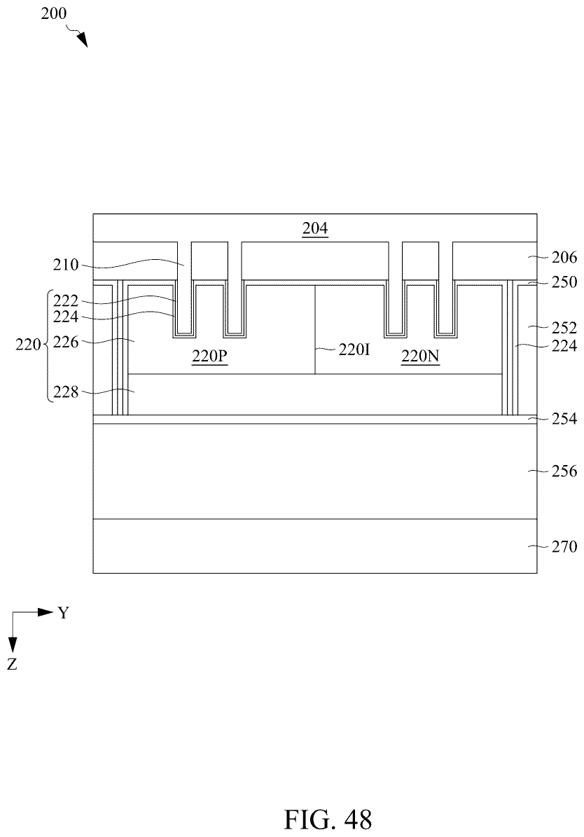

Referring to FIG. 45 and FIG. 48 (or FIG. 57), at operation 306, the method 300 thins down the device 200 from the backside of the device 200. The thinning process may include a mechanical grinding process and/or a chemical thinning process. A substantial amount of substrate material may be first removed from the substrate 204 during a mechanical grinding process. Afterwards, a chemical thinning process may apply an etching chemical to the backside of the substrate 204 to further thin down the substrate 204.

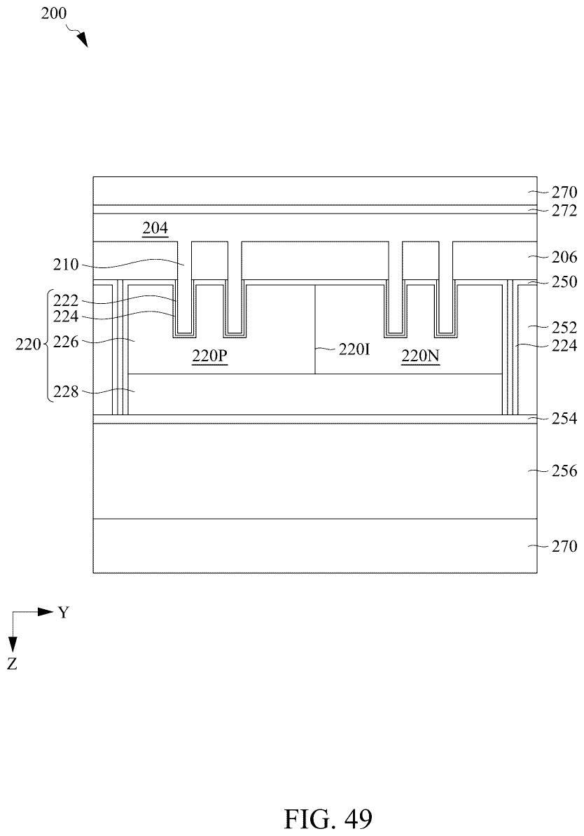

Referring to FIG. 45 and FIG. 49 (or FIG. 58), at operation 308, the method 300 deposits a backside CESL 272 and a backside ILD layer 274 over the backside CESL 272. The backside CESL 272 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s); and may be formed by CVD, PVD, ALD, or other suitable methods. The backside ILD layer 274 may include tetraethylorthosilicate (TEOS) oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof; and may be formed by plasma enhanced CVD (PE-CVD), flowable CVD (F-CVD), or other suitable methods.

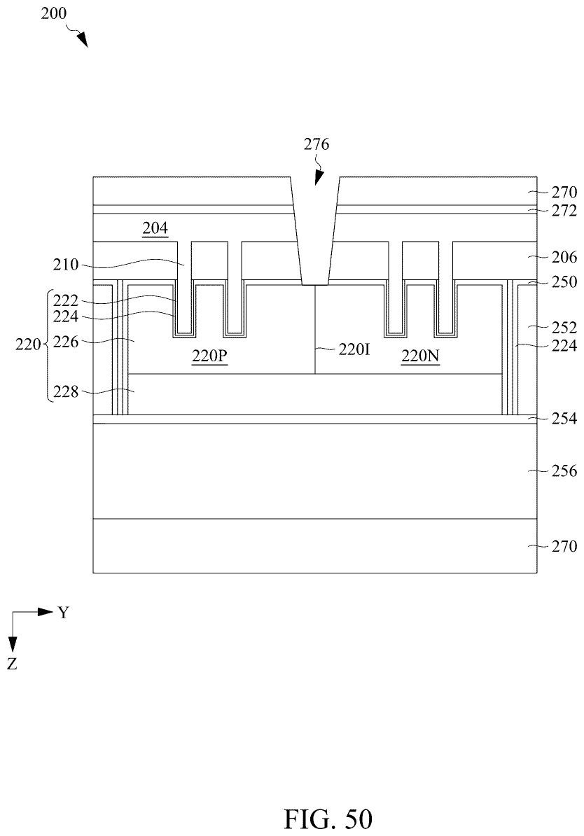

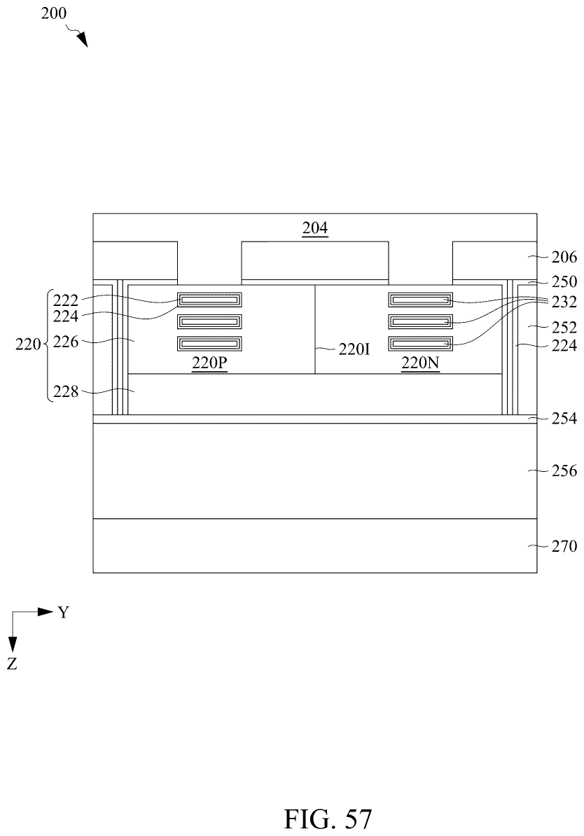

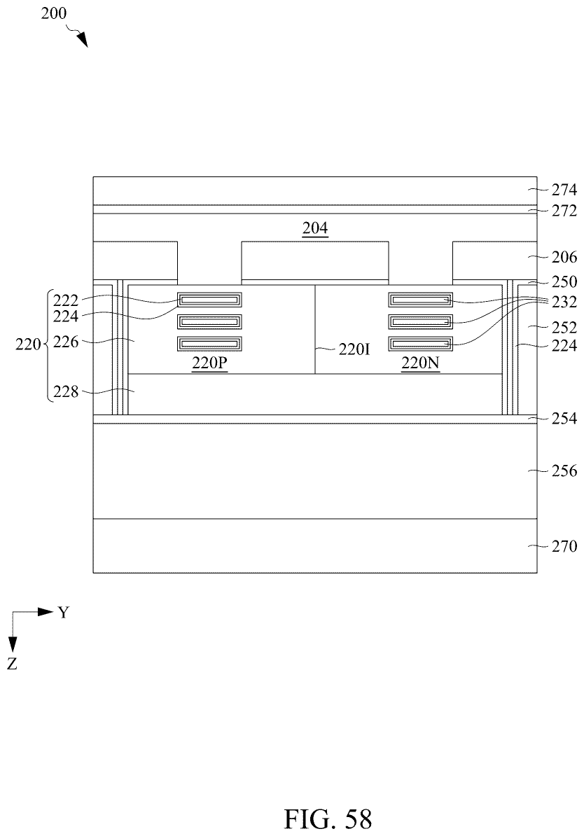

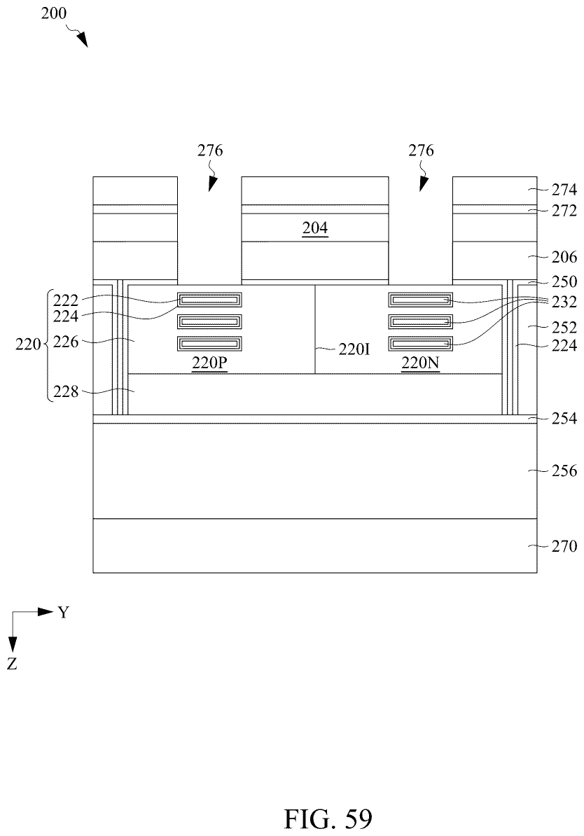

Referring to FIG. 45 and FIG. 50 (or FIG. 59), at operation 310, the method 300 patterns the backside dielectric layers to form one or two backside openings 276 over the backside of the gate structure 220 and further extends the backside opening(s) 276 through the substrate 204, the isolation structure 206, and the high-k dielectric layer 224. The backside dielectric layers are patterned using any suitable photolithography technique to form the backside opening(s) 276 therein. As an example of patterning, a resist layer (not shown) may be deposited on the backside ILD layer 274 and exposed to a radiation beam including an UV or an excimer laser such as a 248 nm beam from a Krypton Fluoride (KrF) excimer laser, a 193 nm beam from an Argon Fluoride (ArF) excimer laser, or a 157 nm beam from a F₂ excimer laser. Exposure of the photosensitive material may be performed using an immersion lithography system to increase resolution and decrease the minimum achievable pitch. A bake or cure operation may be performed to harden the resist layer, and a developer may be used to remove either the exposed or unexposed portions of the resist layer depending on whether a positive or negative resist is used. Subsequently, the opening defined in the resist layer is transferred to the underneath layers using one or more suitable etching processes. The etching processes also extend the backside opening(s) 276 through the high-k dielectric layer 224 and expose the gate electrode layer 226. Furthermore, the etching process may over-etch into the gate electrode layer 226, such that the backside opening(s) 276 extends to a position above (along Z direction) a bottom surface of the gate electrode layer 226, such that when the backside gate contact is formed, a top portion of the backside gate contact above the high-k dielectric layer 224 would be embedded in the gate electrode layer 226.

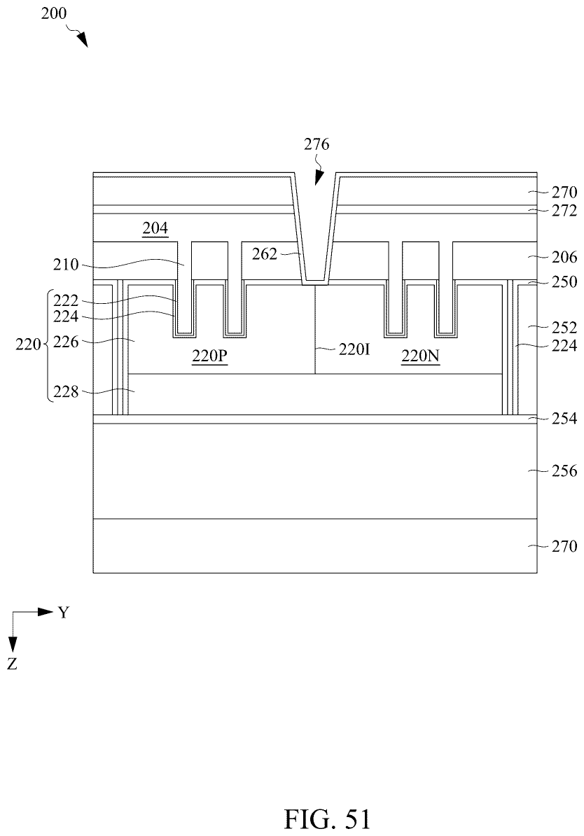

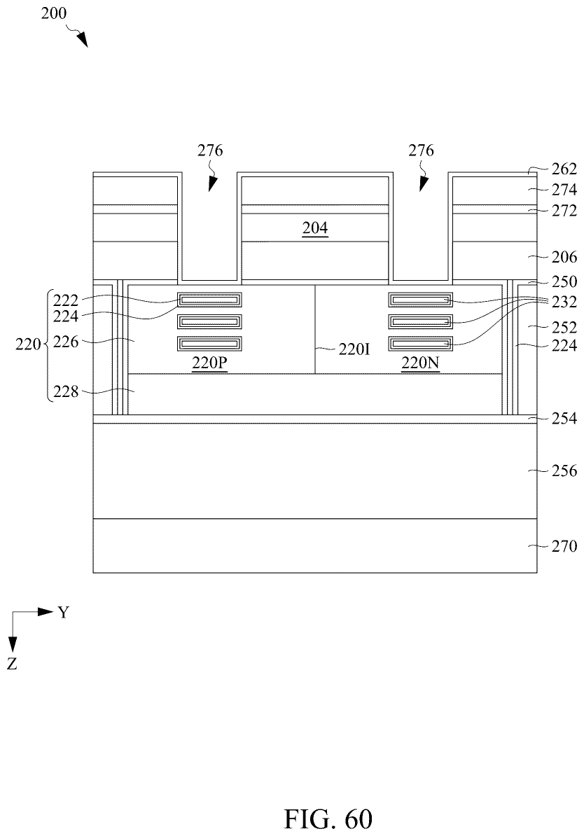

Referring to FIG. 45 and FIG. 51 (or FIG. 60), at operation 312, the method 300 deposits a dielectric liner 262 on sidewalls and bottom surface of the backside opening(s) 276 (including on backside surface of the device 200). The dielectric liner 262 further protects the gate structure 220 from metal element diffusion when conductive features are subsequently formed in the backside opening(s) 276. In the illustrated embodiment, the dielectric liner 262 is conformally deposited to have a substantially uniform thickness along the various surfaces of the backside of the device 200. In various embodiments, the dielectric liner 262 may include SiN, SiOCN, SiOC, SiCN, SiO₂, SiC, ZnO, ZrN, Zr₂Al₃O₉, TiO₂, TaO₂, ZrO₂, HfO₂, Y₂O₃, La₂O₃, Al₂O₃, AlON, TaCN, ZrSi, combinations thereof, or other suitable material(s). The dielectric liner 262 may be deposited using ALD, CVD, or other suitable methods.

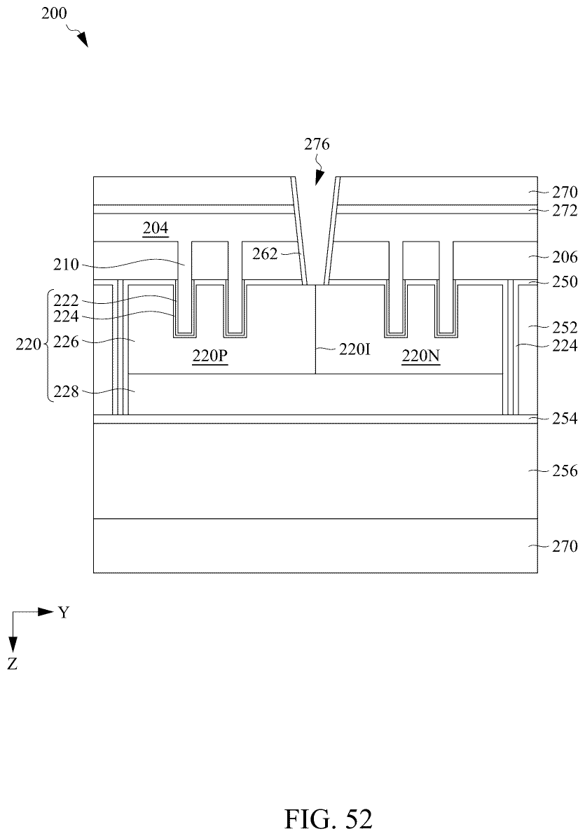

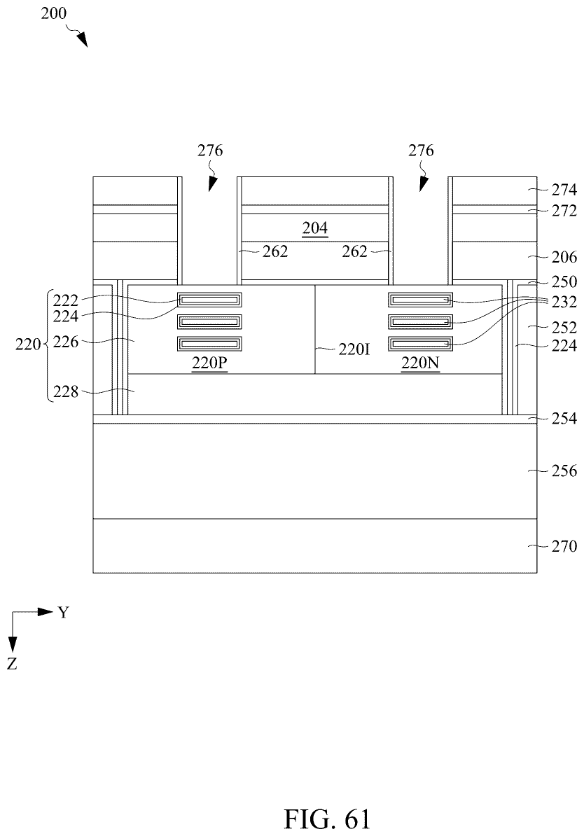

Referring to FIG. 45 and FIG. 52 (or FIG. 61), at operation 314, the method 300 performs an etching process for breaking through, and removing the majority of, the horizontal portions of the dielectric liner 262. The etching process is also referred to as a breakthrough (BT) etching process. In some embodiments, the BT etching process may include an anisotropic dry etch process, or the like. In some embodiments where the dielectric liner 262 is formed of a nitride (e.g., silicon nitride), the BT etch process is a reactive ion etch (RIE) process with etch process gases including CHF₃, Ar, CF₄, N₂, O₂, CH₂F₂, SF₃, the like, or a combination thereof. The RIE process may be performed for an etch time between about 2 seconds and about 20 seconds, at a pressure between about 2 mTorr and about 30 mTorr, a temperature between about 10° C. and about 100° C., a radio frequency (RF) power between about 100 W and about 1500 W, and a voltage bias between about 10 V and about 800 V. In the illustrated embodiment, as a result of the operation 314, portions of the dielectric liner 262 remain on sidewalls of the backside opening(s) 276. In some embodiments, the method 300 may further perform an over-etching process after the breakthrough of the dielectric liner 262 to form a flange-like cavity above the high-k dielectric layer 224.

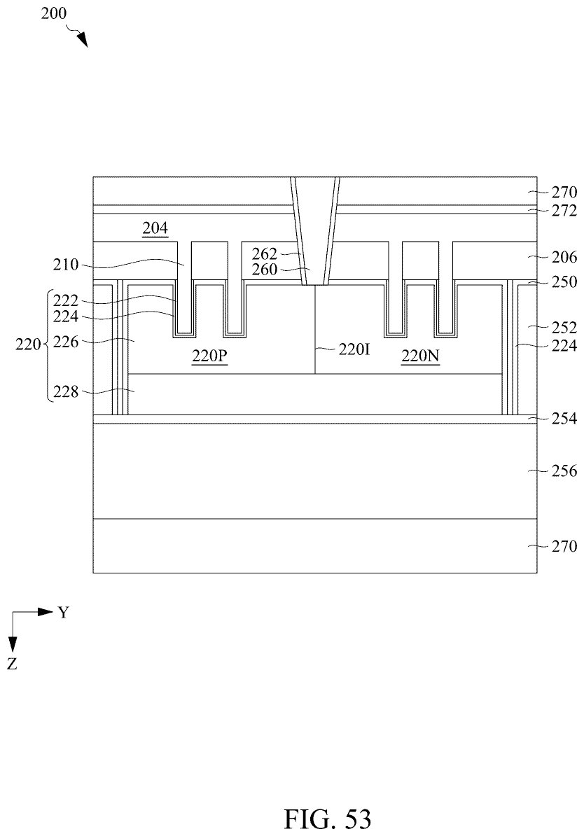

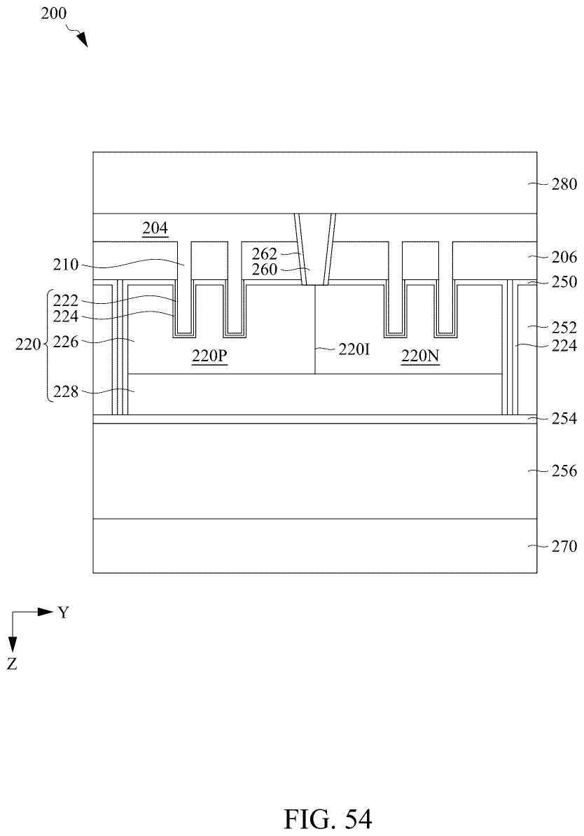

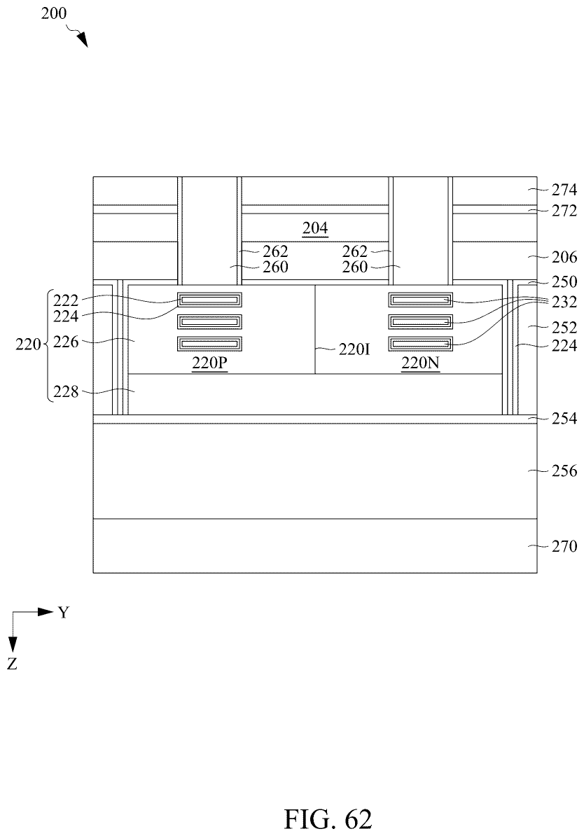

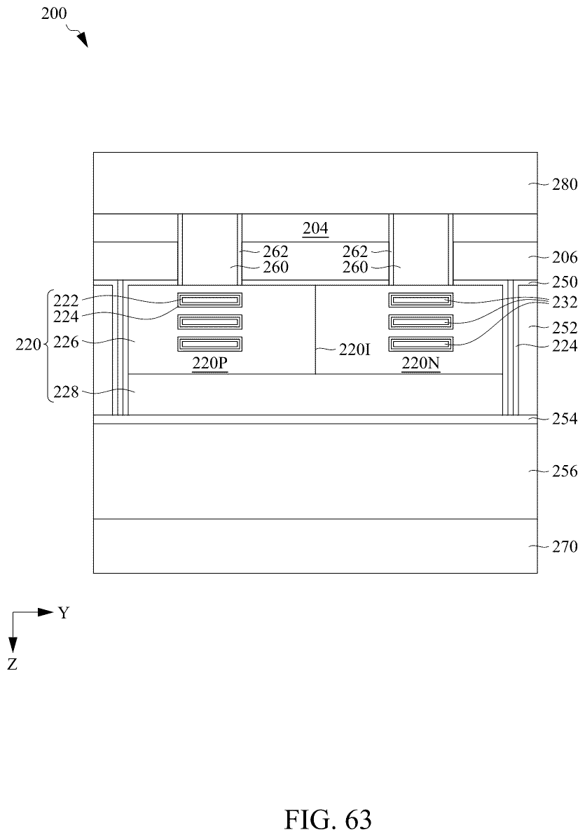

Referring to FIG. 45 and FIG. 53 (or FIG. 62), at operation 316, the method 300 forms the backside gate contact(s) 260 in the backside opening(s) 276. In some embodiments, the backside gate contact(s) 260 is formed by filling the backside opening(s) 276 with one or more conductive materials. The backside gate contact(s) 260 may include tungsten (W), cobalt (Co), molybdenum (Mo), ruthenium (Ru), copper (Cu), nickel (Ni), titanium (Ti), tantalum (Ta), titanium nitride (TiN), tantalum nitride (TaN), or other metals, and may be formed by CVD, PVD, ALD, plating, or other suitable processes. In some embodiments, the conductive material in forming the backside gate contact(s) 260 is fluorine-free, such as fluorine-free tungsten. Subsequently, the method 300 removes excessive conductive materials from the backside of the device 200 and exposes the substrate 204 in a planarization process and may continue to form a backside interconnect structure 280, such as the BM0 layer and/or other underneath BMLI layers (FIG. 2). The resultant structure based on the FinFET construction is shown in FIG. 54; the resultant structure based on the GAA construction is shown in FIG. 63. The method 300 may continue to other manufacturing processes to finalize the IC product.

In one exemplary aspect, the present disclosure is directed to a semiconductor device. The semiconductor device includes a first active region including a first channel region and two first source/drain regions sandwiching the first channel region, a second active region including a second channel region and two second source/drain regions sandwiching the second channel region, an isolation structure extending from a first sidewall of the first active region to a second sidewall of the second active region, the isolation structure comprising a dielectric constant between about 3 and about 5, a gate structure extending across the first and second channel regions, the gate structure including a gate dielectric layer and a gate electrode layer, the gate electrode layer including a first segment of a first conductivity type over the first channel region and a second segment of a second conductivity type over the second channel region, gate spacers disposed on sidewalls of the gate structure, an interlayer dielectric layer disposed over the first source/drain regions and the second source/drain regions, a source/drain contact extending through the interlayer dielectric layer to electrically couple to one of the first source/drain regions, and a backside gate contact extending through the gate dielectric layer and interfacing a bottom surface of the gate electrode layer. In some embodiments, the semiconductor device further includes a dielectric liner disposed on sidewalls of the backside gate contact. The dielectric liner interfaces the gate dielectric layer. In some embodiments, a width of the backside gate contact expands above the gate dielectric layer. In some embodiments, each of the first and second channel regions resides in a semiconductor fin protruding from a substrate and through the isolation structure. In some embodiments, the first channel region includes a stack of first channel layers suspended directly above a fin-shaped base, and the second channel region includes a stack of second channel layers suspended directly above the backside gate contact. In some embodiments, the semiconductor device further includes a first bottom dielectric layer disposed in the first source/drain regions, and a second bottom dielectric layer disposed in the second source/drain regions. In some embodiments, the backside gate contact is positioned between the first and second active regions. In some embodiments, the backside gate contact is positioned on a same side of the first and second active regions. In some embodiments, the backside gate contact is positioned directly under an interface between the first and second segments of the gate electrode layer. In some embodiments, along a longitudinal direction of the first and second active regions, a width of the backside gate contact is equal to or greater than a width of the gate structure.

In another exemplary aspect, the present disclosure is directed to a semiconductor device. The semiconductor device includes a first transistor of a first conductivity type and a second transistor of a second conductivity type different from the first conductivity type. The first transistor includes a first active region, and a first gate structure across the first active region. The second transistor includes a second active region extending parallel to the first active region, and a second gate structure across the second active region. The first and second gate structures share a common gate dielectric layer. The semiconductor device further includes gate spacers extending along sidewalls of the first and second gate structures. A dielectric constant of the common gate dielectric layer is greater than a dielectric constant of the gate spacers. The semiconductor device further includes an isolation structure disposed alongside the first and second active regions, and a backside gate contact extending through the isolation structure and the common gate dielectric layer and in electrical coupling with the first and second gate structures. In some embodiments, the first gate structure abuts the second gate structure, and the backside gate contact is positioned directly under an interface between the first and second gate structures. In some embodiments, the backside gate contact is positioned directly under the second active region and offset from the first active region. In some embodiments, the backside gate contact includes a top portion above the common gate dielectric layer and a bottom portion under the common gate dielectric layer, and wherein a width of the top portion is greater than a width of the bottom portion. In some embodiments, sidewalls of the backside gate contact have a tapered profile. In some embodiments, sidewalls of the backside gate contact are substantially straight.

In yet another exemplary aspect, the present disclosure is directed to a method of manufacturing a semiconductor device. The method includes forming a structure having a first active region, second active region, and a common gate structure across the first and second active regions and disposed on a frontside of a substrate, forming a gate spacer along a sidewall of the common gate structure, forming a contact etch stop layer extending along and interfacing the gate spacer, such that the gate spacer is between the common gate structure and the contact etch stop layer, thinning down the substrate from a backside of the substrate, forming a backside dielectric layer over the backside of the substrate, patterning the backside dielectric layer to form a backside opening directly under the common gate structure, extending the backside opening through the substrate and a gate dielectric layer of the common gate structure, a thickness of the gate spacer being greater than a thickness of the gate dielectric layer, forming a dielectric liner on sidewalls of the backside opening, and depositing a backside gate contact in the backside opening. The backside gate contact interfaces a bottom surface of a gate electrode layer of the common gate structure. In some embodiments, the method further includes after the forming of the dielectric liner, performing an etching process to expand a width of the backside opening above the gate dielectric layer. In some embodiments, the forming of the dielectric liner includes conformally depositing the dielectric liner on sidewalls and a bottom surface of the backside opening, and performing an anisotropic etching process to remove the dielectric liner from the bottom surface of the backside opening. In some embodiments, the backside gate contact is positioned directly under one of the first and second active regions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first active region including a first channel region and two first source/drain regions sandwiching the first channel region;
a second active region including a second channel region and two second source/drain regions sandwiching the second channel region;
an isolation structure extending from a first sidewall of the first active region to a second sidewall of the second active region, wherein the isolation structure comprises a dielectric constant between about 3 and about 5;
a gate structure extending across the first and second channel regions, the gate structure including a gate dielectric layer and a gate electrode layer, the gate electrode layer including a first segment of a first conductivity type over the first channel region and a second segment of a second conductivity type over the second channel region;
gate spacers disposed on sidewalls of the gate structure;
an interlayer dielectric layer disposed over the first source/drain regions and the second source/drain regions;
a source/drain contact extending through the interlayer dielectric layer to electrically couple to one of the first source/drain regions; and
a backside gate contact extending through the gate dielectric layer and interfacing a bottom surface of the gate electrode layer.

2. The semiconductor device of claim 1, further comprising:
a dielectric liner disposed on sidewalls of the backside gate contact, wherein the dielectric liner interfaces the gate dielectric layer.

3. The semiconductor device of claim 1, wherein a width of the backside gate contact expands above the gate dielectric layer.

4. The semiconductor device of claim 1, wherein each of the first and second channel regions resides in a semiconductor fin protruding from a substrate and through the isolation structure.

5. The semiconductor device of claim 1, wherein the first channel region includes a stack of first channel layers suspended directly above a fin-shaped base, and wherein the second channel region includes a stack of second channel layers suspended directly above the backside gate contact.

6. The semiconductor device of claim 1, further comprising:
a first bottom dielectric layer disposed in the first source/drain regions; and
a second bottom dielectric layer disposed in the second source/drain regions.

7. The semiconductor device of claim 1, wherein the backside gate contact is positioned between the first and second active regions.

8. The semiconductor device of claim 1, wherein the backside gate contact is positioned on a same side of the first and second active regions.

9. The semiconductor device of claim 1, wherein the backside gate contact is positioned directly under an interface between the first and second segments of the gate electrode layer.

10. The semiconductor device of claim 1, wherein, along a longitudinal direction of the first and second active regions, a width of the backside gate contact is equal to or greater than a width of the gate structure.

11. A semiconductor device, comprising:
a first transistor of a first conductivity type, the first transistor comprising:
a first active region; and
a first gate structure across the first active region;
a second transistor of a second conductivity type different from the first conductivity type, the second transistor comprising:
a second active region extending parallel to the first active region;
a second gate structure across the second active region, wherein the first and second gate structures share a common gate dielectric layer;
gate spacers extending along sidewalls of the first and second gate structures, wherein a dielectric constant of the common gate dielectric layer is greater than a dielectric constant of the gate spacers;
an isolation structure disposed alongside the first and second active regions; and
a backside gate contact extending through the isolation structure and the common gate dielectric layer and in electrical coupling with the first and second gate structures.

12. The semiconductor device of claim 11, wherein the first gate structure abuts the second gate structure, and wherein the backside gate contact is positioned directly under an interface between the first and second gate structures.

13. The semiconductor device of claim 11, wherein the backside gate contact is positioned directly under the second active region and offset from the first active region.

14. The semiconductor device of claim 11, wherein the backside gate contact includes a top portion above the common gate dielectric layer and a bottom portion under the common gate dielectric layer, and wherein a width of the top portion is greater than a width of the bottom portion.

15. The semiconductor device of claim 11, wherein sidewalls of the backside gate contact have a tapered profile.

16. The semiconductor device of claim 11, wherein sidewalls of the backside gate contact are substantially straight.

17. A method of manufacturing a semiconductor device, comprising:
forming a structure having a first active region, second active region, and a common gate structure across the first and second active regions and disposed on a frontside of a substrate;
forming a gate spacer along a sidewall of the common gate structure;
forming a contact etch stop layer extending along and interfacing the gate spacer, such that the gate spacer is between the common gate structure and the contact etch stop layer;
thinning down the substrate from a backside of the substrate;
forming a backside dielectric layer over the backside of the substrate;
patterning the backside dielectric layer to form a backside opening directly under the common gate structure;
extending the backside opening through the substrate and a gate dielectric layer of the common gate structure, wherein a thickness of the gate spacer is greater than a thickness of the gate dielectric layer;
forming a dielectric liner on sidewalls of the backside opening; and
depositing a backside gate contact in the backside opening, wherein the backside gate contact interfaces a bottom surface of a gate electrode layer of the common gate structure.

18. The method of claim 17, further comprising:
after the forming of the dielectric liner, performing an etching process to expand a width of the backside opening above the gate dielectric layer.

19. The method of claim 17, wherein the forming of the dielectric liner includes:
conformally depositing the dielectric liner on sidewalls and a bottom surface of the backside opening; and
performing an anisotropic etching process to remove the dielectric liner from the bottom surface of the backside opening.

20. The method of claim 17, wherein the backside gate contact is positioned directly under one of the first and second active regions.
